(19) United States
(12) Patent Application Publication
(10) Pub. No.: US 2025/0045973 A1
(43) Pub. Date: Feb. 6, 2025

(54) Decoder for providing decoded Parameters of a Neural Network, Encoder, Methods and Computer Programs using a Reordering

(71) Applicant: Fraunhofer-Gesellschaft zur Förderung der angewandten Forschung e.V., München (DE)

(72) Inventors: Paul HAASE, Berlin (DE); Heiner KIRCHHOFFER, Berlin (DE); Daniel BECKING, Berlin (DE); Karsten MÜLLER, Berlin (DE); Wojciech SAMEK, Berlin (DE); Heiko SCHWARZ, Berlin (DE); Detlev MARPE, Berlin (DE); Thomas WIEGAND, Berlin (DE); Gerhard TECH, Berlin (DE)

(21) Appl. No.: 18/913,085

(22) Filed: Oct. 11, 2024

Related U.S. Application Data
(63) Continuation of application No. PCT/EP2023/059638, filed on Apr. 13, 2023.

(30) Foreign Application Priority Data
Apr. 15, 2022 (EP) 22168623.1

(51) Int. Cl. G06T 9/00; H04N 19/129; H04N 19/13; H04N 19/167; H04N 19/196

(52) U.S. Cl. CPC G06T 9/002; H04N 19/129; H04N 19/13; H04N 19/167; H04N 19/196

(57) ABSTRACT

Embodiments according to the invention relate to a decoder for providing decoded parameters of a neural network on the basis of an encoded representation, wherein the decoder is configured to obtain a first multi-dimensional array comprising a plurality of neural network parameter values using a decoding of neural network parameters and wherein the decoder is configured to obtain a re-ordered multidimensional array using a reordering, in which a first dimension of the first multi-dimensional array is rearranged to a different dimension in the re-ordered multidimensional array. Furthermore, encoders, methods and computer programs using a reordering are disclosed.

### CROSS-REFERENCES TO RELATED APPLICATIONS

This application is a continuation of copending International Application No. PCT/EP2023/059638, filed Apr. 13, 2023, which is incorporated herein by reference in its entirety, and additionally claims priority from European Application No. EP 22168623.1, filed Apr. 15, 2022, which is incorporated herein by reference in its entirety.

Embodiments according to the invention are related to a decoder for providing decoded parameters of a neural network, an encoder, methods and computer programs using a reordering.

Embodiments according to the invention are related to a tensor dimension reordering by a tensor dimension shift.

Embodiments according to the invention are related to methods for a tensor dimension reordering for coding of neural networks.

Embodiments according to the invention are related to a compression of neural networks for multimedia content description and analysis.

### BACKGROUND OF THE INVENTION

Many frameworks provide several compression tools, comprising quantization and/or lossless encoding methods and lossless decoding methods, for the processing and/or compression of tensors.

As an example, based on the success of artificial neural networks in multimedia analysis and processing, media coding, data analytics and many other applications, the demand for concepts which allow for an exchange of such networks, for example in the form of respective neural network parameters has increased. Such neural network parameters may, for example, be processed and/or encoded and decoded in the form of tensors.

Accordingly, the processing, encoding and decoding of such tensors may represent a crucial aspect for an efficiency of such a framework.

Therefore, it is desired to get an improved concept for an encoding, decoding and/or processing of parameters, such as neural network parameters, provided in a structured representation, such as a multi-dimensional array or tensor, which makes a better compromise between a coding efficiency, flexibility and complexity.

This is achieved by the subject matter of the independent claims of the present application.

### SUMMARY

An embodiment may have a decoder for providing decoded parameters of a neural network on the basis of an encoded representation, wherein the decoder is configured to acquire a first multi-dimensional array comprising a plurality of neural network parameter values using a decoding of neural network parameters; wherein the decoder is configured to acquire a re-ordered multidimensional array using a reordering, in which a first dimension of the first multi-dimensional array is rearranged to a different dimension in the re-ordered multidimensional array.

Another embodiment may have an encoder for providing an encoded representation of parameters of a neural network, wherein the encoder is configured to acquire a re-ordered multidimensional array using a reordering, in which a given dimension of an given multi-dimensional array of neural network parameters is rearranged to a first dimension in the re-ordered multidimensional array; wherein the encoder is configured to encode the reordered multi-dimensional array.

Another embodiment may have a method for providing decoded parameters of a neural network on the basis of an encoded representation, wherein the method comprises acquiring a first multi-dimensional array comprising a plurality of neural network parameter values using a decoding of neural network parameters; wherein the method comprises acquiring a re-ordered multidimensional array using a reordering, in which a first dimension of the first multi-dimensional array is rearranged to a different dimension in the re-ordered multidimensional array.

Another embodiment may have a method for providing an encoded representation of parameters of a neural network, wherein the method comprises acquiring a re-ordered multidimensional array using a reordering, in which a given dimension of an given multi-dimensional array of neural network parameters is rearranged to a first dimension in the re-ordered multidimensional array; wherein the method comprises encoding the reordered multi-dimensional array.

Another embodiment may have a non-transitory digital storage medium having a computer program stored thereon to perform the method for providing decoded parameters of a neural network on the basis of an encoded representation, wherein the method comprises acquiring a first multi-dimensional array comprising a plurality of neural network parameter values using a decoding of neural network parameters; wherein the method comprises acquiring a re-ordered multidimensional array using a reordering, in which a first dimension of the first multi-dimensional array is rearranged to a different dimension in the re-ordered multidimensional array, when said computer program is run by a computer.

Another embodiment may have a non-transitory digital storage medium having a computer program stored thereon to perform the method for providing an encoded representation of parameters of a neural network, wherein the method comprises acquiring a re-ordered multidimensional array using a reordering, in which a given dimension of an given multi-dimensional array of neural network parameters is rearranged to a first dimension in the re-ordered multidimensional array; wherein the method comprises encoding the reordered multi-dimensional array, when said computer program is run by a computer.

Embodiments according to the invention comprise a decoder for providing decoded parameters, e.g. “weights” or “coefficients”, of a neural network on the basis of an encoded representation, e.g. on the basis of a bitstream representing (or for example comprising) the parameters of the neural network in an encoded, e.g. compressed, form.

The decoder is configured to obtain a first multi-dimensional array (e.g. inputTensor[idxA], wherein idxA is a vector of a plurality of index variables; e.g. A[m][n][o][p], wherein m, n, o, p are index variables) comprising a plurality of neural network parameter values, e.g. neural network weights, using a decoding of neural network parameters, for example, such that the first multi-dimensional array comprises decoded neural network parameters.

Furthermore, the decoder is configured to obtain a re-ordered multidimensional array (e.g. reorderedTensor[idxB], wherein idxB is a vector of a plurality of index variables; e.g. B[n][o][m]][p], wherein n, o, m, p are index variables) using a reordering, in which a first dimension of the first multi-dimensional array, e.g. a dimension of the multi-dimensional array designated by a leftmost array index, is rearranged, e.g. moved, to a different dimension, which is for example different from a first dimension, in the re-ordered multidimensional array.

In many frameworks, structured representations of parameters, for example tensors, may be interpreted as 1-dimensional or 2-dimensional representations, for example, in the form of 1-D arrays or 2-D arrays. Accordingly, the shape of such an interpreted representation may be determined by the original dimensions of the structured representation and in particular a respective order of parameters within the original structured representation.

As an example, according to some frameworks, in such an interpretation a length of a first dimension of an interpreted array may be equal to a length of a first dimension of the original representation and the length of a second dimension of the interpreted array may be equal to the product of all other dimensions of the original representation.

The inventors recognized that such a shape and/or ordering of parameters also affects the efficiency of a compression and/or processing pipeline. Moreover, conventional frameworks lack the flexibility to adapt respective structured parameter representations, e.g. tensors, between processing steps in order to increase efficiency.

Hence, the inventors recognized that based on a reordering of dimensions of a structured representation of parameters, a better compromise between a coding efficiency, flexibility and complexity for an encoding, decoding and/or processing of parameters, such as neural network parameters, provided in a structured representation, such as a multi-dimensional array or tensor, may be provided.

Furthermore, as an example, for an encoding and/or decoding of such parameters, a reordering may allow exploiting correlations between parameters, which may allow to increase a coding efficiency. In particular, a reordering may be adapted in order to improve correlation characteristics for the use of a context adaptive coding, e.g. CABAC.

In addition, the inventors recognized that the inventive reordering approach allows uncoupling requirements or constraints for a tensor shape for encoding from requirements or constraints for the tensor shape for processing. Hence, even contradictory objectives for the tensor shape may be achieved via the reordering.

Furthermore, the inventors recognized that based on an inventive reordering an efficiency of existing coding frameworks may be increased with only limited impact on complexity. As an example, already developed processing approaches expecting a predefined parameter structure, e.g. tensor form, may be left untouched whilst allowing a reshaping of parameter representations, e.g. in order to increase processing efficiency. As an example, an inventive reordering may allow to reshape a respective tensor to allow for an efficient block scanning.

According to embodiments of the invention, the decoder is configured to decode a dimension shift value, e.g. “first_tensor_dimension_shift” value, e.g. a single scalar value. The dimension shift value describes by how many dimensions, e.g. by how many array indices, the first dimension, e.g. D2, (e.g. also designated as “first tensor dimension”) of the first multi-dimensional array (e.g. having dimensions [D2,D0,D1,D3]) should be shifted, e.g. towards a higher dimension number, when performing the reordering, e.g. to obtain the re-ordered multidimensional array having dimensions [D0,D1,D2,D3]. The inventors recognized that based on the dimension shift value, a shifting of a tensor dimension may be controlled with low signaling overhead. Furthermore, signaling a shifting information about a dimension may allow to perform the reordering in an efficient manner.

According to embodiments of the invention, the decoder is configured to decode a dimension shift value, e.g. “first_tensor_dimension_shift” value, and the dimension shift value, e.g. a scalar value, describes a new position of the first dimension, e.g. D2, (e.g. also designated as “first tensor dimension”) of the first multi-dimensional array (e.g. having dimensions [D2,D0,D1,D3]) in the re-ordered multidimensional array, e.g. “third dimension in the multi-dimensional array having dimensions [D0,D1,D2,D3]”). Hence, an absolute dimension reordering information, e.g. instead of a relative shift information, may be provided. This may allow a precise reordering of a respective tensor dimension.

According to embodiments of the invention, the dimension-shift value is Exp Golomb-coded. Optionally, the decoder is configured to perform an Exp Golomb decoding of the dimension shift value. The inventors recognized that an Exp Golomb coding may allow providing an efficient representation of the dimension-shift value.

According to embodiments of the invention, the decoder is configured to perform the reordering using a single scalar dimension shift value, e.g. first_tensor_dimension shift, as a sole parameter describing a new order of the dimensions in the re-ordered multi-dimensional array. The inventors recognized that the reordering may be controlled with a single scalar dimension shift value and hence very limited additional data, e.g. in the form of signaling overhead, therefore allowing to maximize coding and/or processing efficiency gains based on the reordering.

According to embodiments of the invention, the decoder is configured to perform, for example only, a single shift of a single dimension to another position, in order to obtain the re-ordered multi-dimensional array. The inventors recognized that allowing arbitrary dimension orders could induce a significant signaling overhead, especially for high dimensional tensors, since the number of permutations may increase massively with the number of tensor dimensions. Instead, according to an aspect of the invention, the decoder may perform only a shift of a single dimension to another position and hence limit the signaling overhead.

According to embodiments of the invention, the decoder is configured to derive a dimension of an auxiliary array from a first dimension of the first multi-dimensional array. As an example, optionally, the decoder may be configured to derive a dimension of a vector or of a two-dimensional array or of an array having more than two dimensions; e.g. of a tensor or “related tensor” or “corresponding tensor” from a first dimension of the first multi-dimensional array. As an example, optionally, the decoder may be configured to derive a dimension of an “auxiliary” array of bias values or of an “auxiliary” array of batch-norm parameters or of an “auxiliary” array of scaling factors from a first dimension of the first multi-dimensional array. Optionally, as an example, the decoder may be configured to set the dimension of the auxiliary array to be equal to the first dimension of the first multi-dimensional array.

Some frameworks, for example MPEG-7 part 17, specify a special NDU-type (e.g. NNR_PT_BLOCK), which allows to transmit a weight tensor and several corresponding tensors, i.e. biases, batch-norm parameters and scaling factors, together in a single NDU. All the tensors in the block may share the same header information (e.g. instead of transmitting individual ones) and thus the bitstream size may reduced. Since the other tensors may be directly related to the weight tensor, the inventors recognized that their dimensions can be derived from the (weight) tensor dimensions.

Hence, in general for a multi-dimensional array (e.g. a weight tensor), an inventive decoder may be configured to derive one or more auxiliary arrays (e.g. comprising biases, batch-norm parameters and scaling factors). Therefore, the above explained dimension determination may be performed, which allows to limit the signaling overhead.

According to embodiments of the invention, the decoder is configured to shift a single dimension of the first multi-dimensional array to a different position, in order to obtain the re-ordered multi-dimensional array. This may provide a simple variant of the inventive reordering, hence limiting the overall impact on complexity and signaling overhead for the processing whilst allowing to increase the processing and/or coding efficiency.

According to embodiments of the invention, the decoder is configured to obtain a 2-dimensional matrix, e.g. having dimensions [D2,(D0*D1*D3)], a first dimension of which is determined by a first dimension value, e.g. D2, and a second dimension of which is determined by a product of a plurality of further dimension values, e.g. D0*D1*D2, on the basis of the encoded representation. In addition, the decoder is configured to obtain the first multi-dimensional array (e.g. having dimensions [D2,D0,D1,D3]), dimensions of which are, optionally individually, determined by individual ones of the first dimension value (e.g. D2) and the further dimension values (e.g. D0,D1,D3) (wherein, for example, each of the first dimension values and the further dimension values may be associated with (and/or define) one dimension of the first multi-dimensional array; wherein, for example, the first dimension value may be associated with (and/or define) a first dimension of the first multi-dimensional array), on the basis of the 2-dimensional matrix. Furthermore, the decoder is configured to obtain the re-ordered multi-dimensional array, e.g. having dimensions [D0,D1,D2,D3], on the basis of the first multi-dimensional array, wherein a first dimension of the re-ordered multi-dimensional array is defined by one of the further dimension values.

The inventors recognized that the decoder may perform, e.g. as an intermediate step for the reordering, an interpretation of a parameter representation of the encoded representation as the 2-dimensional matrix. This approach may allow achieving compliance with existing frameworks, in order to incorporate the inventive reordering, based on the interpreted 2-dimensional matrix. In particular, the inventors recognized that a “shuffling” of one of the further dimension values obtained via the encoded representation to the first dimension of the re-ordered multi-dimensional array allows to increase the flexibility of the processing, since a tensor shape for encoding may be implemented different from a tensor shape for processing.

According to embodiments of the invention, the decoder is configured to decode encoded neural network parameters using a context-based entropy decoding, for example, using an arithmetic decoding in which one or more contexts for an arithmetic decoding of a given encoded neural network parameter are determined in dependence on a previously decoded neural network parameter, e.g. in dependence on a previously decoded neural network parameter directly preceding the given encoded neural network parameter in a decoding order. In addition, the decoder is configured to determine positions of the decoded neural network parameters in the first multi-dimensional array using a position mapping function, e.g. TensorIndex(tensorDimensions[ ], I, scan), which maps a scalar neural network parameter index, e.g. i, onto a set, e.g. a vector or a (preferably 1-dimensional) array, of dimension indices, for example an array having a number of entries which is equal to a number of dimensions of the first multi-dimensional array, e.g. onto an array pointing to an i-th element in a row-major scan order of a multi-dimensional array having the dimensions of the first multi-dimensional array or onto an array pointing to an i-th element in a block-wise scan order (e.g. scanning subblocks) of a two-dimensional interpretation of the first multi-dimensional array, e.g. as defined by function TensorIndex (tensorDimensions[ ], I, scan) for scan>0 when taken in combination with IndexToXY. This approach may allow for an efficient decoding and reordering of tensor values and dimensions.

According to embodiments of the invention, the decoder is configured to contiguously store a plurality of decoded neural network parameters (e.g. D3 decoded neural network parameters), which are directly adjacent with respect to a decoding order (e.g. decoded in a sequence; e.g. decoded considering a context adaptation in dependence on a value of a predecessor), along a given dimension (e.g. a fourth dimension or a highest dimension) of the first multi-dimensional array, wherein, for example, an index of the given dimension is successively increased or decreased and wherein, for example, indices of the other dimensions remain unchanged. Hence, a storing of decoded neural network parameters may be performed while conserving a respective order of the parameters, e.g. at least within a dimension.

According to embodiments of the invention, the decoder is configured to obtain the re-ordered multi-dimensional array using a processing, e.g. computation, of the form:

```
for( i = 0; i < Prod( inputTensorDims ); i++ ){
    idxA = TensorIndex( inputTensorDims, i, 0 )
    idxB = ShiftArrayIndex( idxA, firstTensorDimShift )
    reorderedTensor[idxB] = inputTensor[idxA]
  }
```

wherein i is a running variable, wherein Prod(inputTensorDims) is a product of lengths of dimensions of the first multi-dimensional array, and may, for example, be equal to a number of elements of the first multi-dimensional array. Furthermore, TensorIndex (.,.,.) is a function mapping an integer value (e.g. the running variable i; e.g. a scalar integer value referencing elements of the first multi-dimensional array, e.g. in an ascending order) onto a set (e.g. a one-dimensional array or a vector) of array indices (e.g. a set comprising a number of array indices which is equal to a number of dimensions of the first multi-dimensional array) designating an element (e.g. a decoded neural network parameter] of the first multi-dimensional array). Moreover, inputTensorDims is a set (e.g. a one-dimensional array or a set) of values describing lengths of dimensions of the first multi-dimensional array, idxA is a variable (e.g. representing a set (e.g. a one-dimensional array or a vector) of array indices), ShiftArrayIndex (.,.) is a function mapping an input set (e.g. a one-dimensional array or a set) of array indices (e.g. a set comprising a number of array indices which is equal to a number of dimensions of the first multi-dimensional array, e.g. idxA) onto a return set (e.g. a one-dimensional array or a set, e.g. idxB) of array indices, wherein the return set of array indices is a copy of the input set of array indices but with an element of the input set of array indices at position 0 shifted to a position designated by firstTensorDimShift (wherein positions are optionally counted from 0 to a size of the input set of array indices −1. In addition, firstTensorDimShift is a dimension shift value (e.g. describing by how many dimensions a first dimension of the first multi-dimensional array should be shifted), idxB is a variable (e.g. representing a set (e.g. a one-dimensional array or a vector) of array indices), inputTensor [.] is the first multi-dimensional array, reorderedTensor [.] is the re-ordered multi-dimensional array, inputTensor[idxA] is an element of the first multi-dimensional array at a position designated by idxA and reorderedTensor [idxB] is an element of the reordered multi-dimensional array at a position designated by idxB. Optionally, firstTensorDimShift may correspond to first_tensor_dimension_shift. The inventors recognized that such an approach may allow to provide an efficient implementation of the reordering procedure.

According to embodiments of the invention, the decoder is configured to obtain the re-ordered multidimensional array using a function, e.g. TensorIndex(tensorDimensions[ ],i,scan), which maps an integer element index i designating, e.g. uniquely designating, an element of the first multi-dimensional array onto a set, e.g. a one-dimensional array or a vector, of array indices, wherein a returned set of array indices designates an i-th element in a row-major scan order of the first multidimensional array (e.g. of an array with array dimensions designated by the set tensorDimensions[ ]), or wherein a returned set of array indices designates an i-th element of a block-wise scan, e.g. using blocks of size bs times bs) of the first multi-dimensional array, in which the first multi-dimensional array is considered as a two-dimensional array, for example of width w and height h, for example, elements of which are referenced by x and y, wherein x and y may, for example, be obtained using a function IndexToXY which maps an scalar integer index i onto a set (e.g. array) of two elements x and y. The inventors recognized that the inventive reordering may be performed based on different scan orders of the first multidimensional array. Hence, the inventive approach is flexible and easily compatible with a plurality of scanning approaches.

According to embodiments of the invention, the decoder is configured to decode a list of skipped rows, e.g. row skip list[i], wherein, for example, a number of entries of the list of skipped rows, e.g. tensor2Dheight, may be equal to a length of the first dimension of the first multidimensional array, e.g. dimensions[0]. Furthermore the decoder is configured to enter decoded neural network coefficients, e.g. QuantParam[idx], into the first multidimensional array, e.g. by setting QuantParam[idx] to take a decoded value, at respective positions described by respective sets of array indices, e.g. represented by a variable idx, which is, for example, obtained using a function idx=Tensorindex(dimensions, i, scan_order). In addition, the decoder is configured decide, in dependence on an entry of the list of skipped rows referenced, e.g. designated, by a current array index of the first dimension of the first multidimensional array, e.g. row_skip_list [idx[0]], whether to use a default value for a given neural network parameter, e.g. QuantParam [idx]=0 (or, for example, even for a sequence of neural network parameters having a same current array index of the first dimension of the first multidimensional array) or whether to determine the given neural network parameter (or, for example, even a sequence of neural network parameters having a same current array index of the first dimension of the first multidimensional array) using a decoding, e.g. using a call of a decoding function, e.g. int_param(i,maxNumNoRemMinus1,stateId). Hence, based on the information about the skipped rows a decoding effort can be reduced.

According to embodiments of the invention, the decoder is configured to decode a set, e.g. a one-dimensional array or a vector, of array dimensions (e.g. describing lengths of the first multi-dimensional array in different dimensions, e.g. tensor_dimensions[.], wherein, for example, the array dimensions may be Exp-Golomb coded. Furthermore, the decoder is configured to obtain a reordered set of array dimensions, e.g. a one-dimensional array or a vector, entries of which describe lengths of the reordered multidimensional array in different directions, e.g. using an application of the function ShiftArrayIndex to the decoded set of array dimensions. As an example, a determination of a ordering of tensor or array dimensions may hence be performed separately from the shaping or ordering of the respective tensor and/or array itself. The inventors recognized that hence, a reordering efficiency may be increased.

According to embodiments of the invention, the decoder is configured to enter, e.g. subsequent, decoded neural network parameters, e.g. QuantParam[idx], into the first multidimensional array, e.g. by setting QuantParam[idx] to take a decoded value, at respective positions described by respective sets of array indices, for example represented by a variable idx, which is, for example, obtained using a function idx=Tensorindex(dimensions, i, scan_order). In addition, the decoder is configured to obtain the respective sets of array indices using a mapping function (e.g. TensorIndex (tensorDimensions[ ], i, scan), which may, for example, invoke IndexToXY) which maps a scalar integer parameter index, e.g. i, onto the respective set of array indices and which defines a block-wise scan, wherein, for example, subsequent values of the scalar integer parameter index may be associated with subsequently decoded parameter values. The inventors recognized that this way, an efficient reordering approach may be provided.

According to embodiments of the invention, the mapping function comprises a mapping of the scalar integer parameter index, e.g. i, onto two coordinates, e.g. x, y, which point to a position that corresponds to a scan index defined by the scalar integer parameter index, e.g. i, when a block, e.g. a two-dimensional array of width w and height h, is scanned in blocks, e.g. in quadratic blocks; e.g. in blocks of size bs times bs. Furthermore, the mapping function comprises a mapping of the two coordinates onto the respective set of array indices. The inventors recognized that this way, dimensions to be reordered may be addressed efficiently.

According to embodiments of the invention, the decoder is configured to enter, e.g. subsequent, decoded neural network parameters, e.g. QuantParam[idx], into the first multidimensional array, e.g. by setting QuantParam[idx] to take a decoded value, at respective positions described by respective sets of array indices, e.g. represented by a variable idx, which is, for example, obtained using a function idx=Tensorindex(dimensions, i, scan_order). Furthermore, the decoder is configured to obtain a respective set of array indices on the basis of a scalar integer parameter index i using a function TensorIndex(tensorDimensions[ ], i, scan), wherein the function TensorIndex(tensorDimensions[ ], i, scan) returns an array of array indices with a same number of dimensions as an array tensorDimensions[ ], where the elements of the array of array indices are set to integer values so that the array of array indices can be used as an index pointing to an element of an array, e.g. tensor, with dimensions tensorDimensions[ ] as follows:
If variable scan is equal to 0:
   the returned array of array indices points to the i-th element in row-major scan order of an array [e.g. tensor][e.g. the first multidimensional array] with dimensions defined by tensorDimensions[ ];
If variable scan is greater than 0:
   a variable bs is set to 4<<scan_order;
   a variable h is set to tensorDimensions[0]
      [e.g. to a length of a first dimension of the first multidimensional array];
   a variable w is set to Prod(tensorDimensions)/h
      [e.g. to a product of lengths of the first multidimensional array in different dimensions divided by h, or to a number of elements of the first multidimensional array divided by h];
   two variables x and y are set to the first and second element of an array that is returned
      by calling IndexToXY(w, h, i, bs), respectively;
   the returned array is TensorIndex(tensorDimensions, y*w+x, 0);
      wherein the function IndexToXY(w, h, i, bs) returns an array with two elements, wherein the first element returned by the function IndexToXY is an x coordinate and the second element returned by the function IndexToXY is a y coordinate pointing into a 2D array of width w and height h, wherein x and y point to a position that corresponds to scan index i when the block [e.g. the 2D array of width w and height h] is scanned in blocks of size bs times bs; wherein x and y are derived as follows:
a variable fullRowOfBlocks is set to w*bs;
a variable blockY is set to i/fullRowOfBlocks;
a variable iOff is set to i % fullRowOfBlocks;
a variable currBlockH is set to Min(bs, h−blockY*bs);
a variable fullBlocks is set to bs*currBlockH;
a variable blockX is set to iOff/fullBlocks;
a variable blockOff is set to iOff % fullBlocks;
a variable currBlockW is set to Min(bs, w−blockX*bs)
a variable posX is set to blockOff % currBlockW;
a variable posY is set to blockOff/currBlockW;
The variable x is set to blockX*bs+posX;
The variable y is set to blockY*bs+posY;
   wherein tensorDimensions [ ] is an array of values describing lengths of the first multidimensional array in different dimensions and wherein scan is an integer variable describing a scan mode. The inventors recognized that this way, an efficient reordering approach may be provided.

In the following embodiments according to the invention comprising encoders are discussed. Respective encoders as described below may be based on the same considerations as the above-described decoders. The encoders can, by the way, be completed with all features and functionalities, which are also described with regard to the decoders, individually and taken in combination.

Further embodiments according to the invention comprise an encoder for providing an encoded representation of parameters, e.g. “weights” or “coefficients”, of a neural network, for example in the form of a bitstream representing parameters of the neural network in an encoded (e.g. compressed) form. Furthermore, the encoder is configured to obtain a re-ordered multidimensional array (e.g. BEnc[o][m][n][p], wherein o, m, n, p are index variables) using a reordering, in which a given dimension of an given multi-dimensional array of neural network parameters (e.g. a given dimension of the multi-dimensional array designated by a given array index, e.g. a third dimension of the given multidimensional array AEnc[m][n][o][p]) is rearranged, e.g. moved, to a first dimension, which is optionally different from the given dimension, in the re-ordered multidimensional array. In addition, the encoder is configured to encode the reordered multi-dimensional array, e.g. Benc[o][m][n][p], e.g. using an encoding of entries of the reordered multi-dimensional array.

According to embodiments of the invention, the encoder is configured to encode a dimension shift value (e.g. “first_tensor_dimension_shift” value, e.g. a single scalar value) and the dimension shift value describes which given dimension of the given multi-dimensional array has been rearranged to the first dimension in the re-ordered multidimensional array, or the dimension shift value describes by how many dimensions, e.g. by how many array indices, the first dimension, e.g. D2, of the encoded reordered multi-dimensional array should be shifted, e.g. towards a higher dimension number, when performing a decoder-sided reordering, e.g. to obtain the decoder-sided (two times) re-ordered multidimensional array, for example, having dimensions [D0,D1,D2,D3].

According to embodiments of the invention, the encoder is configured to encode a dimension shift value, e.g. “first_tensor_dimension_shift” value, and the dimension shift value, e.g. a scalar value, describes a new position to which the first dimension, e.g. D2, of the encoded re-ordered multi-dimensional array, e.g. having dimensions [D2,D0,D1,D3], should be moved in a decoder.

According to embodiments of the invention, the encoder is configured to encode the dimension-shift value using Exp Golomb code.

According to embodiments of the invention, the encoder is configured to perform the reordering using a single scalar dimension shift value, e.g. first_tensor_dimension shift, as a sole parameter describing a new order of the dimensions in the re-ordered multi-dimensional array.

According to embodiments of the invention, the encoder is configured to perform, for example, only, a single shift of a single dimension to another position, in order to obtain the re-ordered multi-dimensional array.

According to embodiments of the invention, the encoder is configured to set a dimension of an auxiliary array (e.g. of a vector or of a two-dimensional array or of an array having more than two dimensions; e.g. of a tensor or “related tensor” or “corresponding tensor”, e.g. of an “auxiliary” array of bias values or of an “auxiliary” array of batch-norm parameters or of an “auxiliary” array of scaling factors), which is included in the encoded representation, to be equal to the first dimension of the re-ordered multi-dimensional array.

According to embodiments of the invention, the encoder is configured to shift a single dimension of the given multi-dimensional array to a different position, in order to obtain the re-ordered multi-dimensional array.

According to embodiments of the invention, the encoder is configured to obtain the re-ordered multi-dimensional array (e.g. having dimensions [D2,D0,D1,D3]), dimensions of which are, optionally individually, determined by individual ones of a first dimension value, e.g. D2, associated with the first dimension and further dimension values, e.g. D0,D1,D3, associated with further dimensions beyond the first dimension (wherein, for example, each of the first dimension values and the further dimension values may be associated with (and/or define) one dimension of the reordered multi-dimensional array; wherein, for example, the first dimension value may be associated with (and/or define) a first dimension of the reordered multi-dimensional array), on the basis of the given multi-dimensional array. In addition, the encoder is configured to obtain a 2-dimensional matrix, e.g. a matrix having dimensions [D2,(D0*D1*D3)], a first dimension of which is determined by the first dimension value, e.g. D2, and a second dimension of which is determined by a product of the further dimension values, e.g. D0*D1*D2, on the basis of the re-ordered multi-dimensional array. Furthermore, the encoder is configured to encode the 2-dimensional matrix.

According to embodiments of the invention, the encoder is configured to encode neural network parameters using a context-based entropy encoding, for example, using an arithmetic encoding in which one or more contexts for an arithmetic encoding of a given neural network parameter are determined in dependence on a previously encoded neural network parameter, for example in dependence on a previously encoded neural network parameter directly preceding the given neural network parameter in an encoding order. Furthermore, the encoder is configured to determine neural network parameters in the re-ordered multidimensional array to be encoded using a position mapping function, e.g. TensorIndex(tensorDimensions[ ], I, scan), which maps a scalar neural network parameter index, e.g. i, onto a set, e.g. a vector or a (preferably 1-dimensional) array, of dimension indices, for example an array having a number of entries which is equal to a number of dimensions of the reordered multi-dimensional array, for example, onto an array pointing to an i-th element in a row-major scan order of a multi-dimensional array having the dimensions of the reordered multi-dimensional array or onto an array pointing to an i-th element in a block-wise scan order (e.g. scanning subblocks) of a two-dimensional interpretation of the reordered multi-dimensional array, e.g. as defined by function TensorIndex (tensorDimensions[ ], I, scan) for scan>0 when taken in combination with IndexToXY.

According to embodiments of the invention, the encoder is configured to contiguously read a plurality of neural network parameters to be encoded (e.g. D3 neural network parameters), which are directly adjacent with respect to an encoding order (e.g. encoded in a sequence; e.g. encoded considering a context adaptation in dependence on a value of a predecessor), along a given dimension (e.g. a fourth dimension or a highest dimension) of the re-ordered multi-dimensional array, wherein, for example, an index of the given dimension is successively increased or decreased and wherein, for example, indices of the other dimensions remain unchanged.

According to embodiments of the invention, the encoder is configured to obtain the re-ordered multi-dimensional array using a processing, e.g. computation, of the form:

```
for( i = 0; i < Prod( inputTensorDims ); i++ ){
    idxA = TensorIndex( inputTensorDims, i, 0 )
    idxB = ShiftArrayIndexEnc( idxA, firstTensorDimShift )
    reorderedTensor[idxB] = inputTensor[idxA]
  }
```

wherein i is a running variable; wherein Prod(inputTensorDims) is a product of lengths of dimensions of the given multi-dimensional array, and may, for example, be equal to a number of elements of the given multi-dimensional array. Furthermore, TensorIndex (.,.,.) is a function mapping an integer value (e.g. the running variable i; e.g. a scalar integer value referencing elements of the first multi-dimensional array, e.g. in an ascending order) onto a set, e.g. a one-dimensional array or a vector, of array indices (e.g. a set comprising a number of array indices which is equal to a number of dimensions of the given multi-dimensional array) designating an element, e.g. a neural network parameter to be encoded, of the given multi-dimensional array. In addition, inputTensorDims is a set, e.g. a one-dimensional array or a set, of values describing lengths of dimensions of the given multi-dimensional array, idxA is a variable, e.g. representing a set (e.g. a one-dimensional array or a vector) of array indices. Moreover, ShiftArrayIndexEnc (.,.) is a function mapping an input set, e.g. a one-dimensional array or a set, of array indices (e.g. a set comprising a number of array indices which is equal to a number of dimensions of the given multi-dimensional array, e.g. idxA) onto a return set (e.g. a one-dimensional array or a set, e.g. idxB) of array indices, wherein the return set of array indices is a copy of the input set of array indices but with an element of the input set of array indices at a position designated by firstTensorDimShift shifted to a position 0, wherein as an optional feature positions are counted from 0 to a size of the input set of array indices −1. Furthermore, firstTensorDimShift is a dimension shift value, e.g. describing which given dimension of the given multidimensional array should be shifted to a first position, idxB is a variable (e.g. representing a set (e.g. a one-dimensional array or a vector) of array indices), inputTensor [.] is the given multi-dimensional array, reorderedTensor [.] is the re-ordered multi-dimensional array, inputTensor[idxA] is an element of the given multi-dimensional array at a position designated by idxA and reorderedTensor [idxB] is an element of the reordered multi-dimensional array at a position designated by idxB.

According to embodiments of the invention, the encoder is configured to obtain the re-ordered multidimensional array using a function, e.g. TensorIndex(tensorDimensions[ ],i,scan), which maps an integer element index i designating, e.g. uniquely designating, an element of the given multi-dimensional array onto a set, e.g. a one-dimensional array or a vector, of array indices, wherein a returned set of array indices designates an i-th element in a row-major scan order of the given multidimensional array, e.g. of an array with array dimensions designated by the set tensorDimensions[ ], or wherein a returned set of array indices designates an i-th element of a block-wise scan, e.g. using blocks of size bs times bs, of the given multi-dimensional array, in which the given multi-dimensional array is considered as a two-dimensional array, for example of width w and height h, for example elements of which are referenced, for example, by x and y, wherein x and y may, for example, be obtained using a function IndexToXY which maps an scalar integer index i onto a set (e.g. array) of two elements x and y.

According to embodiments of the invention, (for example wherein the encoder is configured to obtain a list of skipped rows) the encoder is configured to encode a list of skipped rows, e.g. row skip list[i], wherein, for example, a number of entries of the list of skipped rows, e.g. tensor2Dheight, may be equal to a length of the first dimension of the re-ordered multidimensional array, e.g. dimensions[0]. Furthermore, the encoder is configured to, optionally selectively, encode neural network coefficients, e.g. QuantParam[idx], of the reordered multidimensional array at respective positions described by respective sets of array indices, e.g. represented by a variable idx, which is, for example, obtained using a function idx=Tensorindex(dimensions, i, scan_order). In addition, the encoder is configured decide, in dependence on an entry of the list of skipped rows referenced, e.g. designated, by a current array index of the first dimension of the reordered multidimensional array, e.g. row_skip_list [idx[0]], whether to encode or not a neural network parameter at a current position, for example designated by a current set of array indices, or for example even a sequence of neural network parameters having a same current array index of the first dimension of the reordered multidimensional array.

According to embodiments of the invention, the encoder is configured to obtain an, optionally reordered, set of array dimensions, for example a one-dimensional array or a vector, entries of which describe lengths of the reordered multidimensional array in different directions, for example using an application of the function ShiftArrayIndexEnc to a set of array dimensions associated with the given multidimensional array. Furthermore, the encoder is configured to encode the, optionally reordered, set, e.g. a one-dimensional array or a vector, of array dimensions, e.g. describing lengths of the reordered multi-dimensional array in different dimensions, e.g. tensor_dimensions[.], wherein, for example, the array dimensions may be Exp-Golomb coded.

According to embodiments of the invention, the encoder is configured to encode neural network parameters, e.g. QuantParam[idx], of the reordered multidimensional array at respective positions described by respective sets of array indices, e.g. represented by a variable idx, which is, for example, obtained using a function idx=Tensorindex(dimensions, i, scan_order). Furthermore, the encoder is configured to obtain the respective sets of array indices using a mapping function (e.g. TensorIndex (tensorDimensions[ ], i, scan), which may, for example, invoke IndexToXY) which maps a scalar integer parameter index, e.g. i, onto the respective set of array indices and which defines a block-wise scan, wherein, for example, subsequent values of the scalar integer parameter index may be associated with subsequently encoded parameter values.

According to embodiments of the invention, the mapping function comprises a mapping of the scalar integer parameter index, e.g. i, onto two coordinates, e.g. x, y, which point to a position that corresponds to a scan index defined by the scalar integer parameter index, e.g. i, when a block, e.g. a two-dimensional array of width w and height h, is scanned in blocks, e.g. in quadratic blocks; e.g. in blocks of size bs times bs. Furthermore, the mapping function comprises a mapping of the two coordinates onto the respective set of array indices.

According to embodiments of the invention, the encoder is configured to encode neural network parameters of the reordered multidimensional array at respective positions described by respective sets of array indices, e.g. represented by a variable idx, which is, for example, obtained using a function idx=Tensorindex(dimensions, i, scan_order). In addition, the encoder is configured to obtain a respective set of array indices on the basis of a scalar integer parameter index i using a function TensorIndex(tensorDimensions[ ], i, scan), the function TensorIndex(tensorDimensions[ ], i, scan) returns an array of array indices with a same number of dimensions as an array tensorDimensions[ ] and the elements of the array of array indices are set to integer values so that the array of array indices can be used as an index pointing to an element of an array, e.g. tensor, with dimensions tensorDimensions[ ] as follows:
If variable scan is equal to 0:
   the returned array of array indices points to the i-th element in row-major scan order of an array [e.g. tensor][e.g. the first multidimensional array] with dimensions defined by tensorDimensions[ ];
If variable scan is greater than 0:
   a variable bs is set to 4<<scan_order;
   a variable h is set to tensorDimensions[0]
      (e.g. to a length of a first dimension of the first multidimensional array);
   a variable w is set to Prod(tensorDimensions)/h
      (e.g. to a product of lengths of the first multidimensional array in different dimensions divided by h, or to a number of elements of the first multidimensional array divided by h);
   two variables x and y are set to the first and second element of an array that is returned
      by calling IndexToXY(w, h, i, bs), respectively;
   the returned array is TensorIndex(tensorDimensions, y*w+x, 0);

In addition, the function IndexToXY(w, h, i, bs) returns an array with two elements, wherein the first element returned by the function IndexToXY is an x coordinate and the second element returned by the function IndexToXY is a y coordinate pointing into a 2D array of width w and height h, x and y point to a position that corresponds to scan index i when the block, e.g. the 2D array of width w and height h, is scanned in blocks of size bs times bs and x and y are derived as follows:
a variable fullRowOfBlocks is set to w*bs;
a variable blockY is set to i/fullRowOfBlocks;
a variable iOff is set to i % fullRowOfBlocks;
a variable currBlockH is set to Min(bs, h−blockY*bs);
a variable fullBlocks is set to bs*currBlockH;
a variable blockX is set to iOff/fullBlocks;
a variable blockOff is set to iOff % fullBlocks;
a variable currBlockW is set to Min(bs, w−blockX*bs)
a variable posX is set to blockOff % currBlockW;
a variable posY is set to blockOff/currBlockW;
The variable x is set to blockX*bs+posX;
The variable y is set to blockY*bs+posY;

Furthermore, tensorDimensions [ ] is an array of values describing lengths of the first multidimensional array in different dimensions and scan is an integer variable describing a scan mode.

In the following methods according to embodiments of the invention are discussed. The methods as described below may be based on the same considerations as the above-described decoders and encoders respectively. The methods can, by the way, be completed with all features and functionalities, which are also described with regard to the decoders and encoders respectively, both individually and taken in combination.

Embodiments according to the invention comprise a method for providing decoded parameters, e.g. “weights” or “coefficients”, of a neural network on the basis of an encoded representation, e.g. on the basis of a bitstream representing the parameters of the neural network in an encoded (e.g. compressed) form. In addition, the method comprises obtaining a first multi-dimensional array (e.g. inputTensor[idxA], wherein idxA is a vector of a plurality of index variables; e.g. A[dm][dn][do][dp], wherein dm, dn, do, dp are index variables, e.g. A[m][n][o][p], wherein m, n, o, p are index variables) comprising a plurality of neural network parameter values, e.g. neural network weights, using a decoding of neural network parameters, for example such that the first multi-dimensional array comprises decoded neural network parameters. Furthermore, the method comprises obtaining a re-ordered multidimensional array (e.g. reorderedTensor[idxB], wherein idxB is a vector of a plurality of index variables; e.g. B[n][o][m][p], wherein n, o, m, p are index variables) using a reordering, in which a first dimension of the first multi-dimensional array, e.g. a dimension of the multi-dimensional array designated by a leftmost array index, is rearranged, e.g. moved, to a different dimension, which is optionally different from a first dimension, in the re-ordered multidimensional array.

Embodiments according to the invention comprise a method providing an encoded representation of parameters, e.g. “weights” or “coefficients”, of a neural network, e.g. in the form of a bitstream representing parameters of the neural network in an encoded (e.g. compressed) form. Furthermore, the method comprises obtaining a re-ordered multidimensional array (e.g. BEnc[o][m][n][p], wherein o, m, n, p are index variables) using a reordering, in which a given dimension of an given multi-dimensional array of neural network parameters (e.g. a given dimension of the multi-dimensional array designated by a given array index, e.g. a third dimension of the given multidimensional array AEnc[m][n][o][p]) is rearranged, e.g. moved, to a first dimension, which is optionally different from the given dimension, in the re-ordered multidimensional array. In addition, the method comprises encoding the reordered multi-dimensional array, e.g. Benc[o][m][n][p], e.g. using an encoding of entries of the reordered multi-dimensional array.

Embodiments comprise a computer program for performing a method according to any of the embodiments as disclosed herein when the computer program runs on a computer.

### BRIEF DESCRIPTION OF THE DRAWINGS

Embodiments of the present invention will be detailed subsequently referring to the appended drawings, in which:

FIG. 1 shows a schematic view of a decoder for providing decoded parameters of a neural network on the basis of an encoded representation, according to embodiments of the invention;

FIG. 2 shows a schematic view of a decoder with further optional features, according to embodiments of the invention;

FIG. 3 shows a schematic view of an encoder for providing an encoded representation of parameters of a neural network, according to embodiments of the invention;

FIG. 4 shows a schematic block diagram of a method for providing decoded parameters of a neural network on the basis of an encoded representation;

FIG. 5 shows a schematic block diagram of a method for providing an encoded representation of parameters of a neural network;

FIG. 6 shows a schematic block diagram of a concept of tensor dimension reordering for the encoding-decoding pipeline according to embodiments of the invention;

FIG. 7 shows a schematic Illustration of a 2-layered feed forward neural network, according to embodiments of the invention;

FIG. 8 shows a schematic Illustration of a uniform reconstruction quantizer according to embodiments of the invention;

FIG. 9 (a),(b) shows schematic examples of locations of admissible reconstruction vectors for the simple case of two weight parameters according to embodiments: (a) Independent scalar quantization; (b) Dependent scalar quantization;

FIG. 10 shows a schematic example for a splitting of the sets of reconstruction levels into two subsets according to embodiments;

FIG. 11 shows a schematic example of NNR encoding pipelines according to embodiments;

FIG. 12 shows a schematic example of a NNR Unit data structure according to embodiments;

FIG. 13 shows a schematic example for an aggregate NNR unit data structure; and

FIG. 14 shows a schematic example of a NNR bitstream data structure according to embodiments.

### DETAILED DESCRIPTION OF THE INVENTION

Equal or equivalent elements or elements with equal or equivalent functionality are denoted in the following description by equal or equivalent reference numerals even if occurring in different figures.

In the following description, a plurality of details is set forth to provide a more throughout explanation of embodiments of the present invention. However, it will be apparent to those skilled in the art that embodiments of the present invention may be practiced without these specific details. In other instances, well-known structures and devices are shown in block diagram form rather than in detail in order to avoid obscuring embodiments of the present invention. In addition, features of the different embodiments described herein after may be combined with each other, unless specifically noted otherwise.

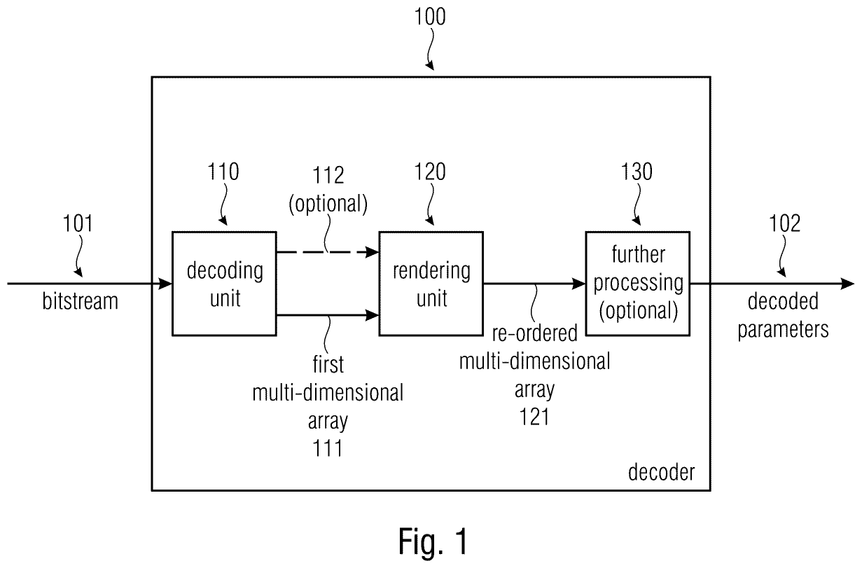

FIG. 1 shows a schematic view of a decoder for providing decoded parameters of a neural network on the basis of an encoded representation, according to embodiments of the invention. FIG. 1 shows decoder 100 comprising a decoding unit 110 and a reordering unit 120. The decoder 100 is provided with a bitstream 101 comprising, for example in a compressed form, an encoded representation of neural network parameters. As an example, the bitstream 101 provided to the decoder 100 may be the encoded representation of the neural network parameters.

As shown in FIG. 1 the decoding unit 110 is provided with the bitstream 101, in order to obtain a first multi-dimensional array 111 comprising a plurality of neural network parameter values. The decoding unit 100 is hence configured to decode the bitstream 101 or at least an encoded representation of the neural network parameters which is part of the bitstream 101.

The first multi-dimensional array 111 is provided to the reordering unit 120. The reordering unit 120 is configured to re-order the first multi-dimensional array 111 to obtain a re-ordered multidimensional array 121. The reordering unit 120 is configured to perform a reordering, in which a first dimension of the first multi-dimensional array 111 is rearranged to a different dimension in the re-ordered multidimensional array 121.

The decoder 100 may provide the re-ordered multidimensional array 121 as the decoded parameters 102 of the neural network. As shown as an optional feature, for providing said decoded parameters of the neural network, the decoder 100 may be configured to further process (e.g. using a plurality of, or at least one optional further processing unit 130) the re-ordered multidimensional array 121 in order to provide the decoded parameters 102 of the neural network.

As an optional feature, as shown in FIG. 1, the decoding unit is configured to decode a dimension shift value 112 from the bitstream 101 and to provide the same to the reordering unit 120. The dimension shift value 112 provides an information to the reordering unit 120 about an extent to which the first dimension of the first multi-dimensional array 111 is to be rearranged, for example shifted, e.g. moved.

Accordingly the dimension shift value 112 may optionally comprise or be an information based on which the reordering unit 120 can determine a new place or position to which the first dimension of the first multi-dimensional array 111 is to be re-arranged, e.g. switched, in the re-ordered multidimensional array 121.

As an optional feature, the dimension shift value 112 is Exp Golomb-coded. Hence, as an optional feature, decoding unit 110 is configured to decode the Exp Golomb-coded dimension shift value 112 from the bitstream 101.

It is to be noted that the dimension shift value 112 may, for example, be a single scalar. As an optional feature, the single scalar may be a sole parameter based on which the new order of the dimensions in the re-ordered multi-dimensional array 121 are specified.

Furthermore, it is to be noted that according to some embodiments, reordering unit 120 may be configured to perform a single shift of a single dimension to another position, in order to obtain the re-ordered multi-dimensional array 121.

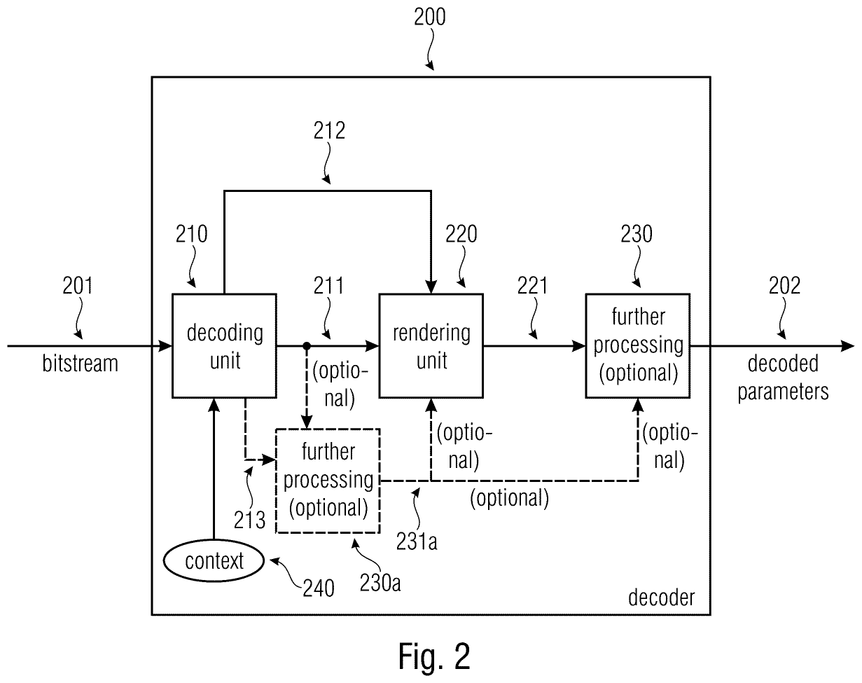

FIG. 2 shows a schematic view of a decoder with further optional features, according to embodiments of the invention. FIG. 2 shows decoder 200 comprising a decoding unit 210 and a reordering unit 220. The decoder 200 is provided with a bitstream 201 in order to obtain a first multi-dimensional array 211. The first multi-dimensional array 211 is provided to the reordering unit 220 which is configured to re-order the first multi-dimensional array 211 to obtain a re-ordered multidimensional array 221. The decoder 200 may provide the re-ordered multidimensional array 221 as the decoded parameters 202 of the neural network. As shown as an optional feature, for providing said decoded parameters of the neural network, the decoder 200 may be configured to further process (e.g. using a plurality of, or at least one optional further processing unit 230) the re-ordered multidimensional array 221 in order to provide the decoded parameters 202 of the neural network.

For the details of the above mentioned features and functionalities of the embodiments shown in FIG. 2, for the sake of brevity, reference is made to the features and functionalities as discussed in the context of FIG. 1. It is to be noted that similar or corresponding features as shown in FIG. 2 may optionally comprise same or corresponding functionalities and/or details, as discussed in the context of FIG. 1. In addition, all features marked and/or discussed as optional in FIG. 1 are optional for embodiments according to FIG. 2 as well.

As shown in FIG. 2, the reordering unit 220 is provided, as an optional feature, with a dimension-shift value 212.

Furthermore, as an optional feature, the first multi-dimensional array 211 is provided to an optional further processing unit 230a. The further processing unit 230a is configured to derive a dimension of an auxiliary array from a first dimension of the first multi-dimensional array 211.

As an example, the first multi-dimensional array 211 may be a weight tensor and the bitstream 201 may comprise an encoded representation of float parameter tensors comprising the (optionally decomposed) weight tensor and, optionally, local scaling parameters, biases, and batch norm parameters that form a block in the model architecture. In other words, a weight tensor and several corresponding tensors, e.g. biases, batch-norm parameters and scaling factors, may be included in the bitsteam 201 together, for example in a single compressed data unit, e.g. NDU. According to such an example, the auxiliary array may comprise respective corresponding tensors, or at least values thereof, e.g. in an adapted shape.

As an example, since the corresponding tensors may be related to the weight tensor, their dimensions can be derived, e.g. using further processing unit 230a, from the (weight) tensor dimensions. As an example, the biases, batch-norm parameters and scaling factors may, e.g. preferably, be 1D tensors with a length equal to the number of output channels (e.g. for fully-connected layers) or the number of filters (e.g. convolutional layers) of the weight tensor, respectively. For deriving these dimensions, the first dimension of a decoded weight tensor may be determined as the length of the 1D tensors. Hence, the decoded weight tensor may be ordered, such that the first dimension corresponds to the number of output channels or filters.

In other words, the first multi-dimensional array 211, e.g. being such a weight tensor, may be ordered, such that the first dimension corresponds to the number of output channels or filters. Accordingly, one or more auxiliary arrays may be determined to represent the biases, batch-norm parameters and scaling factors. A respective information 213 for a determination of such auxiliary arrays may be provided by the decoding unit 213 to the further processing unit 230a.

The first multi-dimensional array 211, e.g. in the form of the weight tensor representation, may have hence been rearranged on an encoder side, so that the first dimension of the encoded representation of the first multi-dimensional array in the bitstream 201 allows to derive said dimension of the auxiliary array from the first dimension of the first multi-dimensional array 211. After a determination of said dimension, the first multi-dimensional array 211 may be reordered to the state it was before encoding using reordering unit 220. As optionally shown, an information 231a comprising such an auxiliary array may be provided for the determination of the decoded neural network parameters 202.

As an optional feature, the reordering unit 220 is configured to shift a single dimension of the first multi-dimensional array to a different position, in order to obtain the re-ordered multi-dimensional array. For example, allowing arbitrary dimension orders could induce a significant signaling overhead, hence with a shift of a single dimension to another position signaling overhead can be kept low.

As an optional feature, decoding unit 210 is configured to perform a context based decoding. In particular, decoding unit 210 is configured to decode encoded neural network parameters using a context-based entropy decoding. Therefore context information 240 is provided to the decoding unit 210. In particular, as an optional feature, the decoding unit 210 is configured to determine positions of the decoded neural network parameters in the first multi-dimensional array 211 using a position mapping function which maps a scalar neural network parameter index onto a set of dimension indices.

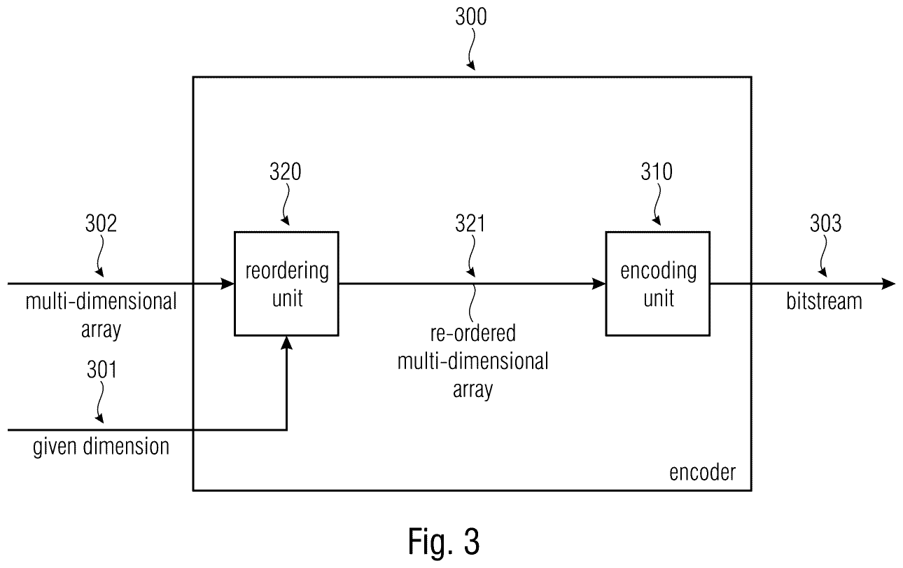

FIG. 3 shows a schematic view of an encoder for providing an encoded representation of parameters of a neural network, according to embodiments of the invention. FIG. 3 shows encoder 300 comprising an encoding unit 310 and a reordering unit 320.

The reordering unit is configured to obtain a re-ordered multidimensional array 321 using a reordering, in which a given dimension 301 of a given multi-dimensional array 302 of neural network parameters is rearranged to a first dimension in the re-ordered multidimensional array 321. Furthermore, the encoding unit 310 is configured to encode the reordered multi-dimensional array 321, for example as shown to a bitstream 303.

As explained before, an encoder according to embodiments of the invention may be based on the same considerations as a corresponding decoder. Hence, for the sake of brevity, with regard to additional, optional features, reference is made to the embodiments comprising decoders as disclosed above, and as will be disclosed in the following. Hence, it is to be noted that an encoder according to embodiments, e.g. encoder 300, may comprise any or all of the features as disclosed in the context of any of the inventive decoders, both individually and taken in combination.

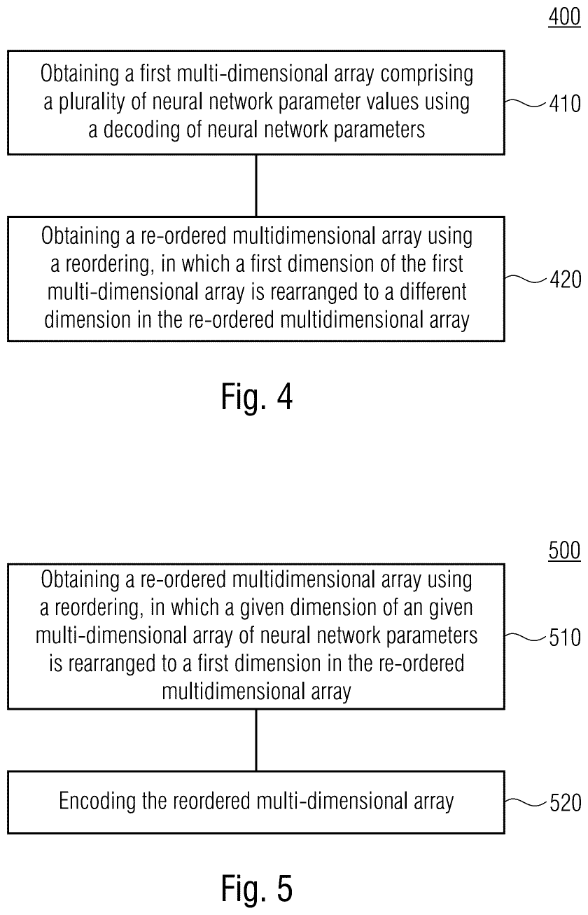

FIG. 4 shows a schematic block diagram of a method for providing decoded parameters of a neural network on the basis of an encoded representation. The method 400 comprises obtaining, 410, a first multi-dimensional array comprising a plurality of neural network parameter values using a decoding of neural network parameters and obtaining, 420, a re-ordered multidimensional array using a reordering, in which a first dimension of the first multi-dimensional array is rearranged to a different dimension in the re-ordered multidimensional array.

FIG. 5 shows a schematic block diagram of a method for providing an encoded representation of parameters of a neural network. The method 500 comprises obtaining, 510, a re-ordered multidimensional array using a reordering, in which a given dimension of an given multi-dimensional array of neural network parameters is rearranged to a first dimension in the re-ordered multidimensional array and encoding, 520, the reordered multi-dimensional array.

In the following, different inventive embodiments and aspects will be described in a chapter “Proposal—Tensor dimension reordering by tensor dimension shift”, in a chapter “Method for Tensor Dimension Reordering for Coding of Neural Networks” and in a chapter “Proposed updated draft of planned international standard ISO/IEC 15938-17” and in their respective subchapters.

Also, further embodiments will be defined by the enclosed claims.

It should be noted that any embodiments as defined by the claims can optionally be supplemented by any of the details (features and functionalities and details) described in the above mentioned chapters and/or subchapters.

Also, the embodiments described in the above mentioned chapters and/or subchapters can be used individually, and can also be supplemented by any of the features in another chapter or subchapter, or by any feature included in the claims.

Also, it should be noted that individual aspects described herein can be used individually or in combination. Thus, details can be added to each of said individual aspects without adding details to another one of said aspects.

It should also be noted that the present disclosure describes, explicitly or implicitly, features usable in a neural network encoder (Encoder for providing an encoded representation of parameters of a neural network) and in a neural network decoder (Decoder for providing decoded parameters of a neural network parameters on the basis of an encoded representation). Thus, any of the features described herein can be used in the context of a neural network encoder and in the context of a neural network decoder.

Moreover, features and functionalities disclosed herein relating to a method can also be used in an apparatus (configured to perform such functionality). Furthermore, any features and functionalities disclosed herein with respect to an apparatus can also be used in a corresponding method. In other words, the methods disclosed herein can optionally be supplemented by any of the features and functionalities described with respect to the apparatuses.

Also, any of the features and functionalities described herein can be implemented in hardware or in software, or using a combination of hardware and software, as will be described in the section “implementation alternatives”.

### Proposal—Tensor Dimension Reordering by Tensor Dimension Shift

In the following, embodiments related to “[NNC] Tensor dimension reordering by tensor dimension shift” are discussed.

### 1 Abstract (Example, Details are Optional)

According to an aspect, this input contribution proposes a method for reordering tensor dimensions, for example to address problems related to using NNR_PT_BLOCK. For example, at the encoder, tensor dimension are rearranged, while, for example, at the decoder this operation is inverted to restore the original order of dimensions. For example, for the standard-relevant part (i.e. at the decoder), tensor dimensions are reordered in a decoded weight tensor by shifting the first dimension to its original position after decoding. For example, this addresses two problems. Firstly, for example, compressed data unit type NNR_PT_BLOCK derives the dimensions, for example, of the bias, and/or batch norm, and/or local scaling parameters from the first dimension of the weight tensor.

For example, a reordering of tensor dimensions after decoding enables the encoder to process tensors with an arbitrary order of dimensions. Secondly, the order of the tensor dimension may not be optimal for efficient encoding.

### 2 Problem Description

### 2.1 Problem 1: Tensor Dimension Derivation for NNR_PT_BLOCK

For example, the current working draft [1] allows to code several float parameter tensors within a single NDU as a block (for example, nnr_compressed_data_unit_payload_type==NNR_PT_BLOCK). The block may, for example, include a (optionally decomposed) weight tensor and, optionally, local scaling parameters, and/or biases and/or batch norm parameters. For example, the tensor dimensions coded in the NDU are related to the weight tensor. For example, the dimensions for the other parameter tensors are then derived as follows. For example, each tensor is 1 D and its length is, for example, equal to the first dimension of the weight tensor. Here, it is, for example, assumed that the first dimension of the weight tensor corresponds to the number of output channels (in the case of fully-connected layers) or to the number of filters (in the case of convolutional layers). Hence, whenever the dimensions of the weight tensor to be coded are arranged in another order, the tensor dimension derivation for other parameters in the block may fail, resulting, for example, in a non-decodable bitstream.

### 2.2 Problem 2: Inefficient Processing

For example, for the coding process each tensor to be compressed is (optionally) converted to a 2D matrix, for example, with the first dimension being equal to the first dimension of the tensor and the second dimension being equal to the product of all the other tensor dimensions. For example, depending on the first dimension of the tensor this may, for example, produce rather “slim” matrices, e.g. if the first dimension denotes the width or height of a 3×3 filter kernel. This may, for example, not be optimal for the subsequent encoding stage, resulting in a reduced coding efficiency or inefficient processing, especially for block scanning orders (scan_order>0) where each tensor is decomposed into blocks (e.g. 4×4, 8×8, etc.).

### 3 Tensor Dimension Reordering by Tensor Dimension Shift

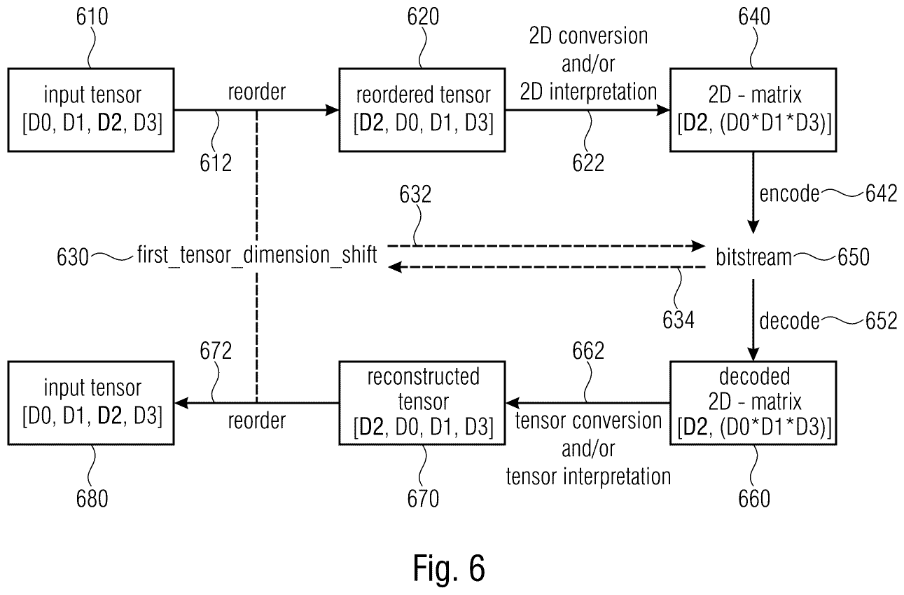

In order to address one or more of the problems described in section 2, according to an aspect of the invention, this contribution proposes a method for tensor dimension reordering by shifting a single tensor dimension to another position. For this, for example, the encoder reorders the tensor such, that, for example, the tensor dimension representing the number of output channels is the first dimension after reordering. For example, from a decoder point of view, the decoded tensor is reordered by shifting the first dimension of the tensor to another position, indicated by a single value. As an example, the concept is illustrated in FIG. 6. FIG. 6 shows a schematic block diagram of a concept of tensor dimension reordering for the encoding-decoding pipeline according to embodiments of the invention. For example, each box corresponds to a tensor/matrix representation with the dimensions given in square brackets. For example, Solid black arrows/lines denote the general processing flow and dashed lines/arrows the processing flow of syntax element first_tensor_dimension_shift. It should be noted that the usage of a 2D-matrix is optional.

As shown in FIG. 6 an input tensor 610 may be, as an example, a four-dimensional tensor with D0 elements in a first dimension, D1 elements in a second dimension, D2 elements in a third dimension and D3 elements in a third dimension. Elements may, for example, be neural network parameters. As shown, for example using an encoder 300 as shown in FIG. 3, for example a reordering unit 320 thereof, the input tensor 610 (which may be an example, of the multi-dimensional array 302) may be reordered 612 to obtain a re-ordered tensor 620 (which may be an example of the multidimensional array 620). As shown, a given dimension, in this case D2, may be re-ordered to a first dimension in the re-ordered tensor 620. Therefore, as an optional feature, a first_tensor_dimension_shift 630 (which may be an example of a dimension shift value) is used.

As already discussed, such a dimension shift value may describe which given dimension of the given multi-dimensional array has been rearranged to the first dimension in the re-ordered multidimensional array, or by how many dimensions the first dimension of the encoded reordered multi-dimensional array should be shifted when performing a decoder-sided reordering. Furthermore, the dimension shift value may describe a new position to which the first dimension of the encoded re-ordered multi-dimensional array should be moved in a decoder. Moreover, a respective encoder, e.g. 300, may be configured to encode, 632, the dimension-shift value optionally using Exp Golomb code to a bitstream 650 (which may be an example for the bitstream 102, 202 and/or 303). In particular, the dimension shift value may optionally be a single scalar dimension shift value as a sole parameter for the reordering 612. As shown in FIG. 6 the reordering 612 may comprise a single shift of a single dimension, D2, to another position, namely the first position, in order to obtain the re-ordered multi-dimensional array in the form of the reordered tensor 620.

Based on the reordered tensor 620, as an optional feature, using a 2D-conversion 622 or a 2D interpretation 622, a 2D-matrix 640 or a 2D-matrix interpretation 640 may optionally be obtained. As shown, a first dimension of the 2-dimensional matrix 640 may be determined by the first dimension of the re-ordered multidimensional array 620, so that a second dimension of the 2-dimensional matrix 640 is determined by a product of the further dimension values of the re-ordered multi-dimensional array 620 (in the form of the reordered tensor 620).

As shown, the 2-dimensional matrix 640 may then be encoded, 642, in a bitstream 650. It is to be noted that the 2D conversion 622 or 2D interpretation 622 is only optional, such that the reordered tensor 620 may optionally be directly encoded.

In any case, optionally, a respective encoder, e.g. 300 may use context-based entropy encoding for the encoding of the neural network parameters.

A decoder, e.g. decoder 100, 200, receives the bitstream 650 which, as shown optionally, comprises the dimension shift value information 630. For example, using a decoding unit 110, 210, the bitstream is decoded, 652, in order to obtain a decoded 2D-Matrix 660 or a decoded 2D-Matrix Interpretation 660 and in order to obtain, using a decoding, 634, the information about the dimension shift 630. Hence, in other words, a 2-dimensional matrix 660 is obtained, a first dimension of which is determined by a first dimension value and a second dimension of which is determined by a product of a plurality of further dimension values on the basis of the encoded representation.

Based thereon and on a tensor conversion 662 or a tensor interpretation 662, the decoder obtains a reconstructed tensor 670 (which may be an example of the first multi-dimensional array 111, 211) which, as an example, corresponds to the reordered tensor 620. In simple words, based on the 2-dimensional matrix 660, an original number of dimensions is reconstructed, wherein the first dimension of the matrix 660 corresponds to the first dimension of the tensor 670. Thereafter, for example using a reordering unit 120, 220, the reconstructed tensor 670 is reordered, 672, in order to obtain the input tensor 680 which corresponds, or is optionally equal to, input tensor 610. Therefore, first_tensor_dimension_shift 630 (e.g. information 112, 212) is, as an example, used.

### 3.1 Proposed Syntax (Example, Details are Optional)

For this, for example, a new syntax element first_tensor_dimension_shift is decoded from the bitstream (for example, denoting the new position of the first dimension) whenever count_tensor_dimensions is greater than 1. For example, the value of first_tensor_dimension_shift is non-negative and smaller than the value of count_tensor_dimensions. For example, a value equal to zero is equivalent to no reordering. For example, if first_tensor_dimension_shift is not present, it is inferred to be zero.

### 3.2 Reordering Method—Examples

For example, the syntax and the reordering method are provided in the working draft text attached to this document (Proposed updated draft of planned international standard ISO/IEC 15938-17)). For simplicity the reordering method is illustrated by two examples using a 2D and a 4D tensor, respectively.

### 3.2.1 Example: 2D-Tensor, First_Tensor_Dimension_Shift==1

Assuming, for example, a 2D-tensor A with tensor dimensions [D1,D0] and first_tensor_dimension_shift equal to one have been decoded from the bitstream and the elements of A can be accessed by A[m][n] (with m∈[0,D1−1] and n E [0,D0−1]), the reordering process is, for example, as follows:
For example, Initialize reordered tensor B with dimensions [D0,D1]
For Example, Set values of B according to:

```
for( m = 0; m < D1; m++ ) {
  for( n = 0; n < D0; n++ ) {
    B[n][m] = A[m][n]
  }
}
```

For example, for a 2D tensor the reordered tensor B is equal to the transposed tensor A.

### 3.2.2 Example: 4D-Tensor, First_Tensor_Dimension_Shift==2

For example, assuming a 4D-tensor A with tensor dimensions [D2,D1,D0,D3] and first_tensor_dimension_shift equal to two have been decoded from the bitstream and the elements of A can be accessed by A[m][n][o][p] (with m∈[0,D2−1], n E [0,D1−1], o∈[0,D0−1] and p∈[0,D3−1]), the reordering process is, for example, as follows:
For example, Initialize reordered tensor B with dimensions [D0,D1,D2,D3]
For example, Set values of B according to:

```
for( m = 0; m < D2; m++ ) {
  for( n = 0; n < D1; n++ ) {
    for( o = 0; o < D0; o++ ) {
      for( p = 0; p < D3; p++ ) {
        B[n][o][m][p] = A[m][n][o][p]
      }
    }
  }
}
```

### 4 Recommendation

According to an aspect of the invention, we recommend adopting the proposed technology to the working draft.

### 5 References for Chapter “Proposal—Tensor Dimension Reordering by Tensor Dimension Shift”

[1] MPEG, “Working Draft 3 on Incremental Compression of Neural Networks”, Document of ISO/IEC JTC1/SC29/WG04, WG04N0178, OnLine, January 2022

### Method for Tensor Dimension Reordering for Coding of Neural Networks

An aspect of the invention relates to a method for reordering the dimensions of (N-dimensional) neural network parameter tensors, for example, in order to enable coding of multiple tensors in a block and/or efficient processing in a neural network compression framework, as for example the MPEG-7 part 17 standard for compression of neural networks for multimedia content description and analysis [2]. Such a framework (e.g. MPEG-7 part 17) may, for example, provide several compression tools comprising, for example, quantization, and/or lossless encoding and lossless decoding methods. Usually (but not necessarily), for efficient processing a tensor is interpreted such that it is equivalent to a 1-dimensional (1D) or 2-dimensional (2D) representation, internally. The shape of this 1 D/2D representation is determined, for example, by the original tensor dimensions and their order. Furthermore, this shape may, for example, also affect the efficiency of the compression and processing pipeline.

Thus, for example, a reordering of the tensor dimensions, as described in this invention, may improve the efficiency.

According to an aspect, the invention is mainly targeted on lossy and lossless coding of layers of neural network parameters in neural network compression, but it can optionally also be applied to other areas of lossy and lossless coding.

The methodology of the apparatus (or of a system) may, for example, be divided into different main parts, which consist of the following:
1. Quantization
2. Lossless Encoding
3. Lossless Decoding

However, it is not necessary to have all these main parts.

In order to understand the main advantages of the invention, we will firstly give a brief introduction on the topic of neural networks and on related methods for parameter coding.

### 1 Application Area (all Details are Optional)

In their most basic form, neural networks constitute, for example, a chain of affine transformations followed by an element-wise non-linear function. They may, for example, be represented as a directed acyclic graph, as depicted in the image below. For example, each node entails a particular value, which is, for example, forward propagated into the next node, for example, by multiplication with the respective weight value of the edge. For example, all incoming values are then simply aggregated.

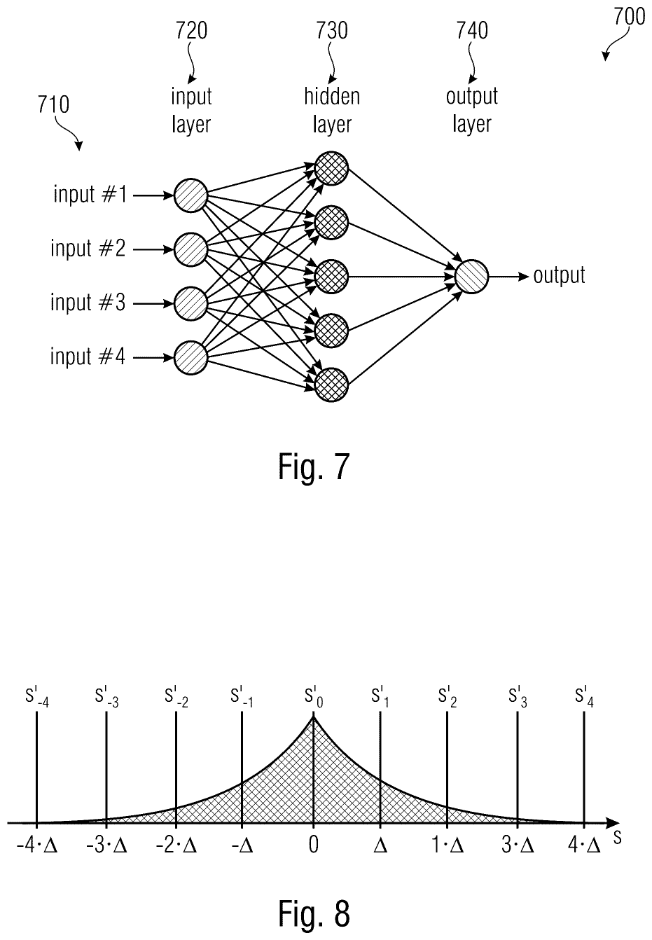

FIG. 7 shows a schematic Illustration of a 2-layered feed forward neural network, according to embodiments of the invention. FIG. 7 shows a graph representation of an example of a feed forward neural network. Specifically, this 2-layered neural network, 700, is a non linear function which maps a 4-dimensional input vector, 710, into the real line. Therefore, the network 700 comprise an input layer 720, a hidden layer 730 and an output layer 740.

Mathematically, the above neural network would, for example, calculate the output in the following manner:

$$output = σ ( {W}_{2} \cdot σ ( {W}_{1} \cdot input ) )$$

Where, for example, W2 and W1 are the neural networks weight parameters (edge weights) and sigma is, for example, some non-linear function. For instance, so-called convolutional layers may also be used by casting them as matrix-matrix products as described in [1]. For example, incremental updates usually aim at providing updates for the weights of W1 and W2 and can, for example, be the outcome of an additional training process. For example, the updated versions of W2 and W1 usually lead to a modified output. From now on, we will refer as inference the procedure of calculating the output from a given input. Also, we will call intermediate results as hidden layers or hidden activation values, which constitute, for example, a linear transformation+element-wise non-linearity, e.g., such as the calculation of the first dot product+non-linearity above.

Usually, neural networks are, for example, equipped with millions of parameters, and may thus, for example, require hundreds of MB in order to be represented. Consequently, they may, for example, require high computational resources in order to be executed since their inference procedure involves, for example, computations of many dot product operations between large matrices. Hence, it is, for example, of high importance to reduce the complexity of performing these dot products.

### 2 Conventional Solutions

It should be noted that optionally, any of the features functionalities and details form this section “conventional solutions” may be used in embodiments according to the present invention, both individually and taken in combination.

Moreover, it should be noted that usually (but not necessarily) parameters (e.g. parameters of a neural network, like weights of the neural network) are in N-dimensional tensors (or, equivalently, in N-dimensional arrays).

### 2.1 Tensor Representation of Neural Networks (all Details are Optional)

For example, the parameters of neural networks are usually (but not necessarily) represented by N-dimensional tensors, where the dimension N depends, for example, on the model architecture and application. For example, in the cases, where N is equal to 1 and N is equal to 2 this corresponds to vectors and matrices, respectively. The size of the tensor in each dimension can, for example, be represented using an array of length N as follows [D₀, D₁, . . . , D_{N-1}]. For example, for processing in the encoder and the decoder of the MPEG-7 part 17 standard, all tensors with N greater or equal to 3 are, for example, (preferably, but not necessarily) interpreted as if they are 2D-matrices with dimensions equal to [D0, (D₁′, D₂, . . . , D_{N-1}]. If not available at the decoder, the standard specifies a method to transmit the tensor dimensions in the bitstream, such that the original tensor shapes can, for example, be reconstructed after decoding. For the methods described in the following it can be assumed, for example, that the weight parameters are represented or interpreted as vectors or 2D matrices, respectively.

### 2.2 Related Methods for Quantization and Entropy Coding (all Details are Optional)

For example, MPEG-7 part 17 standard for compression of neural networks for multimedia content description and analysis [2] provides different methods for quantization of the neural network parameters, as for example independent scalar quantization and dependent scalar quantization (DQ or also trellis-coded quantization TCQ). Additionally, it specifies, for example, an entropy quantization scheme also known as deepCABAC [7]. These methods, which can optionally be used in embodiments according to the invention, are briefly summarized for a better understanding. Details can, for example, be found in [2].

### 2.2.1 Scalar Quantizers (Examples)

For example, the neural network parameters can be quantized using scalar quantizers. For example, as a result of the quantization, the set of admissible values for the parameters is reduced. In other words, the neural network parameters are, for example, mapped to a countable set (in practice, a finite set) of so-called reconstruction levels. The set of reconstruction levels represents, for example, a proper subset of the set of possible neural network parameter values. For example, for simplifying the following entropy coding, the admissible reconstruction levels are, for example, represented by quantization indexes, which are, for example, transmitted as part of the bitstream. At the decoder side, the quantization indexes are mapped to reconstructed neural network parameters. For example, the possible values for the reconstructed neural network parameters correspond to the set of reconstruction levels. At the encoder side, the result of scalar quantization is, for example, a set of (integer) quantization indexes.

In this application, for example, uniform reconstruction quantizers (URQs) are used. As an example, their basic design is illustrated in FIG. 8. FIG. 8 shows a schematic Illustration of a uniform reconstruction quantizer according to embodiments of the invention. For example, URQs have the property that the reconstruction levels are equally spaced. The distance A between two neighboring reconstruction levels is referred to as quantization step size. For example, one of the reconstruction levels is equal to 0. Hence, the complete set of available reconstruction levels is, for example, uniquely specified by the quantization step size Δ. For example, the decoder mapping of quantization indexes q to reconstructed weight parameters t′ is, in principle, given by the simple formula

$${t}^{′} = q \cdot Δ .$$

In this context, the term “independent scalar quantization”, for example, refers to the property that, given the quantization index q for any weight parameter, the associated reconstructed weight parameter t′ can be determined independently of all quantization indexes for the other weight parameters.

### 2.2.2 Dependent Scalar Quantization (Examples, all Details are Optional)

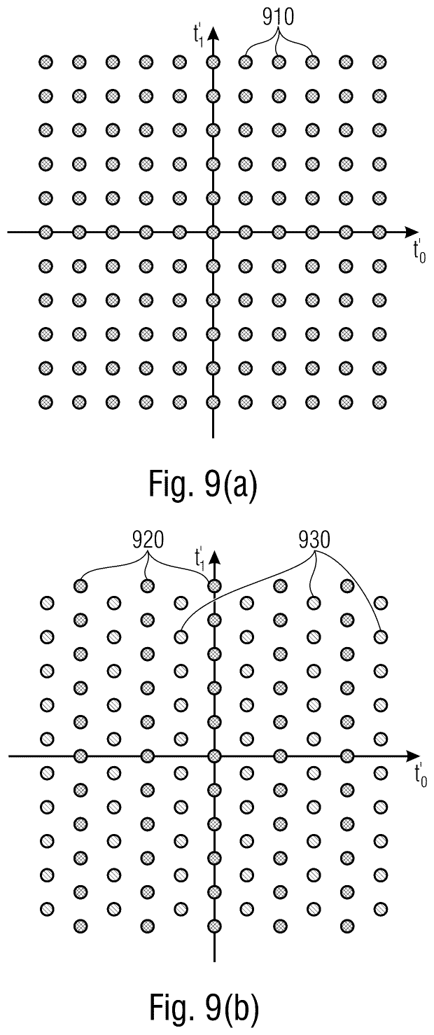

In dependent scalar quantization (DQ) the admissible reconstruction levels for a neural network parameter depend on the selected quantization indexes for the preceding neural network parameters in reconstruction order. The concept of dependent scalar quantization is combined with a modified entropy coding, in which the probability model selection (or, alternatively, the codeword table selection) for a neural network parameter depends on the set of admissible reconstruction levels. The advantage of the dependent quantization of neural network parameters is that the admissible reconstruction vectors are denser packed in the N-dimensional signal space (where N denotes the number of samples or neural network parameters in a set of samples to be processed, e.g. a layer). The reconstruction vectors for a set of neural network parameters refer to the ordered reconstructed neural network parameters (or, alternatively, the ordered reconstructed samples) of a set of neural network parameters. The effect of dependent scalar quantization is illustrated in FIG. 9 for the simplest case of two neural network parameters. FIG. 9 shows schematic examples of locations of admissible reconstruction vectors for the simple case of two weight parameters according to embodiments: (a) Independent scalar quantization; (b) Dependent scalar quantization. FIG. 9a shows the admissible reconstruction vectors (which represent points, 910, in the 2d plane) for independent scalar quantization. As it can be seen, the set of admissible values for the second neural network parameter t′₁ does not depend on the chosen value for the first reconstructed neural network parameter t′₀. FIG. 9b shows an example for dependent scalar quantization. Note that, in contrast to independent scalar quantization, the selectable reconstruction values for the second neural network parameter t′₁ depend on the chosen reconstruction level for the first neural network parameter t′₀. In the example of FIG. 9b, there are two different sets of available reconstruction levels for the second neural network parameter t′₁ (illustrated by different colors, e.g. set 920 and set 930). If the quantization index for the first neural network parameter t′₁ is even ( . . . , −2, 0, 2, . . . ), any reconstruction level of the first set (blue points, 920) can be selected for the second neural network parameter t′₁. And if the quantization index for the first neural network parameter t′₀ is odd ( . . . , −3, −1, 1, 3, . . . ), any reconstruction level of the second set (red points, 930) can be selected for the second neural network parameter t′₁. In the example, the reconstruction levels for the first and second set are shifted by half the quantization step size (any reconstruction level of the second set is located between two reconstruction levels of the first set).

The dependent scalar quantization of neural network parameter has the effect that, for a given average number of reconstruction vectors per N-dimensional unit volume, the expectation value of the distance between a given input vector of neural network parameters and the nearest available reconstruction vector is reduced. As a consequence, the average distortion between the input vector of neural network parameters and the vector reconstructed neural network parameters can be reduced for a given average number of bits. In vector quantization, this effect is referred to as space-filling gain. Using dependent scalar quantization for sets of neural network parameters, a major part of the potential space-filling gain for high-dimensional vector quantization can be exploited. And, in contrast to vector quantization, the implementation complexity of the reconstruction process (or decoding process) is comparable to that of the related neural network parameter coding with independent scalar quantizers.

As a consequence of the above mentioned aspects, DQ usually achieves the same distortion level at lower bitrates.

### 2.2.3 D0 in MPEG-7 Part 17 (Examples, all Details are Optional)

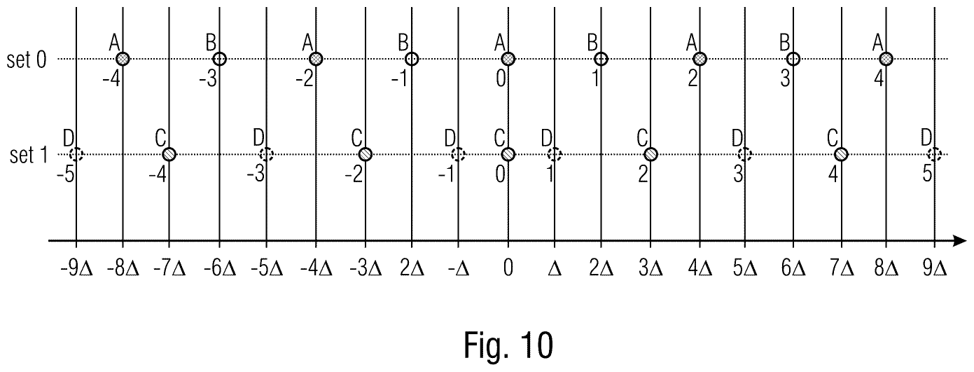

The MPEG-7 part 17 standard for compression of neural networks for multimedia content description and analysis, employs two quantizers Q1 and Q2 with different sets of reconstruction levels. Both sets contain integer multiples of a quantization step size Δ. Q1 contains all the even multiples of the quantization step size and 0 and Q2 contains all the odd multiples of the quantization step size and 0. This splitting of reconstruction sets is illustrated in FIG. 10. FIG. 10 shows a schematic example for a splitting of the sets of reconstruction levels into two subsets according to embodiments. The two subsets of the quantization set 0 are labeled using “A” and “B”, and the two subsets of quantization set 1 are labeled using “C” and “D”.

A process for switching between the sets determines the quantizer to be applied, based on chosen quantization indices for preceding neural network parameters in reconstruction order, or more precisely on the parity of the previously encoded quantization indices. This switching process is realized by a finite state machine with 8 states (as presented in Table 16), where each state is associated with one of the quantizers Q1 or Q2.

TABLE 16
Preferred example of a state transition
table for a configuration with 8 states.

| | | |
|---|---|---|
| | quantization set | |
| current | for current | next state |

| state | coefficient | path 0 | path 1 |
|---|---|---|---|
| 0 | 0 | 0 | 2 |
| 1 | 1 | 7 | 5 |
| 2 | 0 | 1 | 3 |
| 3 | 1 | 6 | 4 |
| 4 | 0 | 2 | 0 |
| 5 | 1 | 5 | 7 |
| 6 | 0 | 3 | 1 |
| 7 | 1 | 4 | 6 |

Using the concept of state transition, the current state and, thus, the current quantization set is uniquely determined by the previous state (in reconstruction order) and the previous quantization index.

### 2.2.4 Entropy Coding (Examples, all Details are Optional)

As a result of the quantization, applied in the previous step, the weight parameters are mapped to a finite set of so-called reconstruction levels. Those can be represented by an (integer) quantizer index (also referred to as parameter level or weight level) and the quantization step size, which may, for example, be fixed for a whole layer. In order to restore all quantized weight parameters of a layer, the step size and dimensions of the layer may be known by the decoder. They may, for example, be transmitted separately.

In this section, a scanning may be described. For example, a section for block coding (NNR_PT_BLOCK) may be described here.

### 2.2.4.1 Scanning of Quantization Indices (Examples, all Details are Optional)

The quantization indexes (integer representation) are then transmitted using entropy coding techniques. Therefore, a layer of weights is mapped onto a sequence of quantized weight levels using a scan. For this, five different scan orders are specified in the standard, denoted by syntax element scan_order. The first (scan_order==0) represents a row first scan, starting with the upper-most row of the matrix, encoding the contained values from left to right. In this way, all rows are encoded from the top to the bottom. All other scan orders (scan_order>0) correspond to block scanning orders. Here, the matrix is decomposed into blocks of size 4×4 (scan_order==1), 8×8 (scan_order==2), 16×16 (scan_order==3) or 32×32 (scan_order==4) and the blocks are processed block-row wise. That is, starting with the upper-most block row, processing the blocks from left to right. Processing a block means scanning its values in a row first manner (rows from top to down, each row from left to right).

### 2.2.4.2 Encoding of Quantization Indexes with Context-Adaptive Binary Arithmetic Coding (CABAC) (Examples, all Details are Optional)

For coding of the levels CABAC (Context-Adaptive Binary Arithmetic Coding) is used. Refer to [2] for details. So, a quantized weight level q is decomposed in a series of binary symbols or syntax elements, which then may be handed to the binary arithmetic coder (CABAC).

In the first step, a binary syntax element sig_flag is derived for the quantized weight level, which specifies whether the corresponding level is equal to zero. If the sig_flag is equal to one a further binary syntax element sign_flag is derived. The bin indicates if the current weight level is positive (e.g., bin=0) or negative (e.g., bin=1).

Next, a unary sequence of bins is encoded, followed by a fixed length sequence as follows:

A variable k is initialized with a non-negative integer and X is initialized with 1<<k.

One or more syntax elements abs_level_greater_X are encoded, which indicate, that the absolute value of the quantized weight level is greater than X. If abs_level_greater_X is equal to 1, the variable k is updated (for example, increased by 1), then 1<<k is added to X and a further abs_level_greater_X is encoded. This procedure is continued until an abs_level_greater_X is equal to 0. Afterwards, a fixed length code of length k suffices to complete the encoding of the quantizer index. For example, a variable rem=X−|q| could be encoded using k bits. Or alternatively, a variable rem′ could be defined as

$${rem}^{′} = ( 1 << k ) - rem - 1 {rem}^{′} = ( 1 << k ) - rem - 1$$

which is encoded using k bits. Any other mapping of the variable rem to a fixed length code of k bits may alternatively be used.

When increasing k by 1 after each abs_level_greater_X, this approach is identical to applying exponential Golomb coding (if the sign_flag is not regarded).

Additionally, if the maximum absolute value abs_max is known at the encoder and decoder side, encoding of abs_level_greater_X syntax elements may be terminated, when for the next abs_Level_greater_X to be transmitted, X>=abs_max holds.

### 2.2.4.3 Decoding of Quantization Indexes with Context-Adaptive Binary Arithmetic Coding (CABAC) (Examples, all Details are Optional)

Decoding of the quantized weight levels (integer representation) works analogously to the encoding. The decoder first decodes the sig_flag. If it is equal to one, a sign_flag and a unary sequence of abs_level_greater_X follows, where the updates of k, (and thus increments of X) must follow the same rule as in the encoder. Finally, the fixed length code of k bits is decoded and interpreted as integer number (e.g. as rem or rem′, depending on which of both was encoded). The absolute value of the decoded quantized weight level |q| may then be reconstructed from from X, and form the fixed length part. For example, if rem was used as fixed-length part, |q|=X−rem. Or alternatively, if rem′ was encoded

$$\vert l \vert = X + 1 + {rem}^{′} - ( 1 << k ) \vert q \vert = X + 1 + {rem}^{′} - ( 1 << k ) .$$

As a last step, the sign needs to be applied to |q| in dependence on the decoded sign_flag, yielding the quantized weight level q. Finally, the quantized weight w is reconstructed by multiplying the quantized weight level q with the step size Δ.

In an implementation variant, k is initialized with 0 and updated as follows. After each abs_level_greater_X equal to 1, the required update of k is done according to the following rule: If X>X′, k is incremented by 1 where X′ is a constant depending on the application. For example X′ is a number (e.g. between 0 and 100) that is derived by the encoder and signaled to the decoder.

### 2.2.4.4 Context Modelling (Examples, all Details are Optional)

In the CABAC entropy coding, most syntax elements for the quantized weight levels are coded using a binary probability modelling. Each binary decision (bin) is associated with a context. A context represents a probability model for a class of coded bins. The probability for one of the two possible bin values is estimated for each context based on the values of the bins that have been already coded with the corresponding context. Different context modelling approaches may be applied, depending on the application. Usually, for several bins related to the quantized weight coding, the context, that is used for coding, is selected based on already transmitted syntax elements. Different probability estimators may be chosen, for example SBMP [4], or those of HEVC [5] or VTM-4.0 [6], depending on the actual application. The choice affects, for example, the compression efficiency and complexity.

A context modeling scheme that fits a wide range of neural networks is described as follows. For decoding a quantized weight level q at a particular position (x,y) in the weight matrix (layer), a local template is applied to the current position. This template contains a number of other (ordered) positions like e.g. (x−1, y), (x, y−1), (x−1, y−1), etc. For each position, a status identifier is derived.

In an implementation variant (denoted Si1), a status identifier s_{x,y} for a position (x,y) is derived as follows: If position (x,y) points outside of the matrix, or if the quantized weight level q_{x,y} at position (x,y) is not yet decoded or equals zero, the status identifier s=0. Otherwise, the status identifier shall be s=q<0 ? 1:2.

For a particular template, a sequence of status identifiers is derived, and each possible constellation of the values of the status identifiers is mapped to a context index, identifying a context to be used. The template and the mapping may be different for different syntax elements. For example, from a template containing the (ordered) positions (x−1, y), (x, y−1), (x−1, y−1) an ordered sequence of status identifiers s_{x-1,y}, s_{x,y-1}, s_{x1,y1} is derived. For example, this sequence may be mapped to a context index C=s_{x-1,y}+3*s_{x,y-1}+9*s_{x-1,y-1}. For example, the context index C may be used to identify a number of contexts for the sig_flag.

In an implementation variant (denoted approach 1), the local template for the sig_flag or for the sign_flag of the quantized weight level q_{x,y} at position (x,y) consists of only one position (x−1, y) (i.e., the left neighbor). The associated status identifier sₓ₋₁, is derived according to the implementation variant Si1.

For the sig_flag, one out of three contexts is selected depending on the value of sₓ₋₁, or for the sign_flag, one out of three other contexts is selected depending on the value of s_{x-1,y}.

In another implementation variant (denoted approach 2), the local template for the sig flag contains the three ordered positions (x−1, y), (x−2, y), (x−3, y). The associated sequence of status identifiers s_{x-1,y}, s_{x-2,y}, s_{x-3,y} is derived according to the implementation variant Si2.

For the sig_flag, the context index C is derived as follows:

$$If {s}_{x - 1 , y} \neq 0 {s}_{x - 1 , y} \neq 0 , then C = 0. \\ Otherwise , if {s}_{x - 2 , y} \neq 0 {s}_{x - 2 , y} \neq 0 , then C = 1. \\ Otherwise , if {s}_{x - 3 , y} \neq 0 , then C = 2. Otherwise , C = 3 .$$

This may also be expressed by the following equation:

$$C = ( {s}_{x - 1 , y} \neq 0 ) ? 0 : ( ( {s}_{x - 2 , y} \neq 0 ) ? 1 : ( ( {s}_{x - 3 , y} \neq 0 ) ? 2 : 3 ) )$$

In the same manner, the number of neighbors to the left may be increased or decreased so that the context index C equals the distance to the next nonzero weight to the left (not exceeding the template size).

Each abs_level_greater_X flag may, for example, apply an own set of two contexts. One out of the two contexts is then chosen depending on the value of the sign_flag.

In an implementation variant, for abs_level_greater_X flags with X smaller than a predefined number X′, different contexts are distinguished depending on X and/or on the value of the sign_flag.

In an implementation variant, for abs_level_greater_X flags with X greater or equal to a predefined number X′, different contexts are distinguished only depending on X.

In another implementation variant, abs_level_greater_X flags with X greater or equal to a predefined number X′ are encoded using a fixed code length of 1 (e.g. using the bypass mode of an arithmetic coder).

Furthermore, some or all of the syntax elements may also be encoded without the use of a context. Instead, they are encoded with a fixed length of 1 bit. E.g., using a so-called bypass bin of CABAC.

In another implementation variant, the fixed-length remainder rem is encoded using the bypass mode.

In another implementation variant, the encoder determines a predefined number X′, distinguishes for each syntax element abs_level_greater_X with X<X′ two contexts depending on the sign, and uses for each abs_level_greater_X with X>=X′ one context.

### 2.2.4.5 Context Modelling for Dependent Scalar Quantization (Examples, all Details are Optional)

The main aspect of dependent scalar quantization is that there are different sets of admissible reconstruction levels (also called quantization sets) for the neural network parameters. The quantization set for a current neural network parameter is determined based on the values of the quantization index for preceding neural network parameters. If we consider the preferred example in FIG. 10 and compare the two quantization sets, it is obvious that the distance between the reconstruction level equal to zero and the neighboring reconstruction levels is larger in set 0 than in set 1. Hence, the probability that a quantization index is equal to 0 is larger if set 0 is used and it is smaller if set 1 is used. In an implementation variant, this effect is exploited in the entropy coding by switching codeword tables or probability models based on the quantization sets (or states) that are used for a current quantization index.

Note that for a suitable switching of codeword tables or probability models, the path (association with a subset of the used quantization set) of all preceding quantization indexes must be known when entropy decoding a current quantization index (or a corresponding binary decision of a current quantization index). Therefore, it is necessary that the neural network parameters are coded in reconstruction order. Hence, in an implementation variant, the coding order of neural network parameters is equal to their reconstruction order. Beside that aspect, any coding/reconstruction order of quantization indexes is possible, such as the one specified in section 2.2.4.2, are any other uniquely defined order.

At least a part of bins for the absolute levels is typically coded using adaptive probability models (also referred to as contexts). In an implementation variant, the probability models of one or more bins are selected based on the quantization set (or, more generally, the corresponding state variable) for the corresponding neural network parameter. The chosen probability model can depend on multiple parameters or properties of already transmitted quantization indexes, but one of the parameters is the quantization set or state that applies to the quantization index being coded.

In another implementation variant, the syntax for transmitting the quantization indexes of a layer includes a bin that specifies whether the quantization index is equal to zero or whether it is not equal to 0. The probability model that is used for coding this bin is selected among a set of two or more probability models. The selection of the probability model used depends on the quantization set (i.e., the set of reconstruction levels) that applies to the corresponding quantization index. In another implementation variant, the probability model used depends on the current state variable (the state variables implies the used quantization set).

In a further implementation variant, the syntax for transmitting the quantization indexes of a layer includes a bin that specifies whether the quantization index is greater than zero or lower than zero. In other words, the bin indicates the sign of the quantization index. The selection of the probability model used depends on the quantization set (i.e., the set of reconstruction levels) that applies to the corresponding quantization index. In another implementation variant, the probability model used depends on the current state variable (the state variables implies the used quantization set).

In a further implementation variant, the syntax for transmitting the quantization indexes includes a bin that specifies whether the absolute value of a quantization index (neural network parameter level) is greater than X (for details refer to section 2.2.4.2). The probability model that is used for coding this bin is selected among a set of two or more probability models. The selection of the probability model used depends on the quantization set (i.e., the set of reconstruction levels) that applies to the corresponding quantization index. In another an implementation variant, the probability model used depends on the current state variable (the state variables implies the used quantization set).

One aspect is that the dependent quantization of neural network parameters is combined with an entropy coding, in which the selection of a probability model for one or more bins of the binary representation of the quantization indexes (which are also referred to as quantization levels) depends on the quantization set (set of admissible reconstruction levels) or a corresponding state variable for the current quantization index. The quantization set (or state variable) is given by the quantization indexes (or a subset of the bins representing the quantization indexes) for the preceding neural network parameters in coding and reconstruction order.

In an implementation variant, the described selection of probability models is combined with one or more of the following entropy coding aspects:
The absolute values of the quantization indexes are transmitted using a binarization scheme that consists of a number of bins that are coded using adaptive probability models and, if the adaptive coded bins do not already completely specify the absolute value, a suffix part that is coded in the bypass mode of the arithmetic coding engine (non-adaptive probability model with a pmf (0.5, 0.5) for all bins). In an implementation variant, the binarization used for the suffix part depends on the values of the already transmitted quantization indexes.
The binarization for the absolute values of the quantization indexes includes an adaptively coded bin that specifies whether the quantization index is unequal to 0. The probability model (as referred to a context) used for coding this bin is selected among a set of candidate probability models. The selected candidate probability model is not only determined by the quantization set (set of admissible reconstruction levels) or state variable for the current quantization index, but, in addition, it is also determined by already transmitted quantization indexes for the layer. In an implementation variant, the quantization set (or state variable) determines a subset (also called context set) of the available probability models and the values of already coded quantization indexes determine the used probability model inside this subset (context set).

In an implementation variant, the used probability model inside a context set is determined based on the values of the already coded quantization indexes in a local neighborhood of the current neural network parameter. In the following, some example measures are listed that can be derived based on the values of the quantization indexes in the local neighborhood and can, then, be used for selecting a probability model of the pre-determined context set:
The signs of the quantization indexes not equal to 0 inside the local neighborhood.
The number of quantization indexes not equal to 0 inside the local neighborhood. This number can possibly be clipped to a maximum value.
The sum of the absolute values of the quantization indexes in the local neighborhood. This number can be clipped to a maximum value.
The difference of the sum of the absolute values of the quantization indexes in the local neighborhood and number of quantization indexes not equal to 0 inside the local neighborhood. This number can be clipped to a maximum value.

The binarization for the absolute values of the quantization indexes includes adaptively coded bin that specifies whether the absolute value of the quantization index is greater than X. The probability models (as referred to a context) used for coding these bins are selected among a set of candidate probability models. The selected probability models are not only determined by the quantization set (set of admissible reconstruction levels) or state variable for the current quantization index, but, in addition, it is also determined by already transmitted quantization indexes for the layer. In an implementation variant, the quantization set (or state variable) determines a subset (also called context set) of the available probability models and the data of already coded quantization indexes determines the used probability model inside this subset (context set). For selecting the probability model, any of the methods described above (for the bin specifying whether a quantization index is unequal to 0) can be used.

### 2.3 Related Methods for Compression of Incremental Updates of Neural Networks (Examples, all Details are Optional)

This section describes methods for encoding of incremental updates of neural networks, where a reconstructed network layer is a composition of an existing base layer (of a base model) and one or more incremental update layers, that may be encoded and transmitted separately.

### 2.3.1 Concept of Base Model and Update Models (Examples, all Details are Optional)

The concept introduces a neural network model according to section 1 which can be considered as a full model in a sense that an output can be computed on a given input. This model is denoted as base model N_{B}. Each base model consists of layers, which are denoted as base-layers L_{B1}, L_{B2}, . . . , L_{BJ}. A base-layer contains base values, that may, for example, be chosen such that they can efficiently be represented or compressed/transmitted in a first step. Additionally, the concept introduces update models (N_{U1}, N_{U2}, . . . , N_{UK}), which may have a similar or even identical architecture as the base model. The update model may, for example, not be a full model in sense mentioned above. Instead, it may be combined with a base model using a composition method, such that they form a new full model N_{B1}. This model itself can serve as base model for further update models. An update model N_{Uk} consists of layers, denoted as update layers L_{Uk,1}, L_{Uk,2}, . . . , L_{Uk}. An update layer contains base values, that may, for example, be chosen such that they can efficiently be represented or compressed/transmitted separately.

The update model may be the outcome of an (additional) training process applied to the base model at the encoder side. Several composition methods, depending on the type of updates provided by the update model may be applied. Note that the methods described within this invention are not restricted to any specific type of updates/composition method, but are applicable to any architecture using the base model/update model approach.

In a preferred embodiment the k-th update model N_{Uk} contains layers L_{Uk,j} with differential values (also denoted as incremental updates) that are added to corresponding layers of a base model L_{B}j to form a new model layers L_{Nk,j} according to:

$${L}_{Nkj} = {L}_{Bj} + {L}_{Uk , j} , for all j$$

The new model layers form the (updated) new model, which then serves as base model for a next incremental update, which is transmitted separately.

In a further preferred embodiment the k-th update model contains layers L_{Uk,j} with scaling factor values that are multiplied by the corresponding base layer L_{B}j values to form a new model L_{Nk,j} according to:

$${L}_{Nk , j} = {L}_{Bj} \cdot {L}_{Uk , j} , for all j$$

The new model layers form the (updated) new model, which then serves as base model for a next incremental update, which is transmitted separately.

Note, that in some cases, an update model may also contain new layers, which replace one or more existing layers (i.e. for a layer k: L_{Nk,j}=L_{Uk,j}, for all j), instead of updating a layer as described above.

### 2.3.2 Neural Network Parameter Coding of Incremental Updates (Examples, all Details are Optional)

The concept of a base model and one or more incremental updates can be exploited in the entropy coding stage in order to improve the coding efficiency. The parameters of a layer are usually represented by a multidimensional tensor. For the encoding process all tensors are usually mapped to a 2D matrix, such that entities like rows and columns. This 2D matrix is then scanned in a predefined order and the parameters are encoded/transmitted. Note that the methods described in the following are not restricted to 2D matrices. The methods are applicable to all representations of neural network parameters that provides parameter entities of known size, like e.g. rows, columns, blocks etc. and/or a combination of them. The 2D Matrix representation is used in the following for a better understanding of the methods.

In a preferred embodiment the parameters of a layer are represented as a 2D matrix, which provides entities of values like rows and columns.

### 2.3.2.1 Row or Channel Skip Mode (Examples, all Details are Optional)

Usually the magnitude of the values of an update model is smaller compared to a full (base) model. Often a significant number of values is zero which is also further amplified by the quantization process. As a result, the layers to be transmitted may contain long sequences of zeros, which means that some of the rows of the 2D matrix are completely zero.

This can be exploited by introducing a flag (skip_row_flag) for each row, which specifies whether all the parameters in a row are equal to zero or not. If the flag is equal to one (skip_row_flag==1) no further parameters are encoded for that row.

At the decoder side, if the flag is equal to one, no parameter are decoded for this row. Instead, they are assumed to be 0.

A variant here is to arrange all skip_row_flags into a flag array skip_row_flag[N] with N being the number of rows. Also, in a variant, N might be signaled before the array.

Otherwise, if the flag is equal to zero, the parameters are regularly encoded and decoded for this row.

Each of the skip_row_flags is associated with a probability model or context model. A context model is chosen out of a set of context models, based on previously coded symbols (e.g. preceding encoded parameters or skip_row_flags.

In a preferred embodiment a single context model is applied to all skip_row_flags of a layer.

In another preferred embodiment a context model is chosen out of a set of two context models based on the value of the previously encoded skip_row_flag. That is the first context model if the value of the preceding skip_row_flag is equal to zero, and the second context model if the value is equal to one.

In further preferred embodiment a context model is chosen out of a set of two context models based on the value of a co-located skip_row_flag in a corresponding layer of a previously encoded update or the base model. That is the first context model if the value of the preceding skip_row_flag is equal to zero, and the second context model if the value is equal to one.

In another preferred embodiment the given number of context models, as for example in the previous embodiments, is doubled forming two sets of context models. Then a set of context models is chosen based on the value of a co-located skip_row_flag in a corresponding layer of a specific previously encoded update or the base model. That means the first set is chosen if the value of the preceding skip_row_flag is equal to zero, and the second set if the value is equal to one.

A further preferred embodiment is equal to the preceding embodiment, but the first set of context models is chosen if there does not exist a corresponding layer in a specific previously encoded update or the base model. Consequently, the second set is chosen if there exists a corresponding layer in a specific previously encoded update or the base model.

Note, that the particular described mechanism for skipping rows similarly applies to columns in the 2D matrix case, as well as in a generalized tensor case with N parameter dimensions, where a sub-block or sub-row of smaller dimension K (K<N) can be skipped, using the described mechanism of a skip_flag or skip_flag_array.

### 2.3.2.2 Improved Context Modeling for the Base-Model Update Model Structure (Examples, all Details are Optional)

The concept of base models and one or more update models can be exploited in the entropy coding stage. The methods described here are applicable to any entropy coding scheme that uses context models, as for example the one described in section 2.2.4.

Usually the separate update models (and the base model) are correlated and available at the encoder and decoder side. This can be used in the context modeling stage to improve the coding efficiency by providing new context models and methods for context model selection.

In a preferred embodiment a binarization (sig_flag, sign_flag, etc.), context modeling and encoding scheme according section 2.2.4.2 is applied.

In another preferred embodiment the given number of context models (context set) for a symbol to be encoded is duplicated forming two or more sets of context models. Then a set of context models is chosen based on the value of a co-located parameter in a corresponding layer of a specific previously encoded update or the base model. That means a first set is chosen if the co-located parameter is lower than a first threshold T₁, a second set if the value is greater or equal than threshold T₁, a third set if the value is greater or equal than a threshold T₂ etc. This procedure may be applied with more or less threshold values.

In a preferred embodiment which is equal to the previous embodiment, a single threshold T₁=0 is used.

In another preferred embodiment the given number of context models (context set) for a symbol to be encoded is duplicated forming two or more sets of context models. Then a set of context models is chosen based on a set of values consisting of a co-located parameter and neighboring values (e.g. a or several spatial neighbors of the co-located parameter) in a corresponding layer of a specific previously encoded update or the base model.

In a preferred embodiment equal to the previous embodiment, a first set is chosen, if the sum of the values (or absolute values) within the template is lower than a first threshold T₁, a second set if the sum is greater or equal than threshold T₁, a third set if the sum is greater or equal than a threshold T₂ etc. This procedure may be applied with more or less threshold values.

In particularly preferred embodiment equal to the previous embodiment, the template comprises the co-located parameter and the left neighbor of the co-located parameter and a single threshold T₁=0 is used.

In another preferred embodiment a context model out of a set of context models for a syntax element is chosen based on a set of values consisting of a co-located parameter and neighboring values (e.g. a or several spatial neighbors of the co-located parameter) in a corresponding layer of a specific previously encoded update or the base model.

In a preferred embodiment equal to the previous embodiment, a first context model is chosen, if the sum of the values (or absolute values) within the template is lower than a first threshold T₁, a second context model if the sum is greater or equal than threshold T₁, a third context model if the value is greater or equal than a threshold T₂ etc. This procedure may be applied with more or less threshold values.

In particularly preferred embodiment equal to the previous embodiment, the template comprises the co-located parameter and the left neighbor of the co-located parameter and a single threshold T₁=0 is used.

In further preferred embodiment the given number of context models (context set) for a symbol to be encoded is duplicated forming two or more sets of context models. Then a set of context models is chosen based on the absolute value of a co-located parameter in a corresponding layer of a specific previously encoded update or the base model. That means the first set is chosen if the absolute value of the co-located parameter is lower than a first threshold T₁, a second set if the absolute value is greater or equal another threshold T₁, a third set if the absolute value is greater or equal than a threshold T₂ etc. This procedure may be applied with more or less threshold values.

In a preferred embodiment which is equal to the previous embodiment a sig_flag is encoded which indicates if a current value to be encoded is equal to zero or not, which employs a set of context models. The embodiment uses a single threshold T₁=1.

Another preferred embodiment is equal to the previous embodiment, but instead of a sig_flag a sign_flag is encoded which indicates the sign of a current value to be encoded.

A further preferred embodiment is equal to the previous embodiment but instead if a sig_flag a abs_level_greater_X is encoded which indicates whether the current value to be encoded is greater than X.

In further preferred embodiment the given number of context models (context set) for a symbol to be encoded is doubled forming two sets of context models. Then a set of context models is chosen depending on whether there is a corresponding previously encoded update (or base) model or not. The first set of context models is chosen if there is not a corresponding previously encoded update (or base) model, and the second set, otherwise.

In another preferred embodiment a context model out of a set of context models for a syntax element is chosen based on the value of a co-located parameter in a specific corresponding previously encoded update (or base) model. That means a first model is chosen if the co-located parameter is lower than a threshold T₁, a second model if the value is greater or equal than threshold T₁, a third set if the value is greater or equal than another threshold T₂ etc. This procedure may be applied with more or less threshold values.

In preferred embodiment equal to the previous embodiment a sign_flag is encoded which indicates the sign of a current value to be encoded. A first threshold for the context model selection process is T₁=0 and a second threshold is T₂=1.

In another preferred embodiment a context model out of a set of context models for a syntax element is chosen based on the absolute value of a co-located parameter in a specific corresponding previously encoded update (or base) model. That means a first model is chosen if the absolute value of the co-located parameter is lower than a threshold T₁, a second model if the value is greater or equal than threshold T₁, a third model if the value is greater or equal than threshold T₂ etc. This procedure may be applied with more or less threshold values.

In a preferred embodiment equal to the previous embodiment a sig_flag is encoded which indicates whether a current value to be encoded is equal to zero or not. It employs a first threshold set to T₁=1 and second threshold set to T₂=2.

In another preferred embodiment equal to the previous embodiment instead of a sig_flag a abs_level_greater_X flag is encoded which indicates whether a current value to be encoded is greater than X. Additionally only one threshold is employed which is set to T₁=X.

Note that any of the above mentioned embodiments can be combined with one or more of the other embodiments.

### 2.4 Compressing Multiple Tensors in a Block (Examples, all Details are Optional)

Usually, each tensor is encoded separately and transmitted in a so-called compressed data unit (NDU), which also contains (header) information about the compressed tensor, e.g. the tensor type, coding parameters or the original dimensions of the tensor (described in section 2.1). However, MPEG-7 part 17 specifies a special NDU-type (NNR_PT_BLOCK), which allows to transmit a weight tensor and several corresponding tensors, i.e. biases, batch-norm parameters and scaling factors, together in a single NDU. All the tensors in the block share the same header information (instead of transmitting individual ones) and thus the bitstream size is reduced. Since the other tensors are directly related to the weight tensor, their dimensions can be derived from the (weight) tensor dimensions in the following way. The biases, batch-norm parameters and scaling factors are 1 D tensors with a length equal to the number of output channels (fully-connected layers) or the number of filters (convolutional layers) of the weight tensor, respectively. For deriving these dimensions the standard specifies to use the first dimension of a decoded weight tensor as the length of the 1D tensors. This implies that a decoded weight tensor is expected to be ordered such that the first dimension always corresponds to the number of output channels or filters.

### 3 Invention

In the following aspects of the invention and embodiments according to the invention will be described.

It should be noted that any of the features, functionalities and details described in this section may used individually and in combination. Moreover, it should be noted that, optionally, any of the features, functionalities and details described in this section may optionally be introduced into any of the conventional encoding concepts and decoding concepts.

According to an aspect, this invention describes a tensor dimension reordering scheme in order to enable efficient processing of tensors in a neural network compression framework, as for example the MPEG-7 part 17 standard for compression of neural networks for multimedia content description and analysis [2]. For example, the tensor dimensions are reordered at the encoder side prior to encoding of the tensor. For example, at the decoder side this reordering is then applied in reverse order to restore the original dimensions. For example, the information on how to derive the original dimensions is signaled in the bitstream.

For example, allowing arbitrary dimension orders could induce a significant signaling overhead, especially for high dimensional tensors, since the number of permutations increases massively with the number of tensor dimensions N. Instead, according to an aspect of the invention, the method described in this invention, for example, only performs a shift of a single dimension to another position.

In the next section the need for tensor dimension reordering will be shortly motivated. Then, in section 3.2 the method is illustrated using an example. Afterwards in section 3.3 and section 3.4, as an example, the method and related syntax will be described.

### 3.1 Motivation

As already mentioned in section 2.1 a tensor is usually (but not necessarily) (e.g. in MPEG-7 part 17) represented or interpreted as a 1D vector or a 2D matrix, respectively, e.g. such that the length of the first dimension is equal to the first dimension of the tensor and the length of the second dimension is equal to the product of all other dimensions.

Consequently, the shape of the 2D-matrix may, for example, essentially depend on the first dimension of the tensor. For example, if the tensor dimensions are ordered such that the length of the first dimension is small (e.g. the width or height of a 3×3 filter kernel) the output is, for example, a rather “slim” matrix. This may, for example, result in inefficient processing of the 2D matrix (interpretation) to be encoded, especially for block scan orders as for example described section 2.2.4.1, where the matrix is, for example, decomposed into blocks. For example, the MPEG-7 part 17 standard specifies 4 block scan orders with block sizes 4×4, 8×8, 16×16 and 32×32. Assuming, for example, the first dimension of the matrix is smaller than 4 (or 8, 16, 32) this produces a single block row of cropped blocks, which is not optimal for further processing.

According to an aspect, the invention is, for example, further motivated by the method described in section 2.4, where, for example, multiple related tensors are compressed in a block, as for example used in MPEG-7 part 17. Here, for example, the dimensions of corresponding tensors are derived from the dimensions of the weight tensor, or, for example, more specifically, from the first dimension of the weight tensor. In some cases, this requires, for example, the tensor to be ordered such that the first dimension is related, for example, to the number of output channels (fully-connected layers) or filters (convolutional layers), otherwise the derivation process may, in some cases, fail.

The mentioned aspects show, for example, the advantages of an efficient tensor dimension reordering method, which is described in the following sections.

### 3.2 Illustration of the Tensor Dimension Reordering Scheme (Examples, Details are Optional)

As mentioned before, according to an aspect of the invention, the method reorders the tensor, for example, by shifting a single dimension to another position. First, the concept is illustrated using an example with 4 dimensions, namely as shown in FIG. 6. As discussed earlier, FIG. 6 shows a schematic example of a concept of tensor dimension reordering for example, for the encoding-decoding pipeline. For example, each box corresponds to a tensor/matrix representation/interpretation with the dimensions given in square brackets. For example, Solid black arrows/lines denote the general processing flow and dashed lines/arrows the processing flow of syntax element first_tensor_dimension_shift. (example; encoding and decoding can be used individually; 2D matrix interpretation is optional).

For example, from the encoder point of view a value first_tensor_dimension_shift (here it is optionally set to 2) denotes the tensor dimension, which is shifted to the first position of the tensor dimensions in the reordering process (see D2 in the example). So, for example, in a first step, the tensor is reordered and in a second step this tensor is, for example, (optionally) interpreted as 2D matrix and then encoded. For example, at the decoder side the (optional) 2D matrix (interpretation) is, for example, decoded and, for example, interpreted as a tensor. Then, for example, the reordering is done in reverse order, i.e., for example, shifting dimension D2 back to position two. Here, for example, the value first_tensor_dimension_shift specifies the new position of the first dimension of decoded and reconstructed tensor after reordering.

For the given example the reordering process at the encoder and decoder are, for example, as follows:

### Encoder (Example; Details are Optional):

Assuming, for example, a 4D-tensor A_{Enc} with tensor dimensions [D0,D1,D2,D3] and first_tensor_dimension_shift equal to two are given and the elements of A_{E}nc can be accessed by A_{Enc}[m] [n] [o] [p] (with m∈[0, D0−1], n∈[0, D1−1], o∈[0,D2−1] and p∈[0,D3−1]), then
For example (optionally) Initialize reordered tensor B_{Enc} with dimensions [D2, D0,D1, D3]
For example, Set values of B_{Enc} according to:

```
for( m = 0; m < D0; m++ ) {
  for( n = 0; n < D1; n++ ) {
    for( o = 0; o < D2; o++ ) {
      for( p = 0; p < D3; p++ ) {
        B_{Enc}[o][m][n][p] = A_{Enc}[m][n][o][p]
      }
    }
  }
}
```

### Decoder: (Example; Details are Optional)

Assuming, for example, a 4D-tensor B_{Dec} with tensor dimensions [D2,D0,D1,D3] and first_tensor_dimension_shift equal to two have been decoded from the bitstream and the elements of B_{Dec} can be accessed by B_{Dec} [o] [m] [n] [p] (with m E [0,D0−1], n∈[0,D1−1], o∈[0,D2−1] and p∈[0,D3−1]), then:
For example, Initialize reordered tensor A_{Dec} with dimensions [D0,D1,D2,D3]
   For example, Set values of A_{Dec} according to:

```
for( m = 0; m < D0; m++ ) {
  for( n = 0; n < D1; n++ ) {
    for( o = 0; o < D2; o++ ) {
      for( p = 0; p < D3; p++ ) {
        A_{Dec}[m][n][o][p] = B_{Dec}[o][m][n][p]
      }
    }
  }
}
```

Hence, in general, a decoder, e.g. 100 as shown in FIG. 1, e.g. 200 as shown in FIG. 2, for example respective decoding units thereof 110, 210, may, for example, be configured to obtain a 2-dimensional matrix 660, a first dimension of which is determined by a first dimension value, e.g. D2 as shown in FIG. 6, and a second dimension of which is determined by a product of a plurality of further dimension values, e.g. D0*D1*D3 as shown in FIG. 6, on the basis of the encoded representation, e.g. in bitstream 650. Furthermore, such a decoder may, for example, be configured to obtain the first multi-dimensional array, e.g. 111, e.g. 211, e.g. 670 as shown in FIG. 6, dimensions of which are determined by individual ones of the first dimension value and the further dimension values, on the basis of the 2-dimensional matrix 660 and such a decoder may be configured to obtain the re-ordered multi-dimensional array, e.g. 111, e.g. 221, e.g. 680 as shown in FIG. 6, on the basis of the first multi-dimensional array, wherein a first dimension of the re-ordered multi-dimensional array is defined by one of the further dimension values.

### 3.3 Method for Tensor Dimension Reordering (Example, Details are Optional)

As an example, this section describes the invention for arbitrary tensor dimensions, which works analogously to the example given in section 3.2. For example, at the encoder a tensor is reordered such that a certain tensor dimension, for example, specified by a value first_tensor_dimension_shift, is shifted to the first position. For example, at the decoder this shifting is done in reverse order (for example, shifting the first dimension to the position denoted by first_tensor_dimension_shift). The method is described, as an example, in the following.

For example, an N-dimensional tensor T (with N∈ [symbol] ) with the dimensions written as an array dims_{T}=[D₀, D₁, . . . , D_{N-1}], is given, where, for example, D₀ is associated with the first dimension of the tensor, D₁ is associated with the second dimension of the tensor, etc. The value of Dₖ (k∈[0, 1, . . . , N−1]) denotes, for example, the length of the associated dimension (e.g. D₀ is then length of the first dimension). For example, the position of a weight within the tensor T can be addressed by (idxT), for example, using another array idxT=[d₀, d₁, . . . , d_{N-1}] with a length equal to the length of dims_{T}. Here, dₖ∈[0, 1, . . . , Dₖ₋₁] denotes, for example, a position in dimension Dₖ and scalar i∈[0, 1, . . . , (D₀, D₁, . . . , D_{N-1})] specifies, for example, a position within the tensor. The mapping of i to idxT is determined, for example, by a scan, e.g. a row-major scan (details can be found below). Furthermore, there is, for example, a function arrayIndexShift(inputArray[ ], shiftPos, reverseOrder), which takes, for example, an array inputArray[ ], a value shiftPos and boolean value reverseOrder as inputs, and outputs, for example, an array outputArray[ ] as follows:
For example, Initialize outputArray[ ] with a copy of inputArray[ ]
For example, if reverseOrder==False:
   The element at position shiftPos is, for example, erased from outputArray[ ]
   The element at position shiftPos of inputArray[ ] is, for example, inserted at the first position of outputArray[ ]
For example, Else:
   If shiftPos>0:
      The element at the first position is, for example, erased from outputArray[ ]
      The first element of inputArray[ ] is, for example, inserted into outputArray[ ], for example, before the element with position shiftPos and after the element with position shiftPos−1

Then, for example, a reordered tensor R (from tensor T) at the encoder can be obtained as follows:
For example, Initialize tensor R with dimensions dims_{R}=arrayIndexShift(dims_{T}, first_tensor_dimension_shift, False)
For example, for (i=0; i<(D₀, D₁, . . . , D_{N-1}); i++)
   idx_{R}ⁱ=arrayIndexShift(idxT, first_tensor_dimension_shift, False)
   R (idx_{R}ⁱ)=T (idx)

For example, A reordered tensor R (from tensor T) at the decoder can be obtained as follows:
For example, Initialize tensor R with dimensions dims_{R}=arrayIndexShift(dims_{T}, first_tensor_dimension_shift, True)
For example, for (i=0; i<(D₀, D₁, . . . D_{N-1}); i++)
   idx_{R}ⁱ=arrayIndexShift(idx_{T}ⁱ, first_tensor_dimension_shift, True)
   R(idx_{R}ⁱ)=T(idx_{T}ⁱ)

In a preferred embodiment the process at the decoder for the method is, for example, implemented as below:

Inputs to this process are, for example:
A variable inputTensor representing, for example, the tensor for which the dimensions shall be reordered
A variable inputTensorDims specifiying, for example, the dimensions of inputTensor
A variable firstTensorDimShift denoting, for example, the shift of the first dimension of inputTensor

For example, Output of this process is a variable reorderedTensor, fore example, with dimensions equal to ShiftArrayIndex(inputTensorDims, firstTensorDimShift). The elements of variable reorderedTensor are, for example, set as follows:

```
for( i = 0; i < Prod( inputTensorDims ); i++ ){
    idxA = TensorIndex( inputTensorDims, i, 0 )
    idxB = ShiftArrayIndex( idxA, firstTensorDimShift )
    reorderedTensor[idxB] = inputTensor[idxA]
  }
```

For example, the functions Size, Prod, TensorIndex and ShiftArrayIndex are defined as follows:

Prod(arrayName[ ]) returns, for example, the product of all elements of array arrayName[ ].

Size(arrayName[ ]) returns, for example, the number of elements contained in the array or tensor named arrayName. If arrayName[ ] is a tensor this corresponds, for example, to the product of all dimensions of the tensor.

TensorIndex(tensorDimensions[ ], i, scan) returns, for example, an array with the same number of dimensions as tensorDimensions[ ] where, for example, the elements of the array are set to integer values so that the array can, for example, be used as an index pointing to an element of a tensor with dimensions tensorDimensions[ ] as follows:
If, for example, variable scan is equal to 0:
   The returned array points, for example, to the i-th element in row-major scan order of a tensor with dimensions tensorDimensions[ ] and is, for example, derived as follows:
   For example, a variable outputArray[ ] is initialized with a size set to Size(tensorDimensions[ ]).
   For example, a variable idx is set to i
   For example, the elements of outputArray[ ] are set as follows:
      for(a=Size(tensorDimensions)−1; a>=0; a−−){
         outputArray[a]=idx % tensorDimensions[a]
         idx=idx/tensorDimensions[a]
   For example, the returned array is outputArray[ ].
For example, if variable scan is greater than 0:
   A variable bs is, for example, set to 4<<scan_order.
      A variable h is, for example, set to tensorDimensions[0].
      A variable w is, for example, set to Prod(tensorDimensions)/h
   Two variables x and y are, for example, set to the first and second element of the array that is returned, for example, by calling IndexToXY(w, h, i, bs), respectively.
   For example, the returned array is TensorIndex(tensorDimensions, y*w+x, 0).
Note: The operator “/” is defined as integer division with truncation of the result toward zero. For example, 7/4 and −7/−4 are truncated to 1 and −7/4 and 7/−4 are truncated to −1.
Note: The operator “++” is defined as increment, i.e., x++ is equivalent to x=x+1; when used in an array index, evaluates to the value of the variable prior to the increment operation.
Note: The operator “−−” is defined as decrement, i.e., x−− is equivalent to x=x−1; when used in an array index, evaluates to the value of the variable prior to the decrement operation.
Note: The operator “x % y” is defined as modulus. Remainder of x divided by y, defined only for integers x and y with x≥0 and y>0.
Note: The function TensorIndex provides, for example, a mapping from “i” to a position in the tensor such that it is equivalent to scanning a 2D matrix with dimensions equal to [tensorDimensions[0], Prod(tensorDimensions)/tensorDimensions[0] ] with a scan according to “scan” (refer to 2.2.4.1)

ShiftArrayIndex(inputArray[ ], TensoshiftIndexPosition) returns, for example, an array outputArray[ ] which is, for example, a copy of inputArray[ ] but with the element at position 0 of the inputArray shifted to shiftIndexPosition, for example, as follows:
For example, a variable outputArray[ ] is initialized with a copy of inputArray[ ].
   For example, if shiftindexPosition is greater than 0:
   For example, the first element of outputArray[ ] is erased from outputArray[ ].
For example, the first element of inputArray[ ] is inserted into outputArray[ ] before the element with position shiftIndexPosition and after element with position shiftIndexPosition-1.

In general, a decoder according to embodiments, e.g. a decoder 100 as shown in FIG. 1, e.g. a decoder 200 as shown in FIG. 2, for example respective decoding units thereof 110, 210, may, for example, be configured to determine positions of the decoded neural network parameters in the first multi-dimensional array, e.g. 111, e.g. 211, using a position mapping function, e.g. TensorIndex(tensorDimensions[ ], i, scan), which maps a scalar neural network parameter index, e.g. i, onto a set of dimension indices. Such decoders may in particular be configured to decode encoded neural network parameters using a context-based entropy decoding, e.g. as shown in FIG. 2.

Furthermore, in general, a decoder according to embodiments, e.g. a decoder 100 as shown in FIG. 1, e.g. a decoder 200 as shown in FIG. 2, for example respective reordering units thereof 120, 220, may, for example, be configured to obtain the re-ordered multidimensional array, e.g. 121, 221, using a function (e.g.

TensorIndex(tensorDimensions[ ], i, scan)) which maps an integer element index i designating an element of the first multi-dimensional array, e.g. 111, 211, onto a set of array indices, wherein a returned set of array indices designates an i-th element in a row-major scan order of the first multidimensional array, or wherein a returned set of array indices designates an i-th element of a block-wise scan of the first multi-dimensional array, in which the first multi-dimensional array is considered as a two-dimensional array.

Moreover, in general, a decoder according to embodiments, e.g. a decoder 100 as shown in FIG. 1, e.g. a decoder 200 as shown in FIG. 2, for example respective reordering units thereof 120, 220, may, for example, be configured to decode a set of array dimensions, e.g. tensor_dimensions[ ], and to obtain a reordered set of array dimensions. As an example, referring to FIG. 6, the reordered set of array dimensions may be a vector [D0, D1, D2, D3], for example, characterizing, the reordered tensor 680, which is obtained based on a decoded set of array dimensions, e.g. of tensor 670 or optionally of tensor 660.

Moreover, in general, a decoder according to embodiments, e.g. a decoder 100 as shown in FIG. 1, e.g. a decoder 200 as shown in FIG. 2, for example respective decoding units thereof 110, 210, may, for example, be configured to enter decoded neural network parameters into the first multidimensional array, e.g. 111, 211, 670, at respective positions described by respective sets of array indices, wherein the decoder is configured to obtain the respective sets of array indices using a mapping function which maps a scalar integer parameter index onto the respective set of array indices and which defines a block-wise scan.

In addition, in general, the mapping function may optionally comprises a mapping of the scalar integer parameter index onto two coordinates which point to a position that corresponds to a scan index defined by the scalar integer parameter index when a block is scanned in blocks and the mapping function may comprise a mapping of the two coordinates onto the respective set of array indices.

### 3.4 Syntax for Tensor Dimension Reordering (Example, Details are Optional)

For example, a syntax element first_tensor_dimension_shift is written to the bitstream. For example, from a decoder point of view, it may specify the new position of the of the first tensor dimension decoded from the bitstream after reordering. Hence, the value of first_tensor_dimension_shift is, for example, non-negative and smaller than the number of tensor dimensions. For example, a value equal to zero means no reordering of the tensor (which is, for example, identical to shifting the first dimension to the first position).

In a preferred embodiment the number of tensor dimensions is, for example, denoted by count_tensor_dimensions and general_profile_idc is, for example, equal to 1, then first_tensor_dimension is encoded, for example, as follows:

| | |
|---|---|
| if( count_tensor_dimensions > 1) { | |
| if(general_profile_idc == 1 ) | |
| first_{—}tensor_{—}dimension_{—}shift | ue(1) |
| ... | |
| } | |

For example, if first_tensor_dimension_shift is not present, it is inferred to be zero.

In a further preferred embodiment first_tensor_dimension_shift is, for example, encoded using an exponential Golomb code. Here, the number of bits required for encoding the values is usually lower for smaller values. So, for example, the number of bits required for a value equal to 1 is lower or equal to the number of bits required for a value of 2. For example, The number of bits required for a value equal to 2 is lower or equal to the number of bits required for a value of 3, etc.

### References for Chapter “Method for Tensor Dimension Reordering for Coding of Neural Networks”

[1] S. Chetlur et al., “cuDNN: Efficient Primitives for Deep Learning,” arXiv: 1410.0759, 2014
[2] MPEG, “Text of ISO/IEC DIS 15938-17 Compression of Neural Networks for Multimedia Content Description and Analysis”, Document of ISO/IEC JTC1/SC29/WG11, w19764, OnLine, October 2020
[3] D. Marpe, H. Schwarz und T. Wiegand, “Context-Based Adaptive Binary Arithmetic Coding in the H.264/AVC Video Compression Standard,” IEEE transactions on circuits and systems for video technology, Vol. 13, No. 7, pp. 620-636, July 2003.
[4] H. Kirchhoffer, J. Stegemann, D. Marpe, H. Schwarz und T. Wiegand, “JVET-K0430-v3—CE5-related: State-based probalility estimator,” in JVET, Ljubljana, 2018.
[5] ITU—International Telecommunication Union, “ITU-T H.265 High efficiency video coding,” Series H: Audiovisual and multimedia systems—Infrastructure of audiovisual services—Coding of moving video, April 2015.
[6] B. Bross, J. Chen und S. Liu, “JVET-M1001-v6—Versatile Video Coding (Draft 4),” in JVET, Marrakech, 2019.
[7] S. Wiedemann et al., “DeepCABAC: A Universal Compression Algorithm for Deep Neural Networks,” in IEEE Journal of Selected Topics in Signal Processing, vol. 14, no. 4, pp. 700-714, May 2020, doi: 10.1109/JSTSP.2020.2969554.

### Proposed Updated Draft of Planned International Standard ISO/IEC 15938-17 (e.g. ISO/IEC DIS 15938-17:xxxx(E))

### Information Technology—Multimedia Content Description Interface—Part 17: Compression of Neural Networks for Multimedia Content Description and Analysis (2^{nd} Edition)

General remark: all details are optional Contents

In the following aspects according to the invention are discussed in sections: Foreword, Introduction, 1 Scope, 2 Normative references, 3 Terms and definitions, 4 Abbreviated terms, conventions and symbols, 4.1 General, 4.2 Abbreviated terms, 4.3 List of symbols, 4.4 Number formats and computation conventions, 4.5 Arithmetic operators 4.6 Logical operators, 4.7 Relational operators, 4.8 Bit-wise operators, 4.9 Assignment operators, 4.10 Range notation, 4.11 Mathematical functions, 4.12 Array functions, 4.13 Order of operation precedence, 4.14 Variables, syntax elements and tables, 5 Overview, 5.1 General, 5.2 Compression tools, 5.3 Creating encoding pipelines, 6 Syntax and semantics, 6.1 Specification of syntax and semantics, 6.1.1 Method of specifying syntax in tabular form, 6.1.2 Bit ordering, 6.1.3 Specification of syntax functions and data types, 6.1.4 Semantics, 6.2 General bitstream syntax elements, 6.2.1 NNR Unit, 6.2.2 Aggregate NNR unit, 6.2.3 Composition of NNR bitstream, 6.3 NNR bitstream syntax, 6.3.1 NNR unit syntax, 6.3.2 NNR unit size syntax, 6.3.3 NNR unit header syntax, 6.3.4 NNR unit payload syntax, 6.3.5 Byte alignment syntax, 6.4 Semantics, 6.4.1 General, 6.4.2 NNR unit size semantics, 6.4.3 NNR unit header semantics, 6.4.4 NNR unit payload semantics, 7 Decoding process, 7.1 General, 7.2 NNR decompressed data formats, 7.3 Decoding methods, 7.3.1 General, 7.3.2 Decoding method for NNR compressed payloads of type NNR_PT_INT, 7.3.3 Decoding method for NNR compressed payloads of type NNR_PT_FLOAT, 7.3.4 Decoding method for NNR compressed payloads of type NNR_PT_RAW_FLOAT, 7.3.5 Decoding method for NNR compressed payloads of type NNR_PT_BLOCK, 7.3.6 Decoding process for an integer weight tensor, 8 Parameter reduction, 8.1 General (informative), 8.2 Methods (informative), 8.2.1 Sparsification using compressibility loss, 8.2.2 Sparsification using micro-structured pruning, 8.2.3 Combined pruning and sparsification, 8.2.4 Structured sparsification, 8.2.5 Parameter unification, 8.2.6 Low rank/low displacement rank for convolutional and fully connected layers, 8.2.7 Batchnorm folding, 8.2.8 Local scaling adaptation, 8.3 Syntax and semantics, 8.3.1 Sparsification using compressibility loss, 8.3.2 Sparsification using micro-structured pruning, 8.3.3 Combined pruning and sparsification, 8.3.4 Structured sparsification, 8.3.5 Weight unification, 8.3.6 Low rank/low displacement rank for convolutional and fully connected layers, 8.3.7 Batchnorm folding, 8.3.8 Local scaling, 9 Parameter quantization, 9.1 Methods, 9.1.1 Uniform quantization method, 9.1.2 Codebook-based method, 9.1.3 Dependent scalar quantization method, 9.1.4 Iterative QP optimization (informative), 9.2 Syntax and semantics, 9.2.1 Uniform quantization method, 9.2.2 Codebook-based method, 9.2.3 Dependent scalar quantization method, 10 Entropy coding, 10.1 Methods, 10.1.1 DeepCABAC, 10.2 Syntax and semantics, 10.2.1 DeepCABAC syntax, 10.3 Entropy decoding process, 10.3.1 General, 10.3.2 Initialization process, 10.3.3 Binarization process, 10.3.4 Decoding process flow, Annex A (normative) Implementation for NNEF, A.1 General, A.2 Identifiers, A.3 Definitions for use in NNR bitstream, A.4 Carriage of NNEF data in NNR bitstream, Annex B (informative) Implementation for ONNX®, B.1 General, B.2 Identifiers, B.3 Definitions for use in NNR bitstream, B.4 Carriage of ONNX data in NNR bitstream, Annex C (informative) Implementation for PyTorch®, C.1 General, C.2 Identifiers, C.3 Definitions for use in NNR bitstream C.4 Carriage of PyTorch data in NNR bitstream, Annex D (informative) Implementation for TensorFlow®, D.1 General, D.2 Identifiers, D.3 Definitions for use in NNR bitstream, D.4 Carriage of TensorFlow data in NNR bitstream, Annex E (informative) Recommendation for carriage of NNR bitstreams in other containers, E.1 Recommendation for carriage of NNR bitstream in NNEF container organization (to be specified within the NNEF format specification), E.2 Recommendation for carriage of NNR coded bitstream inside ONNX (to be specified within the ONNX format specification), Bibliography for “Information technology—Multimedia content description interface” Furthermore, it is to be noted that some of the above sections (e.g. the Annexes A to E) may, for example, not be included in full herein for the sake of brevity, since features as disclosed therein are to be considered optional for embodiments of the invention. However, it is to be noted that embodiments according to the invention may comprise any or all of the features as disclosed in respective sections, e.g. as disclosed the full versions of the respective sections, e.g. as disclosed in the draft of the (e.g. planned) international standard ISO/IEC 15938-17 (e.g. ISO/IEC DIS 15938-17:xxxx(E)).

### Foreword

This proposed second edition cancels and replaces the first edition (ISO/IEC 15938-17), which has been technically revised.

The main changes compared to the previous edition are as follows:—xxx xxxxxxx xxx xxxx

### Introduction (any Details are Optional)

Artificial neural networks have been adopted for a broad range of tasks in multimedia analysis and processing, media coding, data analytics and many other fields. Their recent success is based on the feasibility of processing much larger and complex neural networks (deep neural networks, DNNs) than in the past, and the availability of large-scale training data sets. As a consequence, trained neural networks contain a large number of parameters and weights, resulting in a quite large size (e.g., several hundred MBs). Many applications require the deployment of a particular trained network instance, potentially to a larger number of devices, which may have limitations in terms of processing power and memory (e.g., mobile devices or smart cameras), and also in terms of communication bandwidth. Any use case, in which a trained neural network (or its updates) needs to be deployed to a number of devices thus benefits from a standard for the compressed representation of neural networks.

Considering the fact that compression of neural networks is likely to have a hardware dependent and hardware independent component, this document is designed as a toolbox of compression technologies. Some of these technologies require specific representations in an exchange format (i.e., sparse representations, adaptive quantization), and thus a normative specification for representing outputs of these technologies is defined. Others do not at all materialize in a serialized representation (e.g. pruning), however, also for the latter ones required metadata is specified. This document is independent of a particular neural network exchange format, and interoperability with common formats is described in the annexes.

This document thus defines a high-level syntax that specifies required metadata elements and related semantics. In cases where the structure of binary data is to be specified (e.g., decomposed matrices) this document also specifies the actual bitstream syntax of the respective block. Annexes to the document specify the requirements and constraints of compressed neural network representations; as defined in this document; and how it is applied.
A specifies, as an example, the implementation of this document with the Neural Network Exchange Format (NNEF), defining the use of NNEF to represent network topologies in a compressed neural network bitstream.
Annex B provides, as an example, recommendations for the implementation of this document with the Open Neural Network Exchange Format (ONNX) @¹, defining the use of ONNX to represent network topologies in a compressed neural network bitstream. ¹ ONNX is the trademark of a product owned by LF PROJECTS, LLC. This information is given for the convenience of users of this document and does not constitute an endorsement by ISO/IEC of the product named.
Annex C provides, as an example, recommendations for the implementation of this document with the PyTorch®² format, defining the reference to PyTorch elements in the network topology description of a compressed neural network bitstream. ² PyTorch is the trademark of a product supplied by Facebook, Inc. This information is given for the convenience of users of this document and does not constitute an endorsement by ISO/IEC of the product named.
Annex D provides, as an example, recommendations for the implementation of this document with the Tensorflow®³ format, defining the reference to Tensorflow elements in the network topology description of a compressed neural network bitstream. ³ TensorFlow is the trademark of a product supplied by Google LLC. This information is given for the convenience of users of this document and does not constitute an endorsement by ISO/IEC of the product named.
Annex E provides, as an example, recommendations for the carriage of tensors compressed according to this document in third party container formats.

The compression tools described in this document have been selected and evaluated for neural networks used in applications for multimedia description, analysis and processing. However, they may be useful for the compression of neural networks used in other applications and applied to other types of data.

### Information Technology—Multimedia Content Description Interface—Part 17: Compression of Neural Networks for Multimedia Content Description and Analysis (2nd Ed)

### 1 Scope

This document specifies, as an example, a compressed representation of the parameters/weights of a trained neural network and a decoding process for the compressed representation, complementing the description of the network topology in existing (exchange) formats for neural networks. It establishes a toolbox of compression methods, specifying (where applicable) the resulting elements of the compressed bitstream. All of these tools can, for example, be applied to the compression of entire neural networks, and some of them can, for example, also be applied to the compression of differential updates of neural networks with respect to a base network. Such differential updates are for example useful when models are redistributed after fine-tuning or transfer learning, or when providing versions of a neural network with different compression ratios.

This document specifies, for example, compressed representations for neural networks which can further be incorporated in other standards. Only the syntax format, semantics, associated decoding process requirements, parameter sparsification, parameter transformation methods, parameter quantization, entropy coding method and integration/signalling within existing exchange formats are specified, while other matters such as pre-processing, system signalling and multiplexing, data loss recovery and post-processing are considered to be outside the scope of this document. Additionally, the internal processing steps performed within a decoder are also considered to be outside the scope of this document; only the externally observable output behaviour is required to conform to the specifications of this document.

### 2 Normative References

The following documents are referred to in the text in such a way that some or all of their content constitutes requirements of this document. For dated references, only the edition cited applies. For undated references, the latest edition of the referenced document (including any amendments) applies.
ISO/IEC 10646, Information technology—Universal coded character set (UCS)
ISO/IEC 60559, Information technology—Microprocessor Systems—Floating-Point arithmetic
IETF RFC 1950, ZLIB Compressed Data Format Specification version 3.3, 1996 NNEF-v1.0.3, Neural Network Exchange Format, The Khronos NNEF Working Group, Version 1.0.3, 2020-06-12 (https://www.khronos.org/registry/NNEF/specs/1.0/nnef-1.0.3.pdf)

### 3 Terms and Definitions

For the purposes of this document, the following terms and definitions apply. ISO and IEC maintain terminological databases for use in standardization at the following addresses:
ISO Online browsing platform: available at https://www.iso.org/obp
IEC Electropedia: available at http://www.electropedia.org/

### 3.1

### Aggregate NNR Unit

NNR unit which carries multiple NNR units in its payload

### 3.2

### Base Neural Network

neural network serving as reference for a differential update

### 3.3

### Compressed Neural Network Representation

representation of a neural network with model parameters encoded using compression tools

### 3.4

### Decomposition

transformation to express a tensor as product of two tensors

### 3.5

### Hyperparameter

parameter whose value is used to control the learning process

### 3.6

### Layer

collection of nodes operating together at a specific depth within a neural network

### 3.7

### Model Parameter

coefficients of the neural network model such as weights and biases

### 3.8

### NNR Unit

data structure for carrying (compressed or uncompressed) neural network data and related metadata

### 3.9

### Pruning

reduction of parameters in (a part of) the neural network

### 3.10

### Sparsification

increase of the number of zero-valued entries of a tensor

### 3.11

### Tensor

multidimensional structure grouping related model parameters

### 3.12

### Updated Neural Network

neural network resulting from modifying the base neural network

Note: The updated neural network is reconstructed by applying the differential update to the base neural network.

### 4 Abbreviated Terms, Conventions and Symbols

### 4.1 General

This subclause contains the definition of operators, notations, functions, textual conventions and processes used throughout this document.

The mathematical operators used in this document are similar to those used in the C programming language. However, the results of integer division and arithmetic shift operations are specified more precisely, and additional operations are specified, such as exponentiation and real-valued division. Numbering and counting conventions generally begin from 0, e.g., “the first” is equivalent to the 0-th, “the second” is equivalent to the 1-th, etc.

### 4.2 Abbreviated Terms

DeepCABAC Context-adaptive binary arithmetic coding for deep neural networks
LR Low-rank
LDR Low displacement rank
LPS Layer parameter set
LSB Least significant bit
MSB Most significant bit
MPS Model parameter set
NN Neural network
NNEF Neural network exchange format
NNR Compressed neural network representation
SVD Singular value decomposition

### 4.3 List of Symbols

This document defines the following symbols:
A Input tensor
B Output tensor
Bⱼₗ^{k} Block in superblock j of layer k.
b Bias parameter
Cᵢₙ Number of input channels of a convolutional layer
Cₒᵤₜ Number of output channels of a convolutional layer
cⱼ^{k} Number of channels of tensor in layer k.
cⱼ^{k′} Derived number of channels of tensor in layer k.
dⱼ^{k} Depth dimension of tensor at layer k.
e Parameter of f-circulant matrix Zₑ.
F Parameter tensor of a convolutional layer
f Parameter of f-circulant matrix Zf.
Gₖ Left-hand side matrix of Low Rank decomposed representation of matrix Wₖ
Hₖ Right-hand side matrix of Low Rank decomposed representation of matrix Wₖ
hⱼ^{k} Height dimension of tensor for layer k.
K Dimension of a convolutional kernel
L Network
L_{compressibility} Compressibility loss
L_{diversity} Diversity loss
Lₜₐₛₖ Task loss
Lₜᵣₐᵢₙ Training loss
M Feature matrix
Mₖ Pruning mask
m Sparsification hyperparameter
mᵢ i-th row of feature matrix M
nⱼ^{k} Kernel size of tensor at layer k.
n^{k} Dimension resulting a product of nⱼ^{k}.
P Stochastic transition matrix
p Pruning ratio hyperparameter
p_{i,j} Elements of transition matrix P
q Sparsification ratio hyperparameter
S Importance of parameters for pruning
Sⱼ^{k} Superblock
s Local scaling factors
sⱼ^{k} size of superblock
u Unification ratio hyperparameter
W Parameter tensor
Wₗ Weight tensor of l-th layer
Wₖ Parameter tensor of layer k
Wₖ Low Rank approximation of Wₖ
w Parameter vector
vⱼ^{k} Width dimension of tensor for layer k.
w_{l,i} Vector of weights for the i-th filter in the l-th layer
w′_{l,i} Vector of normalized weights for the i-th filter in the l-th layer
X Input to a batch-normalization layer
Zₑ f-circulant matrix
Z_{f} f-circulant matrix
α Folded batch normalization parameter
α′ Combined value for folded batch normalization parameter and local scaling factors
β Batch normalization parameter
γ_{c} Compressibility loss multiplier
γ Batch normalization parameter
δ Folded batch normalization parameter
ϵ Scalar close to zero to avoid division by zero in batch normalization
λ Eigenvector
λₑ Compressibility loss weight
λ_{d} Diversity loss weight
μ Batch normalization parameter
π Equilibrium probability of P
σ Batch normalization parameter
τ Sparsification pruning threshold
φ Smoothing factor

### 4.4 Number Formats and Computation Conventions

This document defines the following number formats:
integer Integer number which may be arbitrarily small or large. Integers are also referred to as signed integers.
unsigned integer Unsigned integer that may be zero or arbitrarily large.
float floating point number according to ISO/IEC 60559.

If not specified otherwise, outcomes of all operators and mathematical functions are mathematically exact. Whenever an outcome shall be a float, it is explicitly specified.

### 4.5 Arithmetic Operators

The following arithmetic operators are defined:
+ Addition
− Subtraction (as a two-argument operator) or negation (as a unary prefix operator)
* Multiplication, including matrix multiplication
∘ Element-wise multiplication of two transposed vectors or element-wise multiplication of a transposed vector with rows of a matrix or Hadamard product of two matrices with identical dimensions
x^{y} Exponentiation. Specifies x to the power of y. In other contexts, such notation is used for superscripting not intended for interpretation as exponentiation.
/ Integer division with truncation of the result toward zero. For example, 7/4 and −7/−4 are truncated to 1 and −7/4 and 7/−4 are truncated to −1.
÷ Used to denote division in mathematical equations where no truncation or rounding is intended.
Used to denote division in mathematical equations where no truncation or rounding is intended, including element-wise division of
x/y two transposed vectors or element-wise division of a transposed vector with rows of a matrix.
Σᵢ₌ₓ^{y}f(i) The summation of f(i) with i taking all integer values from x up to and including y.
Πᵢ₌ₓ^{y}f(i) The product of f(i) with i taking all integer values from x up to and including y.
x % y Modulus. Remainder of x divided by y, defined only for integers x and y with x≥0 and y>0.

### 4.6 Logical Operators

The following logical operators are defined:
x && y Boolean logical “and” of x and y
x ∥ y Boolean logical “or” of x and y
   | Boolean logical “not”
x ? y:z If x is TRUE or not equal to 0, evaluates to the value of y; otherwise, evaluates to the value of z.

### 4.7 Relational Operators

The following relational operators are defined as follows:
> Greater than
≥ Greater than or equal to
< Less than
≤ Less than or equal to
== Equal to
!= Not equal to

When a relational operator is applied to a syntax element or variable that has been assigned the value “na” (not applicable), the value “na” is treated as a distinct value for the syntax element or variable. The value “na” is considered not to be equal to any other value.

### 4.8 Bit-Wise Operators

The following bit-wise operators are defined as follows:
& Bit-wise “and”. When operating on integer arguments, operates on a two's complement representation of the integer value. When operating on a binary argument that contains fewer bits than another argument, the shorter argument is extended by adding more significant bits equal to 0.
   | Bit-wise “or”. When operating on integer arguments, operates on a two's complement representation of the integer value. When operating on a binary argument that contains fewer bits than another argument, the shorter argument is extended by adding more significant bits equal to 0.
\hat{ } Bit-wise “exclusive or”. When operating on integer arguments, operates on a two's complement representation of the integer value. When operating on a binary argument that contains fewer bits than another argument, the shorter argument is extended by adding more significant bits equal to 0.
x>>y Arithmetic right shift of a two's complement integer representation of x by y binary digits. This function is defined only for non-negative integer values of y. Bits shifted into the MSBs as a result of the right shift have a value equal to the MSB of x prior to the shift operation.
x<<y Arithmetic left shift of a two's complement integer representation of x by y binary digits. This function is defined only for non-negative integer values of y. Bits shifted into the LSBs as a result of the left shift have a value equal to 0.

! Bit-wise not operator returning 1 if applied to 0 and 0 if applied to 1.

### 4.9 Assignment Operators

The following arithmetic operators are defined as follows:
= Assignment operator
++ Increment, i.e., x++ is equivalent to x=x+1; when used in an array index, evaluates to the value of the variable prior to the increment operation.
−− Decrement, i.e., x−− is equivalent to x=x−1; when used in an array index, evaluates to the value of the variable prior to the decrement operation.
+=Increment by amount specified, i.e., x+=3 is equivalent to x=x+3, and x+=(−3) is equivalent to x=x+(−3).
−= Decrement by amount specified, i.e., x−=3 is equivalent to x=x−3, and x−=(−3) is equivalent to x=x−(−3).

### 4.10 Range Notation

The following notation is used to specify a range of values:
x=y . . . z x takes on integer values starting from y to z, inclusive, with x, y, and z being integer numbers and z being greater than y.
array[x, y] a sub-array containing the elements of array comprised between position x and y included. If x is greater than y, the resulting sub-array is empty.

### 4.11 Mathematical Functions

The following mathematical functions are defined:
Ceil(x) the smallest integer greater than or equal to x
Floor(x) the largest integer less than or equal to x
Log 2(x) the base-2 logarithm of x

$$Min ( x , y ) = \{ \begin{matrix}x ; & x \leq y \\ y ; & x > y\end{matrix} Max ( x , y ) = \{ \begin{matrix}x ; & x \geq y \\ y ; & x < y\end{matrix}$$

### 4.12 Array Functions

Size(arrayName[ ]) returns the number of elements contained in the array or tensor named arrayName. If arrayName[ ] is a tensor this corresponds to the product of all dimensions of the tensor. (optional)

Prod(arrayName[ ]) returns the product of all elements of array arrayName[ ]. (Optional)

TensorReshape(arrayName[ ], tensorDimension[ ]) returns the reshaped tensor array_name[ ] with the specified tensorDimension[ ], without changing its data. (optional)

IndexToXY(w, h, i, bs) returns, for example, an array with two elements. For example, the first element is an x coordinate and the second element is a y coordinate, for example, pointing into a 2D array of width w and height h. For example, x and y point to the position that corresponds to scan index i when the block is scanned in blocks, for example, of size bs times bs. For example, x and y are derived as follows:
A variable fullRowOfBlocks is set to w*bs
A variable blockY is set to i/fullRowOfBlocks
A variable iOff is set to i % fullRowOfBlocks
A variable currBlockH is set to Min(bs, h−blockY*bs)
A variable fullBlocks is set to bs*currBlockH
A variable blockX is set to iOff/fullBlocks
A variable blockOff is set to iOff % fullBlocks
A variable currBlockW is set to Min(bs, w−blockX*bs)
A variable posX is set to blockOff % currBlockW
A variable posY is set to blockOff/currBlockW
The variable x is set to blockX*bs+posX
The variable y is set to blockY*bs+posY

TensorIndex(tensorDimensions[ ], i, scan) returns, for example, an array with the same number of dimensions as tensorDimensions[ ] where, for example, the elements of the array are set to integer values so that the array can be used, for example, as an index pointing to an element of a tensor with dimensions tensorDimensions[ ], for example, as follows:
If variable scan is equal to 0:
   The returned array points, for example, to the i-th element in row-major scan order of a tensor with
   dimensions tensorDimensions[ ].
If variable scan is greater than 0: (optional) (example)
   A variable bs is set, for example, to 4<<scan_order.
   A variable h is set, for example, to tensorDimensions[0].
   A variable w is set, for example, to Prod(tensorDimensions)/h
   Two variables x and y are set, for example, to the first and second element of the array that is
      returned, for example,
      by calling IndexToXY(w, h, i, bs), respectively.
   The returned array is, for example, TensorIndex(tensorDimensions, y*w+x, 0).
NOTE—Variable scan usually (but not necessarily) corresponds to syntax element scan_order.

GetEntryPointIdx(tensorDimensions[ ], i, scan) (optional) returns, for example, −1 if index i doesn't point to the first position of an entry point. If index i points to the first position of an entry point, it returns, for example, the entry point index within the tensor. To determine the positions and indexes of entry points, the following applies: (example)
A variable w is set to Prod(tensorDimensions)/tensorDimensions[0]
A variable epIdx is set to i/(w*(4<<scan))−1
If i>0 and i % (w*(4<<scan)) is equal to 0, index i points to the first position of an entry point and the entry point index is equal to epIdx.
Otherwise, index i doesn't point to the first position of an entry point.

ShiftArrayIndex(inputArray[ ], shiftIndexPosition) returns, for example, an array outputArray[ ] which is, for example, a copy of inputArray[ ] but with the element at position 0 of the inputArray shifted to shiftIndexPosition, for example, as follows:
A variable outputArray[ ] is, for example, initialized with a copy of inputArray[ ].
If shiftIndexPosition is greater than 0:
   The first element of outputArray[ ] is, fₒ example, erased from outputArray[ ].
The first element of inputArray[ ] is, for example, inserted into outputArray[ ] before the element with position shiftIndexPosition and after element with position shiftIndexPosition-1.

AxisSwap(inputTensor[ ], tensorDimensions[ ], numberOfDimensions, axis0, axis1) (optional) returns a tensor which is derived from inputTensor (with dimensions tensorDimensions and number of dimensions as numberOfDimensions) and where values in the axis indexes axis0 and axis1 of the inputTensor are swapped.

TensorSplit(inputTensor[ ], splitIndices, splitAxis) (optional) returns an array of tensors subTensors that is derived by splitting tensor inputTensor into N=Size(splitIndices)+1 tensors using the provided array of indices splitIndices along the provided axis splitAxis as follows:
An array inputDims is set to the dimensions of tensor inputTensor.
An element with value 0 is inserted into splitIndices before the first element and an element with value inputDims[splitAxis] is inserted into splitIndices after the last element.
Tensor subTensors[X] (with X being an integer from 0 to N) is derived as follows:

```
  An array subTensorDims is set to inputDims.
  Element subTensorDims[splitAxis] is replaced with value splitIndices[X
+ 1] − splitIndices[X].
  The elements of subTensors[X] are set as follows:
    for( i = 0; i < Prod( subTensorDims ); i++ ) {
      subIdx = TensorIndex( subTensorDims, i, 0 )
      inputIdx = TensorIndex( inputDims, i, 0 )
      inputIdx[splitAxis] += splitIndices[X]
      subTensors[subIdx] = inputTensor[inputIdx]
```

### 4.13 Order of Operation Precedence

When the order of precedence in an expression is not indicated explicitly by use of parentheses, the following rules apply:
Operations of a higher precedence are evaluated before any operation of a lower precedence.
Operations of the same precedence are evaluated sequentially from left to right.

Table 1 specifies the precedence of operations from highest to lowest; a higher position in the table indicates a higher precedence.
NOTE—For those operators that are also used in the C programming language, the order of precedence used in this document is the same as used in the C programming language.

TABLE 1
Operation precedence from highest (at top of table) to lowest
(at bottom of table).

operations (with operands x, y, and z)
“x+ +”, “x− −”
“!x”, “−x” (as a unary prefix operator)
x^{y}
“x * y”, “x / y”, “x ÷ y”, $“ \frac{x}{y} ” ,$ “x % y”, “Πᵢ₌ₓ^{y}f (i)”,
“x ∘ y”
“x + y”, “x − y” (as a two-argument operator),
“Σᵢ₌ₓ^{y} f (i)”
“x << y”, “x >> y”
“x < y”, “x ≤ y”, “x > y”, “x ≥ y”
“x = = y”, “x != y”
“x & y”
“x | y”
“x && y”
“x | | y”
“x ? y : z”
“x..y”
“x = y”, “x += y”, “x −= y”

### 4.14 Variables, Syntax Elements and Tables

Syntax elements in the bitstream are represented in bold type. Each syntax element is described by its name (all lower case letters with underscore characters), and one data type for its method of coded representation. The decoding process behaves according to the value of the syntax element and to the values of previously decoded syntax elements. When a value of a syntax element is used in the syntax tables or the text, it appears in regular (i.e., not bold) type.

In some cases the syntax tables may use the values of other variables derived from syntax elements values. Such variables appear in the syntax tables, or text, named by a mixture of lower case and upper case letter and without any underscore characters (camel case notation). Variables starting with an upper case letter are derived for the decoding of the current syntax structure and all depending syntax structures. Variables starting with an upper case letter may be used in the decoding process for later syntax structures without mentioning the originating syntax structure of the variable. Variables starting with a lower case letter are only used within the (sub)clause in which they are derived.

In some cases, “mnemonic” names for syntax element values or variable values are used interchangeably with their numerical values. Sometimes “mnemonic” names are used without any associated numerical values. The association of values and names is specified in the text. The names are constructed from one or more groups of letters separated by an underscore character. Each group starts with an upper case letter and may contain more upper case letters.
NOTE—The syntax is described in a manner that closely follows the C-language syntactic constructs.

Functions that specify properties of the current position in the bitstream are referred to as syntax functions. These functions are specified in subclause 6.3 and assume the existence of a bitstream pointer with an indication of the position of the next bit to be read by the decoding process from the bitstream. Syntax functions are described by their names, which are constructed as syntax element names and end with left and right round parentheses including zero or more variable names (for definition) or values (for usage), separated by commas (if more than one variable).

Functions that are not syntax functions (including mathematical functions specified in subclause 4.11 and array functions specified in subclause 4.12) are described by their names, which start with an upper case letter, contain a mixture of lower and upper case letters without any underscore character, and end with left and right parentheses including zero or more variable names (for definition) or values (for usage) separated by commas (if more than one variable).

A one-dimensional array is referred to as a list. A two-dimensional array is referred to as a matrix. Arrays can either be syntax elements or variables. Subscripts or square parentheses are used for the indexing of arrays. In reference to a visual depiction of a matrix, the first subscript is used as a row (vertical) index and the second subscript is used as a column (horizontal) index. The indexing order is reversed when using square parentheses rather than subscripts for indexing. Thus, an element of a matrix s at horizontal position x and vertical position y may be denoted either as s[x][y] or as s_{yx}. A single column of a matrix may be referred to as a list and denoted by omission of the row index. Thus, the column of a matrix s at horizontal position x may be referred to as the list s[x].

A multi-dimensional array is a variable with a number of dimensions. An element of the multi-dimensional array is either indexed by specifying all required indexes like e.g. variable[x][y][z] or by a single index variable that itself is a one-dimensional array specifying the indexes. For example variable[i] with i being a one-dimensional array with elements [x, y, z]. Multi-dimensional arrays are, for example, used to specify tensors.

A specification of values of the entries in rows and columns of an array may be denoted by {{ . . . } { . . . } }, where each inner pair of brackets specifies the values of the elements within a row in increasing column order and the rows are ordered in increasing row order. Thus, setting a matrix s equal to {{1 6} {4 9} } specifies that s[0][0] is set equal to 1, s[1][0] is set equal to 6, s[0][1] is set equal to 4, and s[1][1] is set equal to 9.

Binary notation is indicated by enclosing the string of bit values by single quote marks. For example, ‘01000001’ represents an eight-bit string having only its second and its last bits (counted from the most to the least significant bit) equal to 1.

Hexadecimal notation, indicated by prefixing the hexadecimal number by “0x”, may be used instead of binary notation when the number of bits is an integer multiple of 4. For example, 0x41 represents an eight-bit string having only its second and its last bits (counted from the most to the least significant bit) equal to 1.

Numerical values not enclosed in single quotes and not prefixed by “0x” are decimal values.

A value equal to 0 represents a FALSE condition in a test statement. The value TRUE is represented by any value different from zero.

### 5 Overview

### 5.1 General

This clause provides an overview of the compression tools defined in this document and describes how they can, for example, be combined to encoding.

### 5.2 Compression Tools (Examples; all Details are Optional)

This document contains the following groups of compression tools.

Parameter reduction methods process a model to obtain a compact representation. Examples of such methods include, parameter sparsification, parameter pruning, weight unification, and decomposition methods.

Sparsification processes parameters or group of parameters to produce a sparse representation of the model, e.g., by replacing some weight values with zeros. The sparsification can generate additional metadata (e.g. masks). The sparsification can be structured or unstructured. This document includes methods for unstructured sparsification with compressibility loss (e.g. as disclosed in the respective subclause), structured sparsification using micro-structured sparsification (e.g. as disclosed in the respective subclause), unstructured statistics-adaptive sparsification (e.g. as disclosed in the respective subclause), and structed sparsification (e.g. as disclosed in the respective subclause).

Unification processes the parameters to produce group of similar parameters. Unification does not eliminate or constrain the weights to be zero, but it lowers the entropy of model parameters by making them similar to each other. This document includes a method for weight unification (e.g. as disclosed in the respective subclause).

Pruning reduces the number of parameters by eliminating parameters or group of parameters. The procedure results in a dense representation which has less parameters in comparison to the original model, e.g., by removing some redundant convolution filters from the layers. This document includes a method for combined pruning and sparsification (e.g. as disclosed in the respective subclause).

Decomposition performs a matrix decomposition operation to change the structure of the weights of a model. This document includes a method for low rank/low displacement rank for convolutional and fully connected layers (e.g. as disclosed in the respective subclause).

Along with the reduction methods mentioned above, this document includes decomposition methods that are introduced and tested as part of a parameter quantization technique. Examples of such methods are batchnorm folding (e.g. as disclosed in the respective subclause) and local scaling adaptation (e.g. as disclosed in the respective subclause).

The parameter reduction methods could be combined or applied in sequence to produce a compact model.

Parameter quantization methods reduce the precision of the representation of parameters. If supported by the inference engine, the quantized representation can be used for more efficient inference. This document includes methods for uniform quantization (e.g. as disclosed in the respective subclause), codebook-based quantization (e.g. as disclosed in the respective subclause), dependent scalar quantization (e.g. as disclosed in the respective subclause), and iterative QP optimization (e.g. as disclosed in the respective subclause).

Entropy coding methods encode the results of parameter quantization methods. This document includes DeepCABAC (subclause 9.1.1) as entropy encoding method Supported extensions for DeepCABAC include Row Skipping and Temporal Context Modeling.

Row Skipping reduces the number of bins to be decoded and also the bitstream size by skipping decoding of matrix rows that are entirely zero. For this Row Skip signals one flag per matrix row. The method is described in subclause 9.1.1.2.

Temporal Context Modeling uses information from previously decoded incremental updates to improve the context modeling of DeepCABAC and thus increases the coding efficiency. The method is described in subclause 9.1.1.4.

### 5.3 Creating Encoding Pipelines (Examples, all Details are Optional)

The compression tools in this document can be combined to form different encoding pipelines. Some of the tools are alternatives for addressing neural network models with different types of characteristics, while other tools are designed to work in sequence.

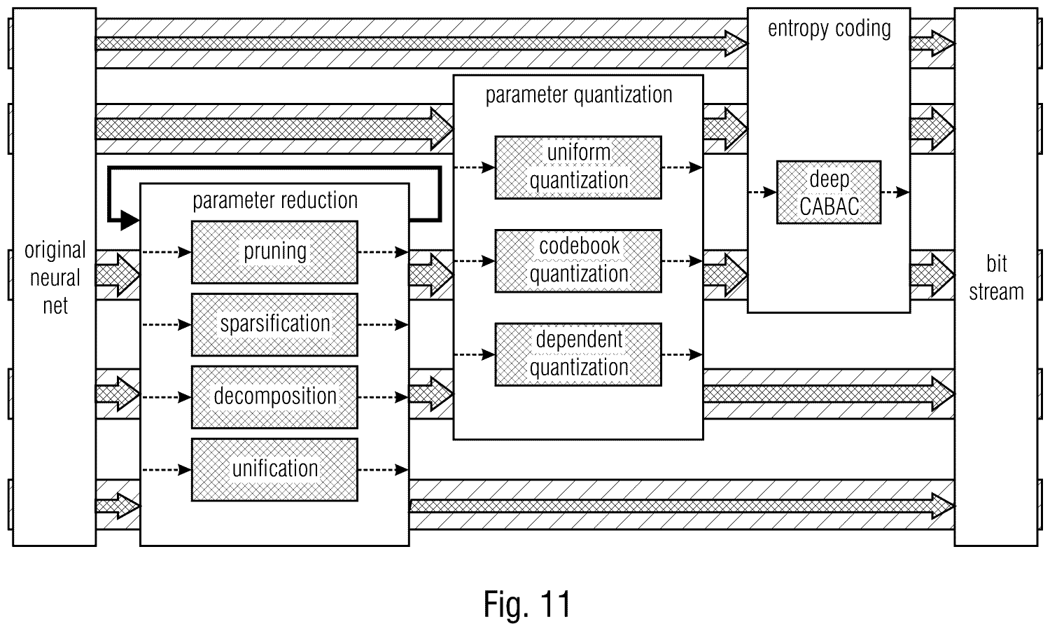

FIG. 11 shows a schematic overview of encoding pipelines according to embodiments that can optionally be assembled using the compression tools in this document. FIG. 11 shows a schematic example of NNR encoding pipelines according to embodiments. From the group of parameter transformation tools, multiple tools can be applied in sequence. Parameter quantization can be applied to source models as well as to the outputs of transformation with parameter reduction methods. Entropy coding is usually applied to the output of quantization.

Raw outputs of earlier steps without applying entropy coding can be serialized if needed.

The following encoding pipelines are considered typical examples of using this document:
1. Dependent scalar quantization (e.g. as disclosed in the respective subclause)—DeepCABAC (subclause 9.1.1)
2. Sparsification (e.g. as disclosed in the respective subclause)—Dependent scalar quantization (e.g. as disclosed in the respective subclause)—DeepCABAC (subclause 9.1.1)
3. Low-rank decomposition (e.g. as disclosed in the respective subclause)—Dependent scalar quantization (e.g. as disclosed in the respective subclause)—DeepCABAC (subclause 9.1.1)
4. Codebook-based quantization (e.g. as disclosed in the respective subclause)—DeepCABAC (subclause 9.1.1)
5. Unification (e.g. as disclosed in the respective subclause)—DeepCABAC (subclause 9.1.1)

This list is non-exhaustive.

### 6 Syntax and Semantics (all Details are Optional)

[Ed. Note (HT) after MPEG 135: Changes regarding section 8 new additions for incremental weight update could be introduced later]

### 6.1 Specification of Syntax and Semantics

### 6.1.1 Method of Specifying Syntax in Tabular Form

The syntax tables specify a superset of the syntax of all allowed bitstreams. Additional constraints on the syntax may be specified, either directly or indirectly, in other clauses.

Table 2 lists examples of the syntax specification format. When syntax_element appears, it specifies that a syntax element is parsed from the bitstream and the bitstream pointer is advanced to the next position beyond the syntax element in the bitstream parsing process.

TABLE 2
Examples of the syntax specification format

| | Type/ |
|---|---|
| Syntax | Clause |
| /* A statement can be a syntax element with an associated data | |
| type or can be an expression used to specify conditions for the | |
| existence, type and quantity of syntax elements, as in the | |
| following two examples */ | |
| syntax_element | st(v) |
| conditioning statement | |
| /*A group of statements enclosed in curly brackets is a | |
| compound statement and is treated functionally as a single | |
| statement. */ | |
| { | |
| statement | |
| statement | |
| ... | |
| } | |
| /* A “while” structure specifies a test of whether a condition is | |
| true, and if true, specifies evaluation of a statement (or | |
| compound statement) repeatedly until the condition is no longer | |
| true */ | |
| while( condition ) | |
| statement | |
| /* A “do ... while” structure specifies evaluation of a statement | |
| once, followed by a test of whether a condition is true, and if | |
| true, specifies repeated evaluation of the statement until the | |
| condition is no longer true */ | |
| do | |
| statement | |
| while( condition ) | |
| /* An “if ... else” structure specifies a test of whether a condition | |
| is true and, if the condition is true, specifies evaluation of a | |
| primary statement, otherwise, specifies evaluation of an | |
| alternative statement. The “else” part of the structure and the | |
| associated alternative statement is omitted if no alternative | |
| statement evaluation is needed */ | |
| if( condition ) | |
| primary statement | |
| else | |
| alternative statement | |
| /* A “for” structure specifies evaluation of an initial statement, | |
| followed by a test of a condition, and if the condition is true, | |
| specifies repeated evaluation of a primary statement followed by | |
| a subsequent statement until the condition is no longer true. */ | |
| for( initial statement; condition; subsequent statement ) | |
| primary statement | |

### 6.1.2 Bit Ordering (Examples)

For bit-oriented delivery, the bit order of syntax fields in the syntax tables is specified to start with the MSB and proceed to the LSB.

### 6.1.3 Specification of Syntax Functions and Data Types (Examples)

The functions presented here are used in the syntactical description. These functions are expressed in terms of the value of a bitstream pointer that indicates the position of the next bit to be read by the decoding process from the bitstream.

byte_aligned( ) is specified as follows:
If the current position in the bitstream is on a byte boundary, i.e. the next bit in the bitstream is the first bit in a byte, the return value of byte_aligned( ) is equal to TRUE.
Otherwise, the return value of byte_aligned( ) is equal to FALSE.

read_bits(n) reads the next n bits from the bitstream and advances the bitstream pointer by n bit positions. When n is equal to 0, read_bits(n) is specified to return a value equal to 0 and to not advance the bitstream pointer.

get_bit_pointer( ) returns the position of the bitstream pointer relative to the beginning of the current NNR unit as unsigned integer value. get_bit_pointer( )>>3 points to the current byte of the bitstream pointer. get_bit_pointer( )& 7 points to the current bit in the current byte of the bitstream pointer where a value of 0 indicates the most significant bit.

set_bit_pointer(pos) sets the position of the bitstream pointer such that get_bit_pointer( ) equals pos.

The following data types specify the parsing process of each syntax element:
ae(v): context-adaptive arithmetic entropy-coded syntax element. The parsing process for this data type is specified in subclause 9.3.4.3.2.
at(v): arithmetic entropy-coded termination syntax. The parsing process for this data type is specified in subclause 9.3.4.3.5.
iae(n): signed integer using n arithmetic entropy-coded bits using the bypass mode of DeepCABAC as specified in subclause 9.3.4.3.4. The read bypass bins are interpreted as a two's complement integer representation with most significant bit written first.
uae(n): unsigned integer using n arithmetic entropy-coded bits using the bypass mode of DeepCABAC as specified in subclause 9.3.4.3.4. The read bypass bins are interpreted as a binary representation of an unsigned integer with most significant bit written first. When n=0, uae(n) does not decode any bins and returns 0.
f(n): fixed-pattern bit string using n bits written (from left to right) with the left bit first. The parsing process for this data type is specified by the return value of the function read_bits(n).
i(n): signed integer using n bits. When n is “v” in the syntax table, the number of bits varies in a manner dependent on the value of other syntax elements. The parsing process for this data type is specified by the return value of the function read_bits(n) interpreted as a two's complement integer representation with most significant bit written first.
u(n): unsigned integer using n bits. When n is “v” in the syntax table, the number of bits varies in a manner dependent on the value of other syntax elements. The parsing process for this data type is specified by the return value of the function read_bits(n) interpreted as a binary representation of an unsigned integer with most significant bit written first.
ue(k): unsigned integer k-th order Exp-Golomb-coded syntax element. The parsing process for this descriptor is according to the following pseudo-code with x as result:

```
x = 0
bit = 1
while( bit ) {
  bit = 1 − u( 1 )
  x += bit << k
  k += 1
}
k −= 1
if( k > 0 )
  x += u( k )
```

ie(k): signed integer k-th order Exp-Golomb-coded syntax element. The parsing process for this descriptor is according to the following pseudo-code with x as result:

```
val = ue( k )
  if( (val & 1) != 0 )
    x = ((val+1)>>1)
  else
    x = − (val>>1)
```

flt(n): Floating point value using n bits where n may be 32, 64, or 128 in little-endian byte order as specified in ISO/IEC 60559 as binary32, binary64, or binary128, respectively.
st(v): null-terminated string, which shall be encoded as UTF-8 characters in accordance with ISO/IEC 10646. The parsing process is specified as follows: st(v) begins at a byte-aligned position in the bitstream and reads and returns a series of bytes from the bitstream, beginning at the current position and continuing up to but not including the next byte-aligned byte that is equal to 0x00, and advances the bitstream pointer by (stringLength+1)*8 bit positions, where stringLength is equal to the number of bytes returned.
NOTE The st(v) and flt(n) syntax descriptors are only used in this document when the current position in the bitstream is a byte-aligned position.
bs(v): Byte-sequence specifies a sequence of bytes of variable length, starting at byte-aligned position. The length of the sequence is determined from the size of the NNR unit containing the byte sequence.

more_data_in_nnr_unit( ) is specified as follows:
If more data follow in the current nnr_unit, i.e. the decoded data up to now in the current nnr_unit is less than numByteslnNNRUnit, the return value of more_data_in_nnr_unit( ) is equal to TRUE.
Otherwise, the return value of more_data_in_nnr_unit( ) is equal to FALSE.

### 6.1.4 Semantics (Examples)

Semantics associated with the syntax structures and with the syntax elements within each structure are specified in a subclause following the subclause containing the syntax structures.

The following definitions apply to the semantics specification.

unspecified is used to specify some values of a particular syntax element to indicate that the values have no specified meaning in this document and will not have a specified meaning in the future as an integral part of future versions of this document.

reserved is used to specify that some values of a particular syntax element are for future use by ISO/IEC and shall not be used in bitstreams conforming to this version of this document, but may be used in bitstreams conforming to future extensions of this document by ISO/IEC.]

nnr_reserved_zero_Obit shall be an element of length 0. Decoders shall ignore the value of nnr_reserved_zero_Obit.

nnr_reserved_zero_1 bit, when present, shall be equal to 0 in bitstreams conforming to this version of this document. Other values for

nnr_reserved_zero_1 bit are reserved for future use by ISO/IEC. Decoders shall ignore the value of nnr_reserved_zero_1 bit.

nnr_reserved_zero_2bits, when present, shall be equal to 0 in bitstreams conforming to this version of this document. Other values for nnr_reserved_zero_2bits are reserved for future use by ISO/IEC. Decoders shall ignore the value of nnr_reserved_zero_2bits.

nnr_reserved_zero_3bits, when present, shall be equal to 0 in bitstreams conforming to this version of this document. Other values for nnr_reserved_zero_3bits are reserved for future use by ISO/IEC. Decoders shall ignore the value of nnr_reserved_zero_3bits.

nnr_reserved_zero_5bits, when present, shall be equal to 0 in bitstreams conforming to this version of this document. Other values for nnr_reserved_zero_5bits are reserved for future use by ISO/IEC. Decoders shall ignore the value of nnr_reserved_zero_5bits.

nnr_reserved_zero_7bits, when present, shall be equal to 0 in bitstreams conforming to this version of this document. Other values for nnr_reserved_zero_7bits are reserved for future use by ISO/IEC. Decoders shall ignore the value of nnr_reserved_zero_7bits.

### 6.2 General Bitstream Syntax Elements (Examples, all Details are Optional)

### 6.2.1 NNR Unit

For example, NNR unit may be the data structure for carrying neural network data and related metadata which is compressed or represented using this document. NNR units carry, for example, compressed or uncompressed information, for example, about neural network metadata, topology information, complete or partial layer data, filters, kernels, biases, quantized weights, tensors or alike.

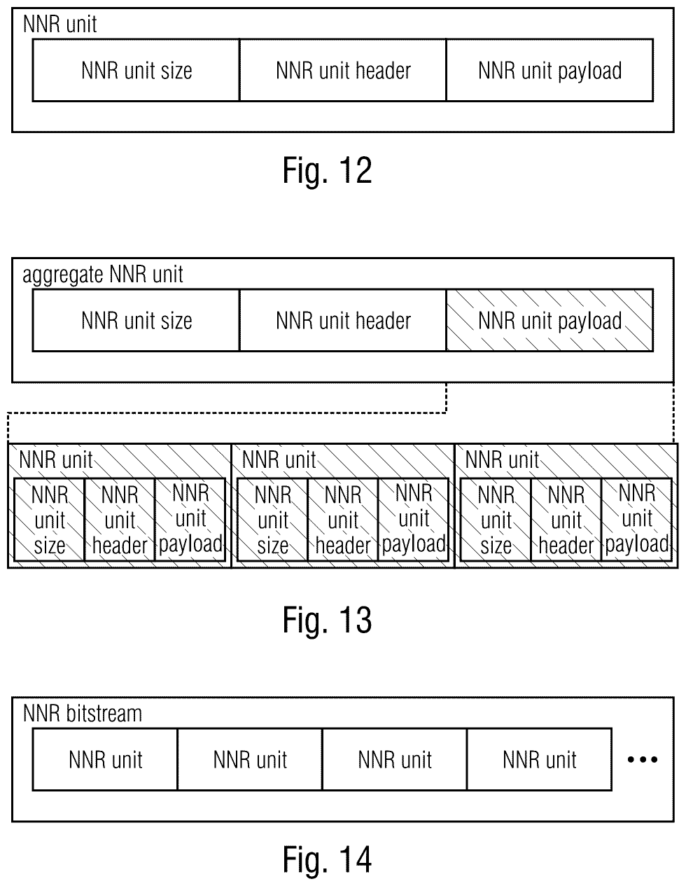

An NNR unit consists, for example, of the following data elements (shown, as an example, in FIG. 12. FIG. 12 shows a schematic example of a NNR Unit data structure according to embodiments):
NNR unit size (optional): This data element signals, for example, the total byte size of the NNR Unit, including the NNR unit size.
NNR unit header (optional): This data element contains, for example, information about the NNR unit type and related metadata.
NNR unit payload: This data element contains, for example, compressed or uncompressed data related to the neural network.

### 6.2.2 Aggregate NNR Unit (Optional, Example)

For example, an aggregate NNR unit is an NNR unit which carries multiple NNR units in its payload. Aggregate NNR units provide, for example, a grouping mechanism for several NNR units which are related to each other and benefit from aggregation under a single NNR unit (shown in FIG. 13. FIG. 13 shows a schematic example for an aggregate NNR unit data structure).

### 6.2.3 Composition of NNR Bitstream (Optional; Example)

For example, NNR bitstream is composed of a sequence of NNR Units (shown in FIG. 14. FIG. 14 shows a schematic example of a NNR bitstream data structure according to embodiments).

In an NNR bitstream; for example, the following constraints apply unless otherwise stated in this document or defined by NNR profiles:
(for example, NNR_STR, NNR_MPS, NNR_NDU, NNR_LPS, NNR_TPL and NNR_QNT are NNR unit types, for example, as specified in Table 3 of subclause 6.4.3)
   An NNR bitstream shall, for example, start with an NNR start unit (NNR_STR) (subclause 6.4.3)
   There shall, for example, be a single NNR model parameter set (NNR_MPS) (subclause 6.4.3) in an NNR bitstream which shall, for example, precede any NNR_NDU (subclause 6.4.3) in the NNR bitstream
   For example, NNR layer parameter sets (NNR_LPS) shall be active until the next NNR layer parameter set in the NNR bitstream or until the boundary of an Aggregate NNR unit is reached.
   For example, topology_elem_id and topology_elem_id_index (subclause 6.4.3.7) values shall be unique in the NNR bitstream.
   NNR_TPL or NNR_QNT units; if present in the NNR bitstream; shall precede any NNR_NDUs that reference their data structures (e.g. topology_elem_id)

### 6.3 NNR Bitstream Syntax (Example, all Details are Optional)

### 6.3.1 NNR Unit Syntax (Example)

Descriptor

```
nnr_unit( numBytesInNNRUnit ) {
  nnr_unit_size( ) (optional)
  nnr_unit_header( ) (optional)
  nnr_unit_payload( )
}
```

### 6.3.2 NNR Unit Size Syntax (Details are Optional)

### 6.3.3 NNR Unit Header Syntax (Details are Optional)

### 6.3.3.1 General

| | Descriptor |
|---|---|
| nnr_unit_header( ) { | |
| nnr_{—}unit_{—}type (optional) | u(6) |
| independently_{—}decodable_{—}flag (optional) | u(1) |
| partial_{—}data_{—}counter_{—}present_{—}flag (optional) | u(1) |
| if( partial_data_counter_present_flag ) | |
| partial_{—}data_{—}counter (optional) | u(8) |
| if( nnr_unit_type == NNR_MPS ) | |
| nnr_model_parameter_set_unit_header( ) | |
| (optional) | |
| if( nnr_unit_type == NNR_LPS ) | |
| nnr_layer_parameter_set_unit_header( ) | |
| (optional) | |
| if( nnr_unit_type == NNR_TPL ) | |
| nnr_topology_unit_header( ) (optional) | |
| if( nnr_unit_type == NNR_QNT ) | |
| nnr_quantization_unit_header( ) (optional) | |
| if( nnr_unit_type == NNR_NDU ) | |
| nnr_compressed_data_unit_header( ) | |
| if( nnr_unit_type == NNR_STR ) | |
| nnr_start_unit_header( ) | |
| if( nnr_unit_type == NNR_AGG ) | |
| nnr_aggregate_unit_header( ) (optional) | |
| } | |

### 6.3.3.2 NNR Start Unit Header Syntax (Details are Optional)

Descriptor
u(8)

### 6.3.3.3 NNR Model Parameter Set Unit Header Syntax (Details are Optional)

### 6.3.3.4 NNR Layer Parameter Set Unit Header Syntax (Details are Optional)

### 6.3.3.5 NNR Topology Unit Header Syntax (Details are Optional)

Descriptor
u(8)
u(8)

### 6.3.3.6 NNR Quantization Unit Header Syntax (Details are Optional)

Descriptor
u(8)
u(8)

### 6.3.3.7 NNR Compressed Data Unit Header Syntax (Example, all Details are Optional)

| | Descriptor |
|---|---|
| nnr_compressed_data_unit_header( ) { | |
| nnr_{—}compressed_{—}data_{—}unit_{—}payload_{—}type (optional) | u(5) |
| nnr_{—}multiple_{—}topology_{—}elements_{—}present_{—}flag (optional) | u(1) |
| nnr_{—}decompressed_{—}data_{—}format_{—}present_{—}flag (optional) | u(1) |
| input_{—}parameters_{—}present_{—}flag (optional) | u(1) |
| if( nnr_multiple_topology_elements_present_flag == 1 ) | |
| topology_elements_ids_list( mps_topology_indexed_reference_fl | |
| ag ) (optional) | |
| else { | |
| if( !mps_topology_indexed_reference_flag ) | |
| topology_{—}elem_{—}id (optional) | st(v) |
| Else | |
| topology_{—}elem_{—}id_{—}index (optional) | ue(7) |
| } | |
| if( general_profile_idc == 1 ) { | |
| node_{—}id_{—}present_{—}flag (optional= | u(1) |
| if( node_id_present_flag ) { | |
| device_{—}id (optional) | ue(1) |
| parameter_{—}id (optional) | ue(5) |
| put_{—}node_{—}depth (optional) | ue(4) |
| } | |
| parent_{—}node_{—}id_{—}present_{—}flag (optional) | u(1) |
| if( parent_node_id_present_flag ) { | |
| parent_{—}node_{—}id_{—}type (optional) | u(2) |
| temporal_{—}context_{—}modeling_{—}flag (optional) | u(1) |
| if( parent_node_id_type == ICNN_NDU_ID ) { | |
| parent_{—}device_{—}id (optional) | ue(1) |
| if( !node_id_present_flag ) { | |
| parameter_{—}id (optional) | ue(5) |
| put_{—}node_{—}depth (optional) | ue(4) |
| } | |
| } else if( parent_node_id_type == | |
| ICNN_NDU_PL_SHA256 ) | |
| parent_{—}node_{—}payload_{—}sha256 (optional) | u(256) |
| Else | |
| parent_{—}node_{—}payload_{—}sha512 (optional) | u(512) |
| } | |
| } | |
| if( nnr_compressed_data_unit_payload_type == | |
| NNR_PT_FLOAT \|\| | |
| nnr_compressed_data_unit_payload_type == | |
| NNR_PT_BLOCK ) { | |
| codebook_{—}present_{—}flag (optional) | u(1) |
| if( codebook_present_flag ) | |
| integer_codebook( CbZeroOffset, Codebook ) (optional) | |
| } | |
| if( nnr_compressed_data_unit_payload_type = = NNR_PT_INT \|\| | |
| nnr_compressed_data_unit_payload_type = = | |
| NNR_PT_FLOAT \|\| | |
| nnr_compressed_data_unit_payload_type = = | |
| NNR_PT_BLOCK ) | |
| dq_{—}flag (optional) | u(1) |
| if( nnr_decompressed_data_format_present_flag == 1 ) | |
| nnr_{—}decompressed_{—}data_{—}format(optional) | u(7) |
| if( input_parameters_present_flag == 1 ) { | |
| tensor_{—}dimensions_{—}flag (optional) | u(1) |
| cabac_{—}unary_{—}length_{—}flag (optional) | u(1) |
| compressed_{—}parameter_{—}types (optional) | u(4) |
| if( ( compressed_parameter_types & NNR_CPT_DC ) != 0 ){ | |
| decomposition_{—}rank (optional) | ue(3) |
| g_{—}number_{—}of_{—}rows (optional) | ue(3) |
| } | |
| if( tensor_dimensions_flag == 1 ) | |
| tensor_dimension_list( ) (optional) | |
| if ( nnr_compressed_data_unit_payload_type != | |
| NNR_PT_BLOCK ) | |
| if( nnr_multiple_topology_elements_present_flag == 1 ) | |
| topology_tensor_dimension_mapping( )(optional) | |
| if( cabac_unary_length_flag == 1 ) | |
| cabac_{—}unary_{—}length_{—}minus1 (optional) | u(8) |
| } | |
| if( nnr_compressed_data_unit_payload_type = = | |
| NNR_PT_BLOCK && | |
| ( compressed_parameter_types & NNR_CPT_DC ) != 0 && | |
| codebook_present_flag ) | |
| integer_codebook( CbZeroOffsetDC, CodebookDC ) | |
| (optional) | |
| if( count_tensor_dimensions > 1) { | |
| if(general_profile_idc == 1 ) (example) | |
| first_{—}tensor_{—}dimension_{—}shift (example) | ue(1) |
| scan_{—}order (optional) | u(4) |
| if( scan_order > 0 ) { | |
| for( j=0; j < NumBlockRowsMinus1; j++ ) { | |
| cabac_{—}offset_{—}list[ j ] (optional) | u(8) |
| if( dq_flag ) | |
| dq_{—}state_{—}list[ j ] (optional) | u(3) |
| if( j == 0 ){ | |
| bit_{—}offset_{—}delta1 (optional) | ue(11) |
| BitOffsetList[ j ] = bit_offset_delta1 | |
| } | |
| else { | |
| bit_{—}offset_{—}delta2 (optional) | ie(7) |
| BitOffsetList[ j ] = BitOffsetList[ j−1 ] + bit_offset_delta2 | |
| (optional) | |
| } | |
| } | |
| } | |
| } | |
| byte_alignment( ) (optional) | |
| } | |

For example, integer_codebook() is defined as follows (all details are optional):

| | Descriptor |
|---|---|
| integer_codebook( cbZeroOffset, | |
| integerCodebook ) { | |
| codebook_egk | u(4) |
| codebook_size | ue(2) |
| codebook_centre_offset | ie(2) |
| cbZeroOffset = ( codebook_size >> 1 ) + | |
| codebook_centre_offset | |
| codebook_zero_value | ie(7) |
| integerCodebook[ cbZeroOffset ] = | |
| codebook_zero_value | |
| previousValue = integerCodebook[ | |
| cbZeroOffset ] | |
| for( j = cbZeroOffset − 1; j >= 0; j−− ) { | |
| codebook_delta_left | ue(codebook_egk) |
| integerCodebook[ j ] = previousValue − | |
| codebook_delta_left − 1 | |
| previousValue = integerCodebook[ j ] | |
| } | |
| previousValue = integerCodebook[ | |
| cbZeroOffset ] | |
| for( j = cbZeroOffset + 1; j < codebook_size; | |
| j++ ) { | |
| codebook_delta_right | ue(codebook_egk) |
| integerCodebook[ j ] = previousValue + | |
| codebook_delta_right + 1 | |
| previous Value = integerCodebook[ j ] | |
| } | |
| } | |

For example, tensor_dimension_list() is defined as follows (all details are optional):

| | Descriptor |
|---|---|
| tensor_dimension_list( ){ | |
| count_tensor_dimensions | ue(1) |
| for( j = 0; j < count_tensor_dimensions; j++ ) | |
| tensor_dimensions[ j ] | ue(7) |
| } | |

For example, topology_elements_ids_list(topologylndexedFlag) is defined as follows (all details are optional):

| | Descriptor |
|---|---|
| topology_elements_ids_list( topologyIndexedFlag ) { | |
| count_topology_elements_minus2 | ue(7) |
| if( topologyIndexedFlag == 0 ) | |
| byte_alignment( ) | |
| for( j = 0; j < count_topology_elements_minus2 + 2; | |
| j++ ) { | |
| if ( topologyIndexedFlag == 0 ) { | |
| topology_elem_id_list[ j ] | st(v) |
| } | |
| else { | |
| topology_elem_id_index_list[ j ] | ue(7) |
| } | |
| } | |
| if ( topologyIndexedFlag == 1 ) | |
| byte_alignment( ) | |
| } | |

For example, topology_tensor_dimension_mapping() is defined as follows (all details are optional):

| | Descriptor |
|---|---|
| topology_tensor_dimension_mapping ( ) { | |
| concatentation_axis_index | u(8) |
| for( j = 0; j < count_topology_elements_minus2 + 1 ; | |
| j++ ) { | |
| split_index[ j ] | ue(7) |
| } | |
| for( k = 0; k < count_topology_elements_minus2 + | |
| 2 ; k++ ) { | |
| number_of_shifts[ k ] | ue(1) |
| for( i = 0; i < number_of_shifts[ k ] ; i++ ) { | |
| shift_index[ k ][ i ] | ue(7) |
| shift_value[ k ][ i ] | ue(1) |
| } | |
| } | |
| } | |

### 6.3.3.8 NNR Aggregate Unit Header Syntax (Details are Optional)

Descriptor
u(8)
u(1)
u(7)
u(16)
u(6)
u(34)
u(5)
u(1)
u(2)
u(3)

### 6.3.4 NNR Unit Payload Syntax (Example, all Details are Optional)

### 6.3.4.1 General (Example, all Details are Optional)

Descriptor

```
nnr_unit_payload( ) {
  if( nnr_unit_type == NNR_MPS )
    nnr_model_parameter_set_unit_payload( )
(optional)
  if( nnr_unit_type == NNR_LPS )
    nnr_layer_parameter_set_unit_payload( )
(optional)=
  if( nnr_unit_type == NNR_TPL )
    nnr_topology_unit_payload( ) (optional)
  if( nnr_unit_type == NNR_QNT )
    nnr_quantization_unit_payload( ) (optional)
  if( nnr_unit_type == NNR_NDU )
    nnr_compressed_data_unit_payload( ) (example)
  if( nnr_unit_type == NNR_STR )
    nnr_start_unit_payload( ) (optional)
  if( nnr_unit_type == NNR_AGG )
    nnr_aggregate_unit_payload( ) (optional)
}
```

### 6.3.4.2 NNR Start Unit Payload Syntax (all Details are Optional)

Descriptor
u(0)

### 6.3.4.3 NNR Model Parameter Set Unit Payload Syntax (all Details are Optional)

### 6.3.4.4 NNR Layer Parameter Set Unit Payload Syntax(all Details are Optional)

### 6.3.4.5 NNR Topology Unit Payload Syntax (all Details are Optional)

### 6.3.4.6 NNR Quantization Unit Payload Syntax (all Details are Optional)

| | |
|---|---|
| [symbol] | [symbol] |
| [symbol] | [symbol] |
| [symbol] | [symbol] |

[symbol]

indicates data missing or illegible when filed

### 6.3.4.7 NNR Compressed Data Unit Payload Syntax (Example, Details are Optional)

| | Descriptor |
|---|---|
| nnr_compressed_data_unit_payload( ) { | |
| if( nnr_compressed_data_unit_payload_type == NN | |
| R_PT_RAW_FLOAT ) (example) | |
| for( i = 0; i < Prod( TensorDimensions ); i++ ) | |
| (example) | |
| raw_float32_parameter[ TensorIndex( TensorDimen | flt(32) |
| sions, i , 0 ) ] (example) | |
| decode_compressed_data_unit_payload( ) | |
| (example) | |
| } | |

For example, decode_compressed_data_unit_payload( ) invokes the decoding process, for example, as specified in subclause 7.3.

### 6.3.4.8 NNR Aggregate Unit Payload Syntax (all Details are Optional)

### 6.3.5 Byte Alignment Syntax (all Details are Optional)

### 6.4 Semantics

### 6.4.1 General

As an example, semantics associated with the syntax structures and elements within these structures are specified in this subclause. For example, when the semantics of a syntax element are specified using a table or a set of tables, any values that are not specified in the table(s) shall, for example, not be present in the bitstream unless otherwise specified in this document.

### 6.4.2 NNR Unit Size Semantics (all Details are Optional)

### 6.4.3 NNR Unit Header Semantics (Example, all Details are Optional)

### 6.4.3.1 General (Example, all Details are Optional)

For example, nnr_unit_type specifies the type of the NNR unit, for example, as specified in Table 3.

TABLE 3
NNR Unit Types (examples)

| nnr_unit_type | Identifier | NNR Unit Type | Description |
|---|---|---|---|
| 0 | NNR_STR | NNR start unit | Compressed neural |
| | | | network bitstream |
| | | | start indicator |
| 1 | NNR_MPS | NNR model | Neural network |
| | | parameter set | global metadata |
| | | data unit | and information |
| 2 | NNR_LPS | NNR layer | Metadata related |
| | | parameter set | to a partial |
| | | data unit | representation of |
| | | | neural network |
| 3 | NNR_TPL | NNR topology | Neural network |
| | | data unit | topology |
| | | | information |
| 4 | NNR_QNT | NNR quantization | Neural network |
| | | data unit | quantization |
| | | | information |
| 5 | NNR_NDU | NNR compressed | Compressed neural |
| | | data unit | network data |
| 6 | NNR_AGG | NNR aggregate | NNR unit with |
| | | unit | payload containing |
| | | | multiple NNR units |
| 7 . . . 31 | NNR_RSVD | Reserved | ISO/IEC-reserved |
| | | | range |
| 32 . . . 63 | NNR_UNSP | Unspecified | Unspecified range |

For example, the values in the range NNR_RSVD are reserved for used in future versions of this or related specifications. Encoders must not use these values. Decoders conforming to this version of the specification may, fore example, ignore NNR units using these values. The values in the range NNR_UNSP are not specified, their use is outside the scope of this specification. Decoders conforming to this version of the specification may, for example, ignore NNR units using these values.

Fore example. independently_decodable_flag specifies whether this compressed data unit is independently decodable. A value of 1 indicates, for example, an independently decodable NNR Unit. A value of 0 indicates, for example, that this NNR Unit is not independently decodable and its payload should be combined with other NNR Units for successful decodability/decompressibility.

The value of independently_decodable flag shall, for example, be the same for all NNR Units which refer to the same topology_elem_id or topology_elem_id_index value or the same topology_elem_id_list.

For example, partial_data_counter_present_flag equal to 1 specifies that the syntax element partial_data_counter is present in NNR unit header. For example, partial_data_counter_present_flag equal to 0 specifies that the syntax element partial_data_counter is not present in NNR unit header.

For example, partial_data_counter specifies the index of the partial data carried in the payload of this NNR Data Unit with respect to the whole data for a certain topology element. For example, a value of 0 indicates no partial information (i.e., the data in this NNR Unit is all data associated to a topology element and it is complete), for example, a value bigger than 0 indicates the index of the partial information (i.e., data in this NNR Unit should be concatenated with the data in accompanying NNR Units until partial_data_counter of an NNR Unit reaches 1). For example, this counter counts backwards to indicate initially the total number of partitions. For example, if not present, the value of partial_data_counter is inferred to be equal to 0. For example, if the value of independently_decodable_flag is equal to 0, the value of partial_data_counter_present_flag shall be equal to 1 and the value of partial_data_counter shall be greater than 0. For example, if the value of independently_decodable_flag is equal to 1, the values of partial_data_counter_present_flag and partial_data_counter are undefined, in this version of this document.

NOTE—In future versions of this document, if the value of independently_decodable_flag is equal to 1 and if partial_data_counter_present_flag is equal to 1, partial_data_counter may, for example, have non-zero values, based on the assumption that multiple independently decodable NNR units are combined to construct a model.

### 6.4.3.2 NNR Start Unit Header Semantics (Details are Optional)

### 6.4.3.3 NNR Model Parameter Set Unit Header Semantics (Details are Optional)

### 6.4.3.4 NNR Layer Parameter Set Unit Header Semantics (Details are Optional)

### 6.4.3.5 NNR Topology Unit Header Semantics (Details are Optional)

### 6.4.3.6 NNR Quantization Unit Header Semantics (Details are Optional)

### 6.4.3.7 NNR Compressed Data Unit Header Semantics (Example, Details are Optional)

For example, nnr_compressed_data unit_payload_type (optional) is as defined in Table 7 of subclause 7.3.

For example, nnr_multiple_topology_elements_present_flag (optional) specifies whether multiple topology units are present in the bitstream. In case there are multiple units, the list of their IDs is included. When nnr_compressed_data_unit_payload_type is set to NNR_PT_BLOCK, this flag shall be set to 1 and topology_elements_ids_list( ) in the NNR compressed data unit header shall list the topology elements or topology element indexes of RecWeight, RecWeightG, RecWeightH, RecLS, RecBeta, RecGamma, RecMean, RecVar and RecBias, in the given order and based on their presence as indicated by the value of compressed_parameter_type in the NNR compressed data unit header.

For example, nnr_decompressed_data_format_present_flag (optional) specifies whether the data format to be obtained after decompression is present in the bitstream.

For example, input_parameters_present_flag (optional) specifies whether the group of elements including tensor dimensions, DeepCABAC unary length and compressed parameter types is present in the bitstream.

For example, topology_elem_id (optional) specifies a unique identifier for the topology element to which an NNR compressed data unit refers. The semantic interpretation of this field is context dependent.

For example, topology_elem_id_index (optional) specifies a unique index value of a topology element which is signaled in topology information of payload type NNR_TPL_REFLIST. The first index shall be 0 (i.e. 0-indexed).

For example, node_id_present_flag (optional) equal to 1 indicates that syntax elements device_id, parameter_id, and put_node_depth are present.

For example, device_id (optional) uniquely identifies the device that generated the current NDU.

For example, parameter_id (optional) uniquely identifies the parameter of the model to which the tensors stored in the NDU relate to. If parent_node_id_type is equal to ICNN_NDU_ID, parameter_id shall equal the parameter_id of the associated parent NDU.

For example, put_node_depth (optional) is the tree depth at which the current NDU is located. A depth of 0 corresponds to the root node. If parent_node_id_type is equal to ICNN_NDU_ID, put_node_depth−1 must equal the put_node_depth of the associated parent NDU.

For example, parent_node_id_present_flag (optional) equal to 1 indicates that syntax element parent_node_id_type is present.

For example, parent_node_id_type (optional) specifies the parent node id type. It indicates which further syntax elements for uniquely identifying the parent node are present. The allowed values for parent_node_id_type are defined in Table 4

TABLE 4
Parent node id type identifiers. (example)

| parent_node_id_type | Identifier | Description |
|---|---|---|
| 0 | ICNN_NDU_ID | Indicates that syntax |
| | | elements parent_device_id, |
| | | parameter_id, and |
| | | put_node_depth are present |
| 1 | ICNN_NDU_PL_SHA256 | Indicates that syntax element |
| | | parent_node_payload_sha256 |
| | | is present |
| 2 | ICNN_NDU_PL_SHA512 | Indicates that syntax element |
| | | parent_node_payload_sha512 |
| | | is present |
| 3 | | Reserved |

For example, temporal_context_modeling_flag (optional) specifies whether temporal context modeling is enabled. A temporal_context_modeling_flag equal to 1 indicates that temporal context modeling is enabled. If temporal_context_modeling_flag is not present, it is inferred to be 0.

For example, parent_device_id (optional) is equal to syntax element device_id of the parent NDU.

For example, parent_node_payload_sha256 (optional) is a SHA256 hash of the nnr_compressed_data_unit_payload of the parent NDU.

For example, parent_node_payload_sha512 (optional) is a SHA512 hash of the nnr_compressed_data_unit_payload of the parent NDU.

For example, count_topology_elements_minus2+2 (optional) specifies the number of topology elements for which this NNR compressed data unit carries data in the payload.

For example, codebook_present_flag (optional) specifies whether codebooks are used. If codebook_present_flag is not present, it is inferred to be 0.

For example, dq_flag (optional) specifies whether the quantization method is dependent scalar quantization according to subclause Fehler! Verweisquelle konnte nicht gefunden werden. or uniform quantization according to subclause.

A dq_flag equal to 0 indicates that the uniform quantization method is used. A dq_flag equal to 1 indicates that the dependent scalar quantization method is used. If dq_flag is not present, it is inferred to be 0.

For example, nnr_decompressed_data_format (optional) is defined in Table 6 of subclause 7.2.

For example, tensor_dimensions_flag (optional) specifies whether the tensor dimensions are defined in the bitstream. If they are not included in the bitstream, they shall be obtained from the model topology description.

For example, cabac_unary_length_flag (optional) specifies whether the length of the unary part in the DeepCABAC binarization is included in the bitstream.

For example, compressed_parameter types (optional) specifies the compressed parameter types present in the current topology element to which an NNR compressed data unit refers. If multiple compressed parameter types are specified, they are combined by OR. The compressed parameter types are defined in Table 5.

TABLE 5
Compressed parameter type identifiers. (example)

| | | Bit in |
|---|---|---|
| Compressed | Compressed | compressed_param- |
| parameter type | parameter type ID | eter_types |
| Decomposition present | NNR_CPT_DC | 0x01 |
| Local scaling present | NNR_CPT_LS | 0x02 |
| Batch norm parameters | NNR_CPT_BN | 0x04 |
| present | | |
| Bias present | NNR_CPT_BI | 0x08 |

For example, when decomposition is present, the tensors G and H represent the result of decomposing the original tensor. If (compressed_parameter_types & NNR_CPT DC) !=0 the variables TensorDimensionsG and TensorDimensionsH are derived, for example, as follows:
Variable TensorDimensionsG is set to [g_number_of_rows, decomposition_rank].
Variable TensorDimensionsH is set to [decomposition_rank, hNumberOfColumns] where hNumberOfColumns is defined as

$$hNumberOfColumns = \frac{{\prod }_{i = 0}^{{count}_{-} {tensor}_{-} dimensions - 1} tensor\_dimensions [ i ]}{g\_number \_of \_rows}$$

For example, if (compressed_parameter types & NNR_CPT_DC) !=0 and if nnr_compressed_data_unit_payload_type !=NNR_PT_BLOCK, the NNR unit contains a decomposed tensor G and the next NNR unit in the bitstream contains, for example, the corresponding decomposed tensor H.

For example, a variable TensorDimensions is derived as follows:
If an NNR unit contains a decomposed tensor G and nnr_compressed_data_unit_payload_type !=NNR_PT_BLOCK, TensorDimensions is set to TensorDimensionsG.
Otherwise, if an NNR unit contains a decomposed tensor H and nnr_compressed_data_unit_payload_type !=NNR_PT_BLOCK, TensorDimensions is set to TensorDimensionsH.
Otherwise, TensorDimensions is set to tensor_dimensions.

For example, a variable NumBlockRowsMinus1 is defined as follows:
If scan_order is equal to 0, NumBlockRowsMinus1 is set to 0.
Otherwise, if nnr_compressed_data_unit_payload_type==NNR_PT_BLOCK and (compressed_parameter_types & NNR_CPT_DC) 0, NumBlockRowsMinus1 is set to ((TensorDimensionsG[0]+(4<<scan_order)−1)>>(2+scan_order))+((TensorDimensionsH[0]+(4<<scan_order)−1)>>(2+scan_order))−2.
Otherwise, NumBlockRowsMinus1 is set to ((TensorDimensions[0]+(4<<scan_order)−1)>>(2+scan_order))−1.

For example, decomposition_rank (optional) specifies the rank of the low-rank decomposed weight tensor components relative to tensor_dimensions.

For example, g_number_of_rows (optional) specifies the number of rows of matrix G in the case where the reconstruction is performed for decomposed tensors in an NNR unit of type NNR_PT_BLOCK

For example, cabac_unary_length_minus1 (optional) specifies the length of the unary part in the DeepCABAC binarization minus 1.

For example, first_tensor_dimension_shift (optional, present in some embodiments) specifies the shift of the first_tensor dimension for tensor dimension reordering and shall be smaller than the value of count_tensor_dimensions. If first_tensor_dimension_shift is not present, it is inferred to be 0.

For example, scan_order (optional, resent in some embodiments) specifies the block scanning order for parameters with more than one dimension, for example, according to the following table:
0: No block scanning
1: 8×8 blocks
2: 16×16 blocks
3: 32×32 blocks
4: 64×64 blocks

For example, cabac_offset_list (optional) specifies a list of values to be used to initialize variable lvlOffset at the beginning of entry points.

For example, dq_state_list (optional) specifies a list of values to be used to initialize variable stateId at the beginning of entry points.

For example, bit_offset_delta1 (optional) specifies the first element of list BitOffsetList.

For example, bit_offset_delta2 (optional) specifies elements of list BitOffsetList except for the first element, as difference to the previous element of list BitOffsetList. For example, Variable BitOffsetList (optional) is a list of bit offsets to be used to set the bitstream pointer position at the beginning of entry points.

For example, codebook_egk (optional) specifies the Exp-Golomb parameter k for decoding of syntax elements codebook_delta_left and codebook_delta_right.

For example, codebook_size (optional) specifies the number of elements in the codebook.

For example, codebook_centre_offset (optional) specifies an offset for accessing elements in the codebook relative to the centre of the codebook. It is used for calculating variable CbZeroOffset.

For example, codebook_zero_value (optional) specifies the value of the codebook at position CbZeroOffset. It is involved in creating variable Codebook (the array representing the codebook).

For example, codebook_delta_left (optional) specifies the difference between a codebook value and its right neighbour minus 1 for values left to the centre position.

It is involved in creating variable Codebook (the array representing the codebook).

For example, codebook_delta right (optional) specifies the difference between a codebook value and its left neighbour minus 1 for values right to the centre position.

It is involved in creating variable Codebook (the array representing the codebook).

For example, count_tensor_dimensions (optional) specifies a counter of how many dimensions are specified. For example, for a 4-dimensional tensor, count_tensor_dimensions is 4. If it is not included in the bitstream, it shall be obtained from the model topology description.

For example, tensor_dimensions (optional) specifies an array or list of dimension values. For example, for a convolutional layer, tensor_dimensions is an array or list of length 4. For NNR units carrying elements G or H of a decomposed tensor, tensor_dimensions is set to the dimensions of the original tensor. The actual tensor dimensions of G and H for the decoding methods are derived from tensor_dimensions, decomposition_rank, and g_number_of_rows. If it is not included in the bitstream, it shall be obtained from the model topology description. As an example, reference is made to FIG. 6 wherein tensor_dimensions of tensor 680 may, for example, be the vector [D0, D1, D2, D3].

For example, topology_elem_id_list (optional) specifies a list of unique identifiers related to the topology element to which an NNR compressed data unit refers.

Elements of topology_elem_id_list are semantically equivalent to syntax element topology_elem_id or the index of it when listed in topology payload of type NNR_TPL_REFLIST. The semantic interpretation of this field is context dependent.

For example, topology_elem_id_index_list (optional) specifies a list of unique indexes related to the topology elements listed in topology information with payload type NNR_TPL_REFLIST. The first element in the topology shall have the index value of 0.

For example, concatentation_axis_index (optional) indicates the 0-based concatenation axis.

For example, split_index[ ] (optional) indicates the tensor splitting index along the concatenation axis indicated by concatentation_axis_index in order to generate each individual tensor which is concatenated.

For example, number_of_shifts[ ] (optional) indicates how many left-shifting operations are to be performed.

For example, shift_index[k][i] (optional) indicates the axis index of the kth topology element to be left-shifted.

For example, shift_value[k][i] (optional) indicates the amount of left-shift on the axis with index index[k][i]

### 6.4.3.8 NNR Aggregate Unit Header Semantics (Details are Optional)

### 6.4.4 NNR Unit Payload Semantics

### 6.4.4.1 General

For example, The following NNR unit payload types are specified:

### 6.4.4.2 NNR Start Unit Payload Semantics (Details are Optional)

### 6.4.4.3 NNR Model Parameter Set Unit Payload Semantics (Details are Optional)

### 6.4.4.4 NNR Layer Parameter Set Unit Payload Semantics (Details are Optional)

### 6.4.4.5 NNR Topology Unit Payload Semantics (Details are Optional)

### 6.4.4.6 NNR Quantization Unit Payload Semantics (Details are Optional)

### 6.4.4.7 NNR Compressed Data Unit Payload Semantics (Example, Details are Optional)

raw_float32_parameter is a float parameter tensor.

### 6.4.4.8 NNR Aggregate Unit Payload Semantics (Details are Optional)

### 7 Decoding Process

### 7.1 General (Example, Details are Optional)

A decoder that complies with this document shall, for example, take an NNR bitstream, as specified in subclause 6.3, as input and
generate decompressed data which, for example complies with an NNR decompressed data format (as defined, for example, in Table 6) or
generate, for example, ASCII or compressed data outputs as indicated, for example, by using the NNR_TPL and NNR_QNT NNR unit payloads (as described in subclause 6.3.3) (optional)

As an example, for the decoding process, the following conditions shall, for example, apply:
For example, any information that is required for decoding an NNR Unit of the NNR bitstream should, for example, be signaled as part of the NNR bitstream. If such information is not part of the NNR bitstream, then it shall, for example, be provided to the decoding process by other means (e.g. out-of-band topology information or parameters required for decoding but not signaled or carried in the NNR bitstream)
For example The decoding process shall be initiated with an NNR unit of type NNR_STR. With the reception of the NNR_STR unit, the decoder shall reset its internal states and get ready to receive an NNR bitstream. The presence and cardinality of preceding NNR units shall be as specified in the relevant clauses and annexes of this document.
Note: For example, a decoder may be further initialized via an NNR Unit of type NNR_MPS in order set global neural network model parameters.

For example, a decoder that complies with this document shall, for example, output data structures which comply with the decompressed NNR data formats as soon as it decompresses them. This allows, for example, low delay between inputting NNR compressed data units and accessing decompressed data structures from its output. How to establish the relationship between the input NNR units and NNR decompressed output data is out of scope of this document and left to implementation.

### 7.2 NNR Decompressed Data Formats (Examples, Details are Optional)

For example, Depending on the compression methods used to create a particular bitstream, the NNR decoder is expected to output different decompressed data formats as a result of decoding an NNR data unit. For example, Table 6 specifies these NNR decompressed data formats that result, for example, after decompressing NNR compressed data units.

TABLE 6
NNR decompressed data formats (examples)

| | | nnr_decom- |
|---|---|---|
| Parameter | | pressed_da- |
| identifier | Parameter description | ta_format |
| TENSOR_INT | Tensor of integer values used for | 0 |
| | representing tensor-shaped signed | |
| | integer parameters of the model | |
| TENSOR_FLOAT | Tensor of float values used for | 1 |
| | representing tensor-shaped float | |
| | parameters of the model | |

### 7.3 Decoding Methods (Examples, Details are Optional)

### 7.3.1 General (Details are Optional)

This subclause specifies, as an example, the decoding methods of this document. For example, depending on the value of nnr_compressed_data_unit_payload_type, one of the subclauses as specified in Table 7 is invoked.

TABLE 7
NNR compressed data payload types (examples, details are Payload identifier optional)

| | | | Sub- |
|---|---|---|---|
| Payload identifier | Description | nnr_compressed_data_unit_payload_type | clause |
| NNR_PT_INT | integer parameter tensor | 0 | 0 |
| NNR_PT_FLOAT | float parameter tensor | 1 | 7.3.3 |
| NNR_PT_RAW_FLOAT | uncompressed float parameter tensor | 2 | 7.3.4 |
| NNR_PT_BLOCK | float parameter tensors including a | 3 | 7.3.5 |
| | (optionally decomposed) weight tensor | | |
| | and, optionally, local scaling | | |
| | parameters, biases, and batch norm | | |
| | parameters that form a block in the | | |
| | model architecture | | |

For example, if the payload identifier is NNR_PT_INT, NNR_PT_FLOAT, or NNR_PT_FLOAT_RAW and if multiple topology elements are combined (for example, as signaled in the NNR compressed data unit header, for example, via nnr_multiple_topology_elements_present_flag), then NNR decompressed tensors shall, for example, be further split into multiple tensors after the decoding process, for example, as follows:
For example, Tensor RecParam is split into multiple tensors, for example, by invoking TensorSplit(RecParam, split-index, concatenation_axis_index).
For example, The output of function TensorSplit is the list of split output tensors associated with topology elements, for example, as specified by array topology_elem_id_list.
For example, Output tensors are further processed by swapping their axis, for example, as signaled in topology_tensor_dimension_mapping ( ) by invoking AxisSwap( ).

### 7.3.1.1 Tensor Dimension Reordering Using First Tensor Dimension Shift (Example, Details are Optional)

Inputs to this process are, for example:
A variable inputTensor representing, for example, the tensor for which the dimensions shall be reordered
A variable inputTensorDims specifying, for example, the dimensions of inputTensor

Output of this process is, for example, a variable reorderedTensor, for example, with dimensions equal to ShiftArrayIndex(inputTensorDims, first_tensor_dimension_shift). For example, The elements of variable reorderedTensor are set as follows:

```
for( i = 0; i < Prod( inputTensorDims ); i++ ){
    idxA = TensorIndex( inputTensorDims, i, 0 )
    idxB = ShiftArrayIndex( idxA, first_tensor_dimension_shift )
    reorderedTensor[idxB] = inputTensor[idxA]
  }
```

Hence, in general, a decoder, e.g. 100 as shown in FIG. 1, e.g. 200 as shown in FIG. 2, for example respective reordering units thereof 120, 220, may, for example, be configured to obtain the re-ordered multi-dimensional array, e.g. 121, 221, using the above processing.

### 7.3.2 Decoding Method for NNR Compressed Payloads of Type NNR_PT_INT (Example, Details are Optional)

Input to this process are, for example:
One or more NNR compressed data units which are, for example, marked to be decompressed together, for example, by partial_data_counter and nnr_compressed_data_unit_payload_type fields are, for example, set as NNR_PT_INT.

Output of this process is, for example, a variable RecParam of type TENSOR_INT as specified, for example, in Table 6. The dimensions of RecParam are, for example, equal to ShiftArrayIndex(TensorDimensions, first_tensor_dimension_shift). For example, decoding of a bitstream conforming to method NNR_PT_INT shall, for example, only produce values for RecParam that can, for example, be represented as 32 bit integer value in two's complement representation.

For example, optionally, the arithmetic coding engine and context models are initialized, for example, as specified in subclause 9.3.2.

For example, optionally, a syntax structure shift_parameter_ids(cabac_unary_length_minus1), for example, according to subclause 9.2.1.6 is decoded from the bitstream and, for example, the initialization process for probability estimation parameters as specified in subclause 9.3.2.2 is invoked.

For example, optionally, a syntax structure quant_tensor(TensorDimensions, cabac_unary_length_minus1, 0), for example, according to subclause 9.2.1.4 is decoded from the bitstream and, for example, RecParam is set equal to QuantParam.

For example, optionally, a syntax structure terminate_cabac( ), for example, according to subclause 9.2.1.2 is decoded from the bitstream.

For example, optionally, Subclause 7.3.1.1 is invoked with RecParam and TensorDimensions as inputs, and the output is assigned to RecParam.

### 7.3.3 Decoding Method for NNR Compressed Payloads of Type NNR_PT_FLOAT (Example, Details are Optional)

For example, input to this process are:
One or more NNR compressed data units which are, for example, marked to be decompressed together by partial_data_counter and, for example, their nnr_compressed_data_unit_payload_type fields are set as NNR_PT_FLOAT

For example, output of this process is a variable RecParam of type TENSOR_FLOAT as specified, for example, in Table 6. For example, the dimensions of RecParam are equal to ShiftArrayIndex(TensorDimensions, first_tensor_dimension_shift).

For example, the arithmetic coding engine and context models are initialized, for example, as specified in subclause 9.3.2.

For example, optionally, subclause 7.3.6 is invoked, for example, with TensorDimensions, 0, and (codebook_present_flag ? 0:−1) as inputs, and the output is, for example, assigned to RecParam.

For example, optionally, a syntax structure terminate_cabac( ), for example, according to subclause 9.2.1.2 is decoded from the bitstream.

For example, optionally, subclause 7.3.1.1 is invoked, for example with RecParam and TensorDimensions as inputs, and the output is assigned to RecParam.

For example, decoding of a bitstream conforming to method NNR_PT_FLOAT shall, for example, only produce values for RecParam that can be represented as float value without loss of precision.

### 7.3.4 Decoding Method for NNR Compressed Payloads of Type NNR_PT_RAW_FLOAT (Example, Details are Optional)

For example, output of this process is a variable RecParam, for example, of type TENSOR_FLOAT, for example, as specified in Table 6. For example, the dimensions of RecParam are equal to ShiftArrayIndex(TensorDimensions, first_tensor_dimension_shift).

For example, RecParam is set equal to raw_float32_parameter.

For example, optionally, subclause 7.3.1.1 is invoked, for example, with RecParam and TensorDimensions as inputs, and the output is, for example, assigned to RecParam.

### 7.3.5 Decoding Method for NNR Compressed Payloads of Type NNR_PT_BLOCK (Example, Details are Optional)

For example, inputs to this process are:
For example, one or more NNR compressed data units which are, for example, marked to be decompressed together by partial_data_counter and their nnr_compressed_data_unit_payload_type fields are, for example, set as NNR_PT_BLOCK.

For example, output of this process are one or more variables, for example, of type TENSOR_FLOAT as specified, for example, in Table 6, for example, depending on the value of compressed_parameter_types, for example, as follows:
If (compressed_parameter_types & NNR_CPT_DC)==0: RecWeight (optional, example)
If (compressed_parameter_types & NNR_CPT_DC) !=0: RecWeightG, RecWeightH (optional, example)
If (compressed_parameter_types & NNR_CPT_LS) !=0: RecLS (optional, example)
If (compressed_parameter_types & NNR_CPT_BN) !=0: RecBeta, RecGamma, RecMean, RecVar (optional, example)
If (compressed_parameter_types & NNR_CPT_BI) !=0: RecBias (optional, example)

If present, the dimensions of RecWeight are equal to ShiftArrayIndex(TensorDimensions, first_tensor_dimension_shift). (optional, example)

If present, the dimensions of RecWeightG are equal to TensorDimensionsG (optional, example).

If present, the dimensions of RecWeightH are equal to TensorDimensionsH (optional, example).

If present, the variables RecLS, RecBeta, RecGamma, RecMean, RecVar, and RecBias are 1 D and their length is equal to the first dimension of TensorDimensions (optional, example).

For example, optionally, the arithmetic coding engine and context models are initialized, for example, as specified in subclause 9.3.2.

If (compressed_parameter_types & NNR_CPT_LS) !=0, subclause 7.3.6 is invoked with the dimensions of RecLS, −1, and −1 as inputs, and the output is assigned to RecLS (optional, example).

If (compressed_parameter_types & NNR_CPT_BI) !=0, subclause 7.3.6 is invoked with the dimensions of RecBias, −1, and −1 as inputs, and the output is assigned to RecBias (optional, example).

If (compressed_parameter_types & NNR_CPT_BN) !=0, subclause 7.3.6 is invoked with the dimensions of RecBeta, −1, and −1 as inputs, and the output is assigned to RecBeta (optional, example).

If (compressed_parameter_types & NNR_CPT_BN) !=0, subclause 7.3.6 is invoked with the dimensions of RecGamma, −1, and −1 as inputs, and the output is assigned to RecGamma (optional, example).

If (compressed_parameter_types & NNR_CPT_BN) !=0, subclause 7.3.6 is invoked with the dimensions of RecMean, −1, and −1 as inputs, and the output is assigned to RecMean (optional, example).

If (compressed_parameter_types & NNR_CPT_BN) !=0, subclause 7.3.6 is invoked with the dimensions of RecVar, −1, and −1 as inputs, and the output is assigned to RecVar (optional, example).

If (compressed_parameter_types & NNR_CPT_DC)==0, subclause 7.3.6 is invoked with the dimensions of RecWeight, 0, and (codebook_present_flag ? 0:−1) as inputs, and the output is assigned to RecWeight (optional, example).

If (compressed_parameter_types & NNR_CPT_DC) !=0, the following applies: (optional, example)
For example, subclause 7.3.6 is invoked, for example, with TensorDimensionsG, 0, and (codebook_present_flag ? 0:−1) as inputs, and the output is, for example, assigned to RecWeightG.
For example, Subclause 7.3.6 is invoked, for example, with TensorDimensionsH, (TensorDimensionsG[0]+(4<<scan_order)−1)>>(2+scan_order))−1, and (codebook present_flag ? 1:−1) as inputs, and the output is, for example, assigned to RecWeightH.
NOTE—From the decoded RecWeightG and RecWeightH, the variable RecWeight can, for example, be derived as follows:
   RecWeight=TensorReshape (RecWeightG*RecWeightH, TensorDimensions)
   For example, optionally, subclause 7.3.1.1 is invoked, for example, with RecWeight and TensorDimensions as inputs, and the output is, for example, assigned to RecWeight.

For example, optionally, a syntax structure terminate_cabac( ), for example, according to subclause 9.2.1.2 is decoded from the bitstream.

For example, optionally, if (compressed_parameter_types & NNR_CPT_DC)==0, subclause 7.3.1.1 is invoked, for example, with RecWeight and TensorDimensions as inputs, and the output is, for example, assigned to RecWeight.

### 7.3.6 Decoding Process for an Integer Weight Tensor (Example, Details are Optional)

For example, inputs to this process are:
A variable tensorDims specifying the dimensions of the tensor to be decoded (optional, example).
A variable entryPointOffset indicating whether entry points are present for decoding and, if entry points are present, an entry point offset (optional, example).
A variable codebookid indicating whether a codebook is applied and, if a codebook is applied, which codebook shall be used (optional, example).

For example, output of this process is a variable recParam of type TENSOR_FLOAT, for example, as specified in Table 6, for example, with dimensions equal to tensorDims.

For example, optionally, a syntax structure quant_param(QpDensity) according to subclause 9.2.1.3 is decoded from the bitstream.

For example, optionally, a syntax structure shift_parameter_ids (cabac_unary_length_minus1) according to subclause 9.2.1.6 is decoded from the bitstream and, for example, the initialization process for probability estimation parameters as specified in subclause 9.3.2.2 is invoked.

For example, optionally, a syntax structure quant_tensor(tensorDims, cabac_unary_length_minus1, entryPointOffset) according to subclause 9.2.1.4 is decoded from the bitstream and recParam is set as follows: (example)

```
if( codebookId = = −1 )
    recParam = QuantParam
  else {
    for( i = 0; i < Prod( tensorDims ); i++ ) {
      idx = TensorIndex( tensorDims, i )
      if( codebookId = = 0 )
        recParam[idx] = Codebook[ QuantParam[idx] + CbZeroOffset ]
      else
        recParam[idx] = CodebookDC[ QuantParam[idx] +
        CbZeroOffsetDC ]
    }
  }
```

For example, optionally, a variable stepSize is derived as follows:
mul=(1<<QpDensity)+((qp_value+QuantizationParameter) & ((1<<QpDensity)−1))
shift=(qp_value+QuantizationParameter)>>QpDensity
stepSize=mul*2^{shift-QpDensity}

For example, optionally, variable recParam is updated as follows:
recParam=recParam*stepSize

NOTE—For example, following from the above calculations, recParam can, for example, always be represented as binary fraction.

### 8 Parameter Reduction (Details are Optional)

### 9 Entropy Coding (Example, Details are Optional)

### 9.1 Methods

### 9.1.1 DeepCABAC (Example, Details are Optional)

### 9.1.1.1 Binarization (Example, Details are Optional)

For example, the encoding method scans the parameter tensor in a manner as defined, for example, by function TensorIndex( ). For example, each quantized parameter level is encoded according to the following procedure, for example, employing an integer parameter ‘maxNumNoRemMinus1’:

For example, optionally, in the first step, a binary syntax element sig_flag is encoded for the quantized parameter level, which specifies, for example, whether the corresponding level is equal to zero. For example, if the sig_flag is equal to one, a further binary syntax element sign_flag is encoded. For example, the bin indicates if the current parameter level is positive or negative. For example, next, a unary sequence of bins is encoded, for example, followed by a fixed length sequence as follows:

For example, a variable k is initialized with zero and, for example, X is initialized with 1<<k. For example, a syntax element abs_level_greater_x/x2 is encoded, which, for example, indicates, that the absolute value of the quantized parameter level is greater than x. For example, if abs_level_greater_x/x2 is equal to 1 and if x is greater than maxNumNoRemMinus1, the variable k is, for example, increased by 1. For example, afterwards, 1<<k is added to x and, for example, a further abs_level_greater_x/x2 is encoded. This procedure is, for example, continued until an abs_level_greater_x/x2 is equal to 0. Now, it is, for example, clear that X must be one of the values (x, x−1, . . . X−(1<<k)+1). For example, a code of length k is encoded, which, for example, points to the values in the list which is absolute quantized parameter level.

### 9.1.1.2 Row Skipping (Example, Details are Optional)

For example, if enabled by flag row_skip_flag_enabled_flag, the row skipping technique may, for example, signal one flag row_skip_list[i] for each value i along the first axis of the parameter tensor. For example, if the flag row_skip_list[i] is 1, all elements of the parameter tensor for which the index for the first axis equals i are set to zero. For example, if the flag row_skip_list[i] is 0, all elements of the parameter tensor for which the index for the first axis equals i are encoded individually.

In general, a decoder according to embodiments, e.g. a decoder 100 as shown in FIG. 1, e.g. a decoder 200 as shown in FIG. 2, for example respective decoding units thereof 110, 210, may, for example, be configured to decode a list of skipped rows, to enter decoded neural network coefficients into the first multidimensional array, e.g. 111, 211, at respective positions described by respective sets of array indices and to decide, in dependence on an entry of the list of skipped rows referenced by a current array index of the first dimension of the first multidimensional array, whether to use a default value for a given neural network parameter or whether to determine the given neural network parameter using a decoding.

### 9.1.1.3 Context Modelling (Example, Details are Optional)

For example, context modelling corresponds to associating the three type of flags sig_flag, sign_flag, and abs_level_greater_x/x2 with context models. In this way, for example, flags with similar statistical behavior should, for example, be associated with the same context model so that the probability estimator (for example, inside of the context model) can, for example, adapt to the underlying statistics.

For example, the context modelling of the presented approach is as follows:

For example, twenty-four context models are distinguished for the sig_flag, for example, depending on the state value and, for example, whether the neighbouring quantized parameter level to the left is zero, smaller, or larger than zero.

For example, if dq_flag is 0, for example, only the first three context models are used.

For example, three other context models are distinguished for the sign_flag, for example, depending on whether the neighbouring quantized parameter level to the left is zero, smaller, or larger than zero.

For example, for the abs_level_greater_x/x2 flags, each x uses, for example, either one or two separate context models. For example, if x<=maxNumNoRemMinus1, two context models are distinguished depending on the sign_flag. For example, if x>maxNumNoRemMinus1, only one context model is used.

### 9.1.1.4 Temporal Context Modelling (Example, Details are Optional)

For example, if enabled by flag temporal_context_modeling_flag, additional context model sets for flags sig_flag, sign_flag and abs_level_greater_x are available. For example, the derivation of ctxIdx is then also based on the value of a quantized co-located parameter level in the previously encoded parameter update tensor, which can, for example, be uniquely identified by the parameter update tree. For example, if the co-located parameter level is not available or equal to zero, the context modeling according to subclause 9.1.1.3 is applied. Otherwise, for example, if the co-located parameter level is not equal to zero, the temporal context modeling of the presented approach is, for example, as follows:

For example, sixteen context models are distinguished for the sig_flag, for example, depending on the state value and whether the absolute value of the quantized co-located parameter level is greater than one or not.

For example, if dq_flag is 0, only the first two additional context models are used.

For example, two more context models are distinguished for the sign_flag, for example, depending on whether the quantized co-located parameter level is smaller or greater than zero.

For example, for the abs_level_greater_x flags, each x uses two separate context models. For example, these two context models are distinguished depending on whether the absolute value of the quantized co-located parameter level is greater or equal to x−1 or not.

### 9.2 Syntax and Semantics (Examples, Details are Optional)

### 9.2.1 DeepCABAC Syntax (Examples, Details are Optional)

### 9.2.1.1 General

This subclause specifies the entropy coding syntax as used, for example, by the decoding process of clause 7.

### 9.2.1.2 DeepCABAC Termination Syntax (Details are Optional)

### 9.2.1.3 Quantization Parameter Syntax (Details are Optional)

### 9.2.1.4 Quantized Tensor Syntax (Example, Details are Optional)

| | Descriptor |
|---|---|
| quant_tensor( dimensions, maxNumNoRemMinus1, | |
| entryPointOffset ) { | |
| tensor2DHeight = dimensions[ 0 ] (example, | |
| optional) | |
| tensor2DWidth = Prod( dimensions ) / | |
| tensor2DHeight (example, optional) | |
| if( general_profile_idc == 1 && tensor2DWidth > 1 ) { | |
| row_skip_enabled_flag (example, optional) | uae(1) |
| if( row_skip_enabled_flag ) | |
| for( i = 0; i < tensor2DHeight; i++ ) | |
| row_skip_list[ i ] (example, optional) | ae(v) |
| } | |
| stateId = 0 (example, optional) | |
| bitPointer = get_bit_pointer( ) (example, optional) | |
| lastOffset = 0 (example, optional) | |
| for( i = 0; i < Prod( dimensions ); i++ ) { (example, | |
| optional) | |
| idx = TensorIndex( dimensions, i, scan_order ) | |
| (example, optional) | |
| if( entryPointOffset != −1 && | |
| GetEntryPointldx( dimensions, i, | |
| scan_order ) != −1 && | |
| scan_order > 0 ) { (example, optional) | |
| lvlCurrRange = 256 (example, optional) | |
| j = entryPointOffset + | |
| GetEntryPointldx( dimensions, i, | |
| scan_order ) (example, optional) | |
| lvlOffset = cabac_offset_list[ j ] (example, | |
| optional) | |
| if( dq_flag ) (example, optional) | |
| stateId = dq_state_list[ j ] (example, optional) | |
| set_bit_pointer( bitPointer + lastOffset + | |
| BitOffsetList[ j ] ) (example, optional) | |
| lastOffset = BitOffsetList[ j ] (example, optional) | |
| init_prob_est_param( ) (example, optional) | |
| } | |
| QuantParam[ idx ] = 0 (example, optional) | |
| if( general_profile_idc != 1 ∥ tensor2DWidth <= 1 \| | |
| !row_skip_enabled_flag ∥ | |
| !row_skip_list[ idx[ 0 ] ] ) | |
| int_param( idx, maxNumNoRemMinus1, stateId | 9.2.1.5 |
| ) (example, optional) | |
| if( dq_flag ) { | |
| nextSt = | |
| StateTransTab[ stateId ][ QuantParam[ idx ] & 1 ] | |
| (example, optional) | |
| if( QuantParam[ idx ] != 0 ) { | |
| QuantParam[ idx ] = QuantParam[ idx ] << 1 | |
| (example, optional) | |
| if( QuantParam[ idx ] < 0 ) | |
| QuantParam[ idx ] += stateId & 1 | |
| (example, optional) | |
| Else | |
| QuantParam[ idx ] += − ( stateId & 1 ) | |
| (example, optional) | |
| } | |
| stateId = nextSt (example, optional) | |
| } | |
| } | |
| } | |

For example, row_skip_enabled_flag specifies whether row skipping is enabled. For example, a row_skip_enabled_flag equal to 1 indicates that row skipping is enabled.

For example, row_skip_list specifies a list of flags where, for example, the i-th flag row_skip_lsit[i] indicates whether all tensor elements of QuantParam for which the index for the first dimension equals i are, for example, zero. For example, if row_skip_list[i] is equal to 1, all tensor elements of QuantParam for which the index for the first dimension equals i are zero.

For example, init_prob_est_param( ) invokes the initialization process, for example, specified in subclause 9.3.2.2.

For example, the 2D integer array StateTransTab[ ][ ] specifies the state transition table for dependent scalar quantization and is, for example, as follows: StateTransTab[ ][ ]={{0, 2}, {7, 5}, {1, 3}, {6, 4}, {2, 0}, {5, 7}, {3, 1}, {4, 6} }

### 9.2.1.5 Quantized Parameter Syntax (Details are Optional)

### 9.2.1.6 Shift Parameter Indices Syntax (Details are Optional)

### 9.2.1.7 Shift Parameter Syntax (Details are Optional)

### 9.3 Entropy Decoding Process (Details are Optional)

### 9.3.1 General (Details are Optional)

### 9.3.2 Initialization Process (Details are Optional)

### 9.3.2.1 General (Details are Optional)

### 9.3.2.2 Initialization Process for Probability Estimation Parameters (Details are Optional)

### 9.3.2.3 Initialization Process for Context Variables (Details are Optional)

### 9.3.2.4 Initialization Process for the Arithmetic Decoding Engine (Details are Optional)

### 9.3.3 Binarization Process (Details are Optional)

### 9.3.3.1 General (Details are Optional)

### 9.3.3.2 Fixed-Length Binarization Process (Details are Optional)

### 9.3.4 Decoding Process Flow (Details are Optional)

### 9.3.4.1 General (Details are Optional)

### 9.3.4.2 Derivation Process for ctxIdx and bypassFlag (Details are Optional)

### 9.3.4.2.1 General (Details are Optional)

### 9.3.4.2.2 Derivation Process of ctxInc for the Syntax Element sig_flag (Details are Optional)

### 9.3.4.2.3 Derivation Process of ctxInc for the Syntax Element sign_flag (Details are Optional)

### 9.3.4.2.4 Derivation Process of ctxInc for the Syntax Element abs_level_greater_x[j] (Details are Optional)

### 9.3.4.3 Arithmetic Decoding Process (Details are Optional)

### 9.3.4.3.1 General (Details are Optional)

### 9.3.4.3.2 Arithmetic Decoding Process for a Binary Decision (Details are Optional)

### 9.3.4.3.2.1 General (Details are Optional)

### 9.3.4.3.2.2 State Transition Process (Details are Optional)

### 9.3.4.3.3 Renormalization Process in the Arithmetic Decoding Engine (Details are Optional)

### 9.3.4.3.4 Bypass Decoding Process for Binary Decisions (Details are Optional)

### 9.3.4.3.5 Decoding Process for Binary Decisions Before Termination (Details are Optional)

A further Annex A may be related to or define the implementation for NNEF. Annexes A to E are not included or not included in their full extent for the sake of brevity. It to be noted that respective details functionalities and features of these Annexes art optional, both individually and in combination for embodiments of the invention.

### Bibliography for “Information Technology—Multimedia Content Description Interface”

[1] Open Neural Network Exchange, VERSION 7, 2020-05-09 (https://github.com/onnx/onnx/blob/master/onnx/onnx.proto)
[2] PyTorch, VERSION 1.5.1, 2020-10-22 (https://github.com/pytorch/pytorch/tree/v1.5.1)
[3] TensorFlow, VERSION 2.2.0, 2020-10-22 (https://github.com/tensorflow/tensorflow/tree/v2.2.0)

### IMPLEMENTATION ALTERNATIVES

Although some aspects are described in the context of an apparatus, it is clear that these aspects also represent a description of the corresponding method, where a block or device corresponds to a method step or a feature of a method step.

Analogously, aspects described in the context of a method step also represent a description of a corresponding block or item or feature of a corresponding apparatus. Some or all of the method steps may be executed by (or using) a hardware apparatus, like for example, a microprocessor, a programmable computer or an electronic circuit. In some embodiments, one or more of the most important method steps may be executed by such an apparatus.

Depending on certain implementation requirements, embodiments of the invention can be implemented in hardware or in software. The implementation can be performed using a digital storage medium, for example a floppy disk, a DVD, a Blu-Ray, a CD, a ROM, a PROM, an EPROM, an EEPROM or a FLASH memory, having electronically readable control signals stored thereon, which cooperate (or are capable of cooperating) with a programmable computer system such that the respective method is performed. Therefore, the digital storage medium may be computer readable.

Some embodiments according to the invention comprise a data carrier having electronically readable control signals, which are capable of cooperating with a programmable computer system, such that one of the methods described herein is performed.

Generally, embodiments of the present invention can be implemented as a computer program product with a program code, the program code being operative for performing one of the methods when the computer program product runs on a computer. The program code may for example be stored on a machine readable carrier.

Other embodiments comprise the computer program for performing one of the methods described herein, stored on a machine readable carrier.

In other words, an embodiment of the inventive method is, therefore, a computer program having a program code for performing one of the methods described herein, when the computer program runs on a computer.

A further embodiment of the inventive methods is, therefore, a data carrier (or a digital storage medium, or a computer-readable medium) comprising, recorded thereon, the computer program for performing one of the methods described herein.

The data carrier, the digital storage medium or the recorded medium are typically tangible and/or non-transitionary.

A further embodiment of the inventive method is, therefore, a data stream or a sequence of signals representing the computer program for performing one of the methods described herein. The data stream or the sequence of signals may for example be configured to be transferred via a data communication connection, for example via the Internet.

A further embodiment comprises a processing means, for example a computer, or a programmable logic device, configured to or adapted to perform one of the methods described herein.

A further embodiment comprises a computer having installed thereon the computer program for performing one of the methods described herein.

A further embodiment according to the invention comprises an apparatus or a system configured to transfer (for example, electronically or optically) a computer program for performing one of the methods described herein to a receiver. The receiver may, for example, be a computer, a mobile device, a memory device or the like. The apparatus or system may, for example, comprise a file server for transferring the computer program to the receiver.

In some embodiments, a programmable logic device (for example a field programmable gate array) may be used to perform some or all of the functionalities of the methods described herein. In some embodiments, a field programmable gate array may cooperate with a microprocessor in order to perform one of the methods described herein. Generally, the methods are preferably performed by any hardware apparatus.

The apparatus described herein may be implemented using a hardware apparatus, or using a computer, or using a combination of a hardware apparatus and a computer.

The apparatus described herein, or any components of the apparatus described herein, may be implemented at least partially in hardware and/or in software.

The methods described herein may be performed using a hardware apparatus, or using a computer, or using a combination of a hardware apparatus and a computer.

The methods described herein, or any components of the apparatus described herein, may be performed at least partially by hardware and/or by software.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

1. A decoder for providing decoded parameters of a neural network on the basis of an encoded representation,
wherein the decoder is configured to acquire a first multi-dimensional array comprising a plurality of neural network parameter values using a decoding of neural network parameters;
wherein the decoder is configured to acquire a re-ordered multidimensional array using a reordering, in which a first dimension of the first multi-dimensional array is rearranged to a different dimension in the re-ordered multidimensional array.

2. The decoder according to claim 1,
wherein the decoder is configured to decode a dimension shift value, and
wherein the dimension shift value describes by how many dimensions the first dimension of the first multi-dimensional array should be shifted when performing the reordering.

3. The decoder according to claim 1,
wherein the decoder is configured to decode a dimension shift value, and
wherein the dimension shift value describes a new position of the first dimension of the first multi-dimensional array in the re-ordered multidimensional array.

4. The decoder according to claim 3,
wherein the dimension-shift value is Exp Golomb-coded.

5. The decoder according to claim 1,
wherein the decoder is configured to perform the reordering using a single scalar dimension shift value as a sole parameter describing a new order of the dimensions in the re-ordered multi-dimensional array.

6. The decoder according to claim 1,
wherein the decoder is configured to perform a single shift of a single dimension to another position, in order to acquire the re-ordered multi-dimensional array.

7. The decoder according to claim 1,
wherein the decoder is configured to derive a dimension of an auxiliary array from a first dimension of the first multi-dimensional array.

8. The decoder according to claim 1,
wherein the decoder is configured to shift a single dimension of the first multi-dimensional array to a different position, in order to acquire the re-ordered multi-dimensional array.

9. The decoder according to claim 1,
wherein the decoder is configured to acquire a 2-dimensional matrix, a first dimension of which is determined by a first dimension value and a second dimension of which is determined by a product of a plurality of further dimension values on the basis of the encoded representation; and
wherein the decoder is configured to acquire the first multi-dimensional array, dimensions of which are determined by individual ones of the first dimension value and the further dimension values, on the basis of the 2-dimensional matrix; and
wherein the decoder is configured to acquire the re-ordered multi-dimensional array on the basis of the first multi-dimensional array, wherein a first dimension of the re-ordered multi-dimensional array is defined by one of the further dimension values.

10. The decoder according to claim 1,
wherein the decoder is configured to decode encoded neural network parameters using a context-based entropy decoding, and
wherein the decoder is configured to determine positions of the decoded neural network parameters in the first multi-dimensional array using a position mapping function which maps a scalar neural network parameter index onto a set of dimension indices.

11. The decoder according to claim 1,
wherein the decoder is configured to contiguously store a plurality of decoded neural network parameters, which are directly adjacent with respect to a decoding order, along a given dimension of the first multi-dimensional array.

12. The decoder according to claim 1,
wherein the decoder is configured to acquire the re-ordered multi-dimensional array using a processing of the form:
for(i=0; i<Prod(inputTensorDims); i++){
idxA=TensorIndex(inputTensorDims, i, 0)
idxB=ShiftArrayIndex(idxA, firstTensorDimShift)
reorderedTensor[idxB]=inputTensor[idxA]
}
wherein i is a running variable;
wherein Prod(inputTensorDims) is a product of lengths of dimensions of the first multi-dimensional array
wherein TensorIndex (.,.,.) is a function mapping an integer value onto a set of array indices designating an element of the first multi-dimensional array;
wherein inputTensorDims is a set of values describing lengths of dimensions of the first multi-dimensional array;
wherein idxA is a variable;
wherein ShiftArrayIndex (.,.) is a function mapping an input set of array indices onto a return set of array indices, wherein the return set of array indices is a copy of the input set of array indices but with an element of the input set of array indices at position 0 shifted to a position designated by firstTensorDimShift;
wherein firstTensorDimShift is a dimension shift value;
wherein idxB is a variable;
wherein inputTensor [.] is the first multi-dimensional array,
wherein reorderedTensor [.] is the re-ordered multi-dimensional array,
wherein inputTensor[idxA] is an element of the first multi-dimensional array at a position designated by idxA;
wherein reorderedTensor [idxB] is an element of the reordered multi-dimensional array at a position designated by idxB.

13. The decoder according to claim 1,
wherein the decoder is configured to acquire the re-ordered multidimensional array using a function which maps an integer element index i designating an element of the first multi-dimensional array onto a set of array indices,
wherein a returned set of array indices designates an i-th element in a row-major scan order of the first multidimensional array, or
wherein a returned set of array indices designates an i-th element of a block-wise scan of the first multi-dimensional array, in which the first multi-dimensional array is considered as a two-dimensional array.

14. The decoder according to claim 1,
wherein the decoder is configured to decode a list of skipped rows;
wherein the decoder is configured to enter decoded neural network coefficients into the first multidimensional array at respective positions described by respective sets of array indices;
wherein the decoder is configured decide, in dependence on an entry of the list of skipped rows referenced by a current array index of the first dimension of the first multidimensional array, whether to use a default value for a given neural network parameter or whether to determine the given neural network parameter using a decoding.

15. The decoder according to claim 1,
wherein the decoder is configured to decode a set of array dimensions; and
wherein the decoder is configured to acquire a reordered set of array dimensions.

16. The decoder according to claim 1,
wherein the decoder is configured to enter decoded neural network parameters into the first multidimensional array at respective positions described by respective sets of array indices;
wherein the decoder is configured to acquire the respective sets of array indices using a mapping function which maps a scalar integer parameter index onto the respective set of array indices and which defines a block-wise scan.

17. The decoder according to claim 16,
wherein the mapping function comprises a mapping of the scalar integer parameter index onto two coordinates which point to a position that corresponds to a scan index defined by the scalar integer parameter index when a block is scanned in blocks; and
wherein the mapping function comprises a mapping of the two coordinates onto the respective set of array indices.

18. The decoder according to claim 1,
wherein the decoder is configured to enter decoded neural network parameters into the first multidimensional array at respective positions described by respective sets of array indices;
wherein the decoder is configured to acquire a respective set of array indices on the basis of a scalar integer parameter index i using a function TensorIndex(tensorDimensions[ ], i, scan);
wherein the function TensorIndex(tensorDimensions[ ], i, scan) returns an array of array indices with a same number of dimensions as an array tensorDimensions[ ],
where the elements of the array of array indices are set to integer values so that the array of array indices can be used as an index pointing to an element of an array with dimensions tensorDimensions[ ] as follows:
If variable scan is equal to 0:
the returned array of array indices points to the i-th element in row-major scan order of an array with dimensions defined by tensorDimensions[ ];
If variable scan is greater than 0:
a variable bs is set to 4<<scan_order;
a variable h is set to tensorDimensions[0];
a variable w is set to Prod(tensorDimensions)/h;
two variables x and y are set to the first and second element of an array that is returned
by calling IndexToXY(w, h, i, bs), respectively;
the returned array is TensorIndex(tensorDimensions, y*w+x, 0);
wherein the function IndexToXY(w, h, i, bs) returns an array with two elements,
wherein the first element returned by the function IndexToXY is an x coordinate and the second element returned by the function IndexToXY is a y coordinate pointing into a 2D array of width w and height h,
wherein x and y point to a position that corresponds to scan index i when the block is scanned in blocks of size bs times bs;
wherein x and y are derived as follows:
a variable fullRowOfBlocks is set to w*bs;
a variable blockY is set to i/fullRowOfBlocks;
a variable iOff is set to i % fullRowOfBlocks;
a variable currBlockH is set to Min(bs, h−blockY*bs);
a variable fullBlocks is set to bs*currBlockH;
a variable blockX is set to iOff/fullBlocks;
a variable blockOff is set to iOff % fullBlocks;
a variable currBlockW is set to Min(bs, w−blockX*bs)
a variable posX is set to blockOff % currBlockW;
a variable posY is set to blockOff/currBlockW;
The variable x is set to blockX*bs+posX;
The variable y is set to blockY*bs+posY;
wherein tensorDimensions [ ] is an array of values describing lengths of the first multidimensional array in different dimensions; and
wherein scan is an integer variable describing a scan mode.

19. An encoder for providing an encoded representation of parameters of a neural network,
wherein the encoder is configured to acquire a re-ordered multidimensional array using a reordering, in which a given dimension of an given multi-dimensional array of neural network parameters is rearranged to a first dimension in the re-ordered multidimensional array;
wherein the encoder is configured to encode the reordered multi-dimensional array.

20. A method for providing decoded parameters of a neural network on the basis of an encoded representation,
wherein the method comprises acquiring a first multi-dimensional array comprising a plurality of neural network parameter values using a decoding of neural network parameters;
wherein the method comprises acquiring a re-ordered multidimensional array using a reordering, in which a first dimension of the first multi-dimensional array is rearranged to a different dimension in the re-ordered multidimensional array.

21. A method for providing an encoded representation of parameters of a neural network,
wherein the method comprises acquiring a re-ordered multidimensional array using a reordering, in which a given dimension of an given multi-dimensional array of neural network parameters is rearranged to a first dimension in the re-ordered multidimensional array;
wherein the method comprises encoding the reordered multi-dimensional array.

22. A non-transitory digital storage medium having a computer program stored thereon to perform the method for providing decoded parameters of a neural network on the basis of an encoded representation,
wherein the method comprises acquiring a first multi-dimensional array comprising a plurality of neural network parameter values using a decoding of neural network parameters;
wherein the method comprises acquiring a re-ordered multidimensional array using a reordering, in which a first dimension of the first multi-dimensional array is rearranged to a different dimension in the re-ordered multidimensional array,
when said computer program is run by a computer.

23. A non-transitory digital storage medium having a computer program stored thereon to perform the method for providing an encoded representation of parameters of a neural network,
wherein the method comprises acquiring a re-ordered multidimensional array using a reordering, in which a given dimension of an given multi-dimensional array of neural network parameters is rearranged to a first dimension in the re-ordered multidimensional array;
wherein the method comprises encoding the reordered multi-dimensional array,
when said computer program is run by a computer.
